(19) United States
(12) Patent Application Publication
(10) Pub. No.: US 2020/0203610 A1
(43) Pub. Date: Jun. 25, 2020

(54) ORGANIC ELECTROLUMINESCENT DEVICE AND PREPARATION METHOD AND DISPLAY APPARATUS THEREOF

(71) Applicants: KunShan Go-Visionox Opto-Electronics Co., Ltd, Kunshan (CN); TSINGHUA UNIVERSITY, Beijing (CN)

(72) Inventors: Lian DUAN, Kunshan (CN); Minghan CAI, Kunshan (CN); Xiaozeng SONG, Kunshan (CN); Guomeng LI, Kunshan (CN)

(73) Assignees: KunShan Go-Visionox Opto-Electronics Co., Ltd, Kunshan (CN); TSINGHUA UNIVERSITY, Beijing (CN)

(21) Appl. No.: 16/804,366

(22) Filed: Feb. 28, 2020

Related U.S. Application Data
(63) Continuation of application No. PCT/CN2019/080614, filed on Mar. 29, 2019.

(30) Foreign Application Priority Data
Aug. 31, 2018 (CN) 201811015674.3

(51) Int. Cl. H01L 51/00

(52) U.S. Cl. CPC H01L 51/008; H01L 51/0094; H01L 51/0067; H01L 51/0072; H01L 51/006

(57) ABSTRACT

An organic electroluminescent device, a preparation method thereof, and a display apparatus thereof. The organic electroluminescent device includes an organic light emitting layer, the organic light emitting layer includes a host material and a resonance-type thermally activated delayed fluorescence material; the host material is an exciplex; a singlet energy level of the exciplex is greater than a singlet energy level of the resonance-type thermally activated delayed fluorescence material, and a triplet energy level of the exciplex is greater than a triplet energy level of the resonance-type thermally activated delayed fluorescence material. The present application can overcome the defects of short device lifetime and wide spectrum caused by using conventional TADF materials for emitting light at present.

### CROSS-REFERENCE TO RELATED APPLICATIONS

The present application is a continuation of International Application No. PCT/CN2019/080614, filed on Mar. 29, 2019, which claims priority to Chinese Patent Application No. 201811015674.3, filed on Aug. 31, 2018. The contents of the above identified applications are incorporated herein by reference in their entireties.

### FIELD

The present application relates to the field of organic electroluminescent technology, and in particular, to an organic electroluminescent device, and a preparation method and a display apparatus thereof.

### BACKGROUND

Organic light emitting diode (OLED) is a device for achieving the purpose of light emitting by current drive. Its main characteristics are derived from an organic light emitting layer therein. When an appropriate voltage is applied, electrons and holes combine in the organic light emitting layer to generate excitons and emit light of different wavelengths according to the characteristics of the organic light emitting layer. At this stage, the light emitting layer is composed of a host material and a doping dye, and the dye is mostly selected from traditional fluorescent materials and traditional phosphorescent materials. Specifically, traditional fluorescent materials have the defect that triplet excitons cannot be used, and although traditional phosphorescent materials can achieve singlet exciton transition to triplet state by introducing a heavy metal atom, such as iridium or platinum, to achieve 100% energy use efficiency. However, heavy metals such as iridium and platinum are very scarce, expensive and easily cause environmental pollution, so phosphorescent materials cannot become the first choice for dyes.

Thermally activated delayed fluorescence (TADF) materials, compared with traditional phosphorescent materials and traditional fluorescent materials, can realize a reverse intersystem crossing from the triplet excitons to the singlet state by absorbing ambient heat, and then emit fluorescence from the singlet state, thereby achieving 100% utilization of excitons, without the aid of any heavy metal. Therefore, currently, 100% energy use efficiency is mainly achieved by doping a host material with the TADF material. However, most TADF materials also have certain defects, such as excessively wide luminescence spectrum, large device roll-off, and short lifetime.

### SUMMARY

The present application provides an organic electroluminescent device and a preparation method thereof, and a display apparatus thereof. An organic light emitting layer of the device uses an exciplex as a host material to sensitize a resonance-type TADF dye to emit light, thereby overcoming the defects of short device lifetime, large efficiency roll-off, and poor color purity caused by the use of traditional TADF materials for light-emitting at present.

The present application provides an organic electroluminescent device including an organic light emitting layer, the organic light emitting layer including a host material and a resonance-type thermally activated delayed fluorescence material; the host material is an exciplex; and a singlet energy level of the exciplex is greater than a singlet energy level of the resonance-type thermally activated delayed fluorescence material, and a triplet energy level of the exciplex is larger than a triplet energy level of the resonance-type thermally activated delayed fluorescence material.

Optionally, the resonance-type thermally activated delayed fluorescence material has a structure represented by formula [1]:

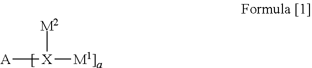

wherein, X is independently selected from one of B, P, P═O, P═S, and SiR₁; R₁ is selected from H, a substituted or unsubstituted C₁-C₃₆ alkyl, a substituted or unsubstituted C₆-C₃₀ aryl, or a substituted or unsubstituted C₃-C₃₀ heteroaryl;
A is selected from a substituted or unsubstituted C₆-C₃₀ aryl, a substituted or unsubstituted C₃-C₃₀ heteroaryl, or a substituted or unsubstituted C₆-C₃₀ arylamino;
M¹ and M² are each independently selected from H, a substituted or unsubstituted C₁-C₃₆ alkyl, a substituted or unsubstituted C₆-C₃₀ aryl, or a substituted or unsubstituted C₃-C₃₀ heteroaryl;
at least three of adjacent X, A, M¹, M² are connected to form a ring, and X is included in the ring;
a is an integer of 1 to 12; preferably, a is an integer of 1 to 6;
when substituents are present in the above groups, the substituents are each independently selected from one or more of halogen, cyano, C₁-C₁₀ alkyl, C₂-C₆ alkenyl, C₁-C₆ alkoxy or thioalkoxy, C₆-C₃₀ aryl and C₃-C₃₀ heteroaryl.

Optionally, three of adjacent X, A, M¹, and M² are connected to form a six-membered ring containing two heteroatoms; the heteroatoms are selected from two of B, P, Si, O, S, N, and Se.

Optionally, the resonance-type thermally activated delayed fluorescence material has a molecular weight of 200-2000.

Optionally, a is an integer of 1 to 6.

Optionally, the resonance-type thermally activated delayed fluorescence material is a compound represented by one of general formulae (F-1) to (F-29) in the present application, and in the general formulae (F-1) to (F-29), R is independently selected from one or more of H, halogen, cyano, C₁-C₁0 alkyl, C₂-C₆ alkenyl, C₁-C₆ alkoxy or thioalkoxy, C₆-C₃₀ aryl, and C₃-C₃₀ heteroaryl; Y is independently selected from O, S, or Se.

Optionally, the resonance-type thermally activated delayed fluorescence material is a compound represented by one of (M-1) to (M-72) of the present application.

Optionally, the exciplex includes an electron donor type material and an electron acceptor type material.

Optionally, an energy level difference between a singlet state and a triplet state of the exciplex is not higher than 0.15 ev.

Optionally, the electron donor type material is a compound having a hole-transport property containing at least one group of carbazolyl, arylamino, silicon group, fluorenyl, dibenzothiophenyl, and dibenzofuranyl.

Optionally, the electron donor type material is a compound represented by one of (D-1) to (D-19) of the present application.

Optionally, the electron acceptor type material is a compound having electron transport property containing at least one group of pyridyl, pyrimidyl, triazinyl, imidazolyl, o-phenanthrolinyl, sulfonyl, heptazinyl, oxadiazolyl, cyano, and diphenylphosphonyl.

Optionally, the electron acceptor type material is a compound represented by one of (A-1) to (A-33) of the present application.

Optionally, in the exciplex, a mass ratio of the electron donor type material to the electron acceptor type material is 1:9 to 9:1.

Optionally, in the exciplex, a mass ratio of the electron donor type material to the electron acceptor type material is 1:1.

Optionally, the exciplex has a mass ratio (doping concentration) of 1 wt % to 99 wt % in the organic light emitting layer.

Optionally, the resonance-type thermally activated delayed fluorescence material has a mass ratio (doping concentration) of 0.1 wt % to 50 wt % in the organic light emitting layer.

The present application also provides a preparation method of an organic electroluminescent device including the following step: forming an organic light emitting layer by co-evaporation of a host material source and a resonance-type thermally activated delayed fluorescence material source; the host material is an exciplex.

The present application further provides a display apparatus including any one of the organic electroluminescent materials described above.

The organic electroluminescent device of the present application uses an exciplex as a host material to sensitize a resonance-type TADF material to emit light. When holes and electrons are recombined, both singlet excitons and triplet excitons of the exciplex can be used and transferred to the singlet and triplet energy levels of the resonance-type TADF material, respectively. At the same time, because the resonance-type TADF material can undergo an inverse intersystem crossing, it can emit light by making use of both singlet excitons and excitons transitioning from the triplet state to their own singlet state. In addition, since the exciplex of the host material can convert a part of its triplet energy into singlet state, suppressing the Dexter energy transfer process, and promoting Föster energy transfer. Therefore, the light emitting efficiency of the organic electroluminescent device of the present application is effectively improved, and meanwhile the efficiency roll-off caused by too long lifetime of triplet state under high brightness is also reduced. Moreover, the exciplex, in addition to being the host material, can balance the transport of carriers in the light-emitting layer, widen the recombination region of the excitons, and further reduce the efficiency roll-off. At the same time, the resonance-type TADF material used in the present application does not have obvious intra-molecular electron transfer, so it is beneficial to narrow the spectrum and improve the color purity of the device.

### BRIEF DESCRIPTION OF THE DRAWINGS

FIG. 1 is a schematic structural diagram of an organic electroluminescent device of the present application.

### DETAILED DESCRIPTION OF THE EMBODIMENTS

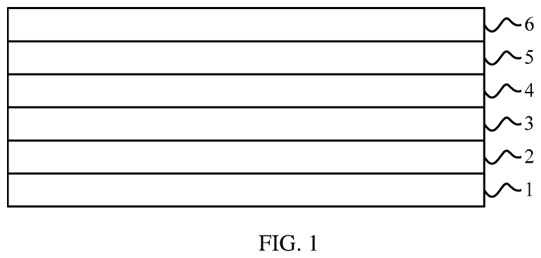

FIG. 1 is a schematic structural diagram of an organic electroluminescent device of the present application. As shown in FIG. 1, the organic electroluminescent device of the present application includes an anode 2, a hole transporting region 3, an organic light emitting layer 4, an electron transporting region 5 and a cathode 6, which are sequentially deposited on a substrate 1.

Specifically, the substrate 1 may be made of glass or a polymer material having excellent mechanical strength, thermal stability, water resistance, and transparency. In addition, the substrate 1 may be provided with a thin film transistor (TFT).

The anode 2 can be formed by sputtering or depositing an anode material on the substrate 1, where the anode material can be oxide transparent conductive materials such as indium tin oxide (ITO), indium zinc oxide (IZO), tin dioxide (SnO₂), zinc oxide (ZnO) and any combination thereof; the cathode 6 can be metals or alloys such as magnesium (Mg), silver (Ag), aluminum (Al), aluminum-lithium (Al—Li), calcium (Ca), magnesium-indium (Mg—In), magnesium-silver (Mg—Ag) and any combination thereof.

Organic material layers of the hole transporting region 3, the organic light emitting layer 4, and the electron transporting region 5 can be sequentially prepared on the anode 2 by methods such as vacuum thermal evaporation, spin coating, and printing. Among them, compounds used as the organic material layers may be organic small molecules, organic macromolecules and polymers, and combinations thereof.

Hereinafter, the organic light emitting layer 4 will be described in detail.

Most of TADF materials as a dye for emitting light have certain defects. For example, due to the intramolecular charge transfer of the TADF materials, the electroluminescence spectrum is often too wide and the light color is not pure. At the same time, due to the higher energy level of triplet state and the long lifetime of triplet excitons of the TADF materials, the device has large roll-off, short lifetime etc. In addition, most of host materials have the characteristics of unipolar transport, resulting in uneven transfer of electrons and holes in the light emitting layer, and also cause severe efficiency roll-off at high brightness, and poor spectral stability.

In view of this, the organic light emitting layer of the present application includes a host material and a resonance-type thermally activated delayed fluorescence material; the host material is an exciplex; a singlet energy level of the exciplex is greater than a singlet energy level of the resonance-type thermally activated delayed fluorescence material, a triplet energy level of the exciplex is greater than a triplet energy level of the resonance-type thermally activated delayed fluorescence material.

The host material of the present application is the exciplex, which has a thermally activated delayed fluorescence effect, that is, the triplet excitons of the exciplex can transition to a singlet state by absorbing ambient heat, that is, having an inverse intersystem crossing.

The resonance-type TADF material of the present application emits light as a dye. Since the resonance-type TADF molecules mostly have a planar aromatic rigid structure, the material has a stable structure. In resonance-type TADF molecules, different resonance effects of different atoms lead to a spatial separation between HOMO and LUMO on different atoms, having a small overlap area, which leads to a small energy level difference between the singlet state and triplet state of resonance-type TADF. Thus, the resonance-type TADF material can undergo reverse intersystem crossing. Specifically, the energy level difference between the singlet state and triplet state of the resonance-type TADF of the present application is less than or equal to 0.3 eV, and the reverse intersystem crossing can occur by absorbing ambient heat. At the same time, there is no obvious donor group and acceptor group in the resonance-type TADF molecules, so the resonance-type TADF molecules have a weak intramolecular charge transfer and a high stability.

In the present application, the singlet energy level of the host material is greater than the singlet energy level of the resonance-type TADF, and the triplet energy level of the host material is greater than the triplet energy level of the resonance-type TADF. Therefore, after the organic electroluminescent device being electrically excited, since the host material is the exciplex with thermally activated delayed fluorescence property, the triplet excitons of the host material will transition to the singlet state of the host material, and then energy will be transferred from the singlet state of the host material to the singlet state of the resonance-type TADF, and the triplet excitons of the resonance-type TADF also undergo inverse intersystem crossing to the singlet state thereof, and finally the energy of the singlet state and triplet state in the organic electroluminescent device are both fully utilized, improving light emitting efficiency of the organic electroluminescent device; at the same time, since the host material can convert its excitons from triplet state to the singlet state, the Dexter energy transfer between the host material and the resonance-type dye is effectively suppressed, increasing the Föster energy transfer process. Therefor the present application can effectively reduce the concentration of triplet excitons, thereby solving the problem of serious roll-off decline at high brightness, effectively increasing the stability of the organic electroluminescent device.

At the same time, the present application uses resonance-type TADF as a dye to emit light. There is no obvious intramolecular charge-transfer excited state inside the resonance-type TADF molecules, so a narrow luminescence spectrum can be obtained.

The present application innovates the composition of the organic light emitting layer, making the exciplex as the host material to sensitize the resonance-type TADF. This can not only improve the lifetime of the organic electroluminescent device, reduce roll-off, narrow the spectrum, but also have a very important significance for industrial applications.

In order to further reduce the roll-off efficiency of the device, it is preferred that the exciplex has a mass ratio of 1 wt % to 99 wt % in the organic light emitting layer; the resonance-type thermally activated delayed fluorescence material has a mass ratio of 0.1 wt %-50wt % in the organic light emitting layer.

Further, the above-mentioned resonance-type thermally activated delayed fluorescence material has a structure represented by formula [1]:

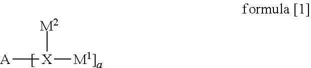

where, X is independently selected from one of B, P, P═O, P═S, and SiR₁; R₁ is selected from H, a substituted or unsubstituted C₁-C₃₆ alkyl, a substituted or unsubstituted C₆-C₃₀ aryl, or a substituted or unsubstituted C₃-C₃₀ heteroaryl; A is selected from a substituted or unsubstituted C₆-C₃₀ aryl, a substituted or unsubstituted C₃-C₃₀ heteroaryl, or a substituted or unsubstituted C₆-C₃₀ arylamino; M¹ and M² are each independently selected from H, a substituted or unsubstituted C₁-C₃₆ alkyl, a substituted or unsubstituted C₆-C₃₀ aryl, or a substituted or unsubstituted C₃-C₃₀ heteroaryl; at least three of adjacent X, A, M¹, M² are connected to form a ring, and X included in the ring; a is an integer of 1 to 12; when substituents are present in the above groups, the substituents are each independently selected from one or more of halogen, cyano, C₁-C₁₀ alkyl, C₂-C₆ alkenyl, C₁-C₆ alkoxy or thioalkoxy, C₆-C₃₀ aryl and C₃-C₃₀ heteroaryl.

It can be understood that when X is independently selected from P═O and P═S, P is connected to M¹ and M², respectively; when X is selected from SiR₁, Si is connected to M¹ and M², respectively.

It should be emphasized that in the structure of formula [1], a X, M¹, and M² can be selected independently of each other, that is, each unit containing X, M¹, and M² can be the same or different, and M¹ and M² in each unit may be the same or different. Furthermore, in the resonance-type TADF of the present application, at least one ring is formed by connection of at least three of adjacent X, A, M¹, and M², and X is included in the ring.

Further, in the resonance-type TADF represented by formula [1] of the present application, three of adjacent X, A, M¹, and M² are connected to form a six-membered ring containing two heteroatoms; the heteroatoms are selected from two of B, P, Si, O, S, N, and Se.

Specifically, adjacent X, A, and M¹ may be connected to form a six-membered ring containing two heteroatoms, adjacent X, A, and M² may be connected to form a six-membered ring containing two heteroatoms, adjacent X, M¹ and M² can be connected to form a six-membered ring containing two heteroatoms.

It can be understood that one heteroatom in the six-membered ring comes from X, that is, it may specifically be B, P, Si, and the other heteroatom is selected from one of O, S, N, and Se. When the other heteroatom is N, since the N atom is trivalent, in addition to being connected to a H atom, the N atom may be connected to an alkyl substituent, and specifically, the alkyl substituent is one or more of cyano, C₁-C₁₀ alkyl or cycloalkyl, C₂-C₆ alkenyl or cycloalkenyl, C₁-C₆ alkoxy or thioalkoxy, C₆-C₃₀ aryl, and C₃-C₃₀ heteroaryl.

As a preferred embodiment, a resonance-type TADF material with a molecular weight of 200-2000 is selected as a dye in the present application, and if the resonance-type TADF material has a too large molecule, it is not beneficial to evaporation in an actual operation process.

As an implementation, the molecular weight of the resonance-type TADF can be controlled by defining a to an integer of 1 to 6, that is, the resonance-type TADF of the present application may include 1-6 units having X, M¹, and M².

Preferably, the resonance-type TADF material of the present application may have a structure represented by one of the following general formulae (F-1) to (F-29):

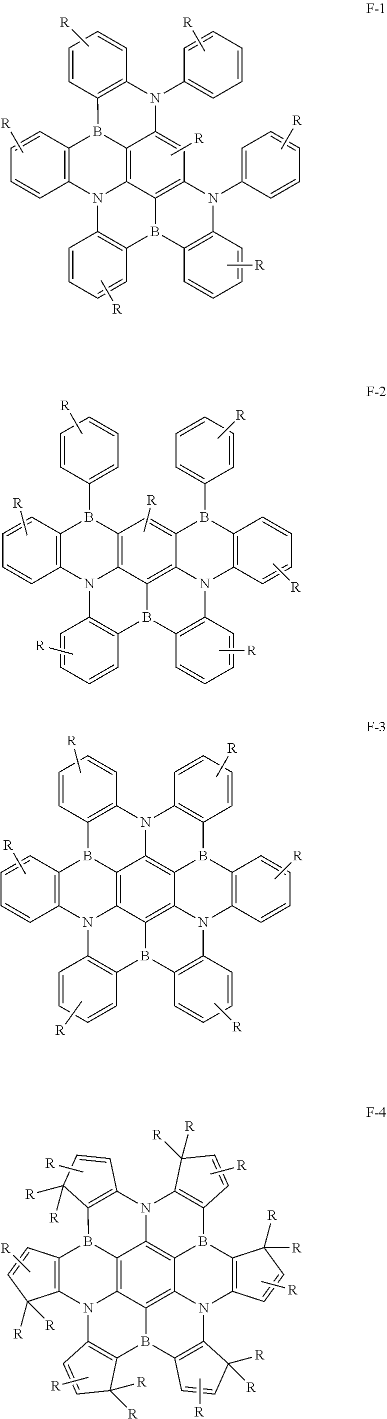

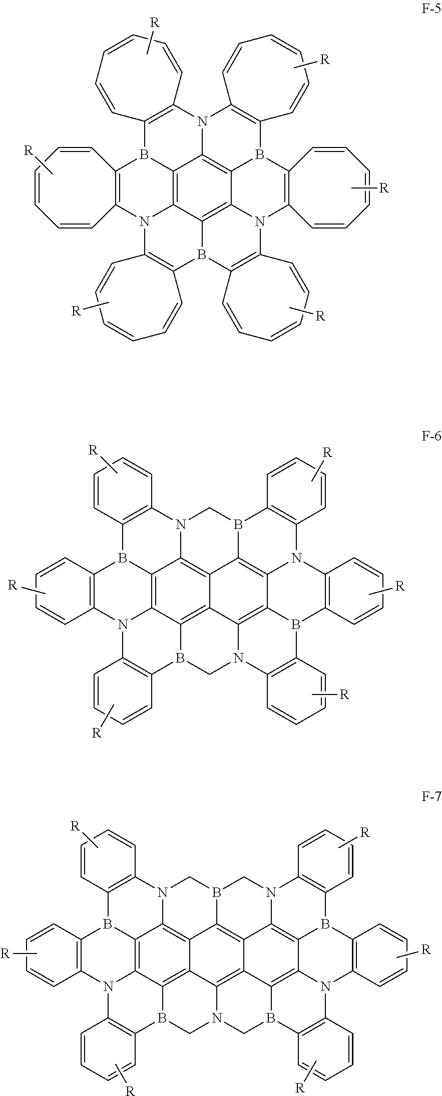

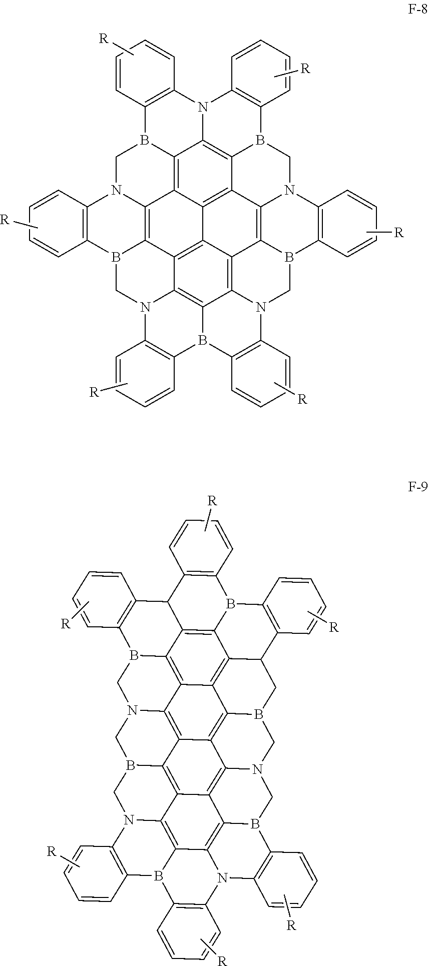

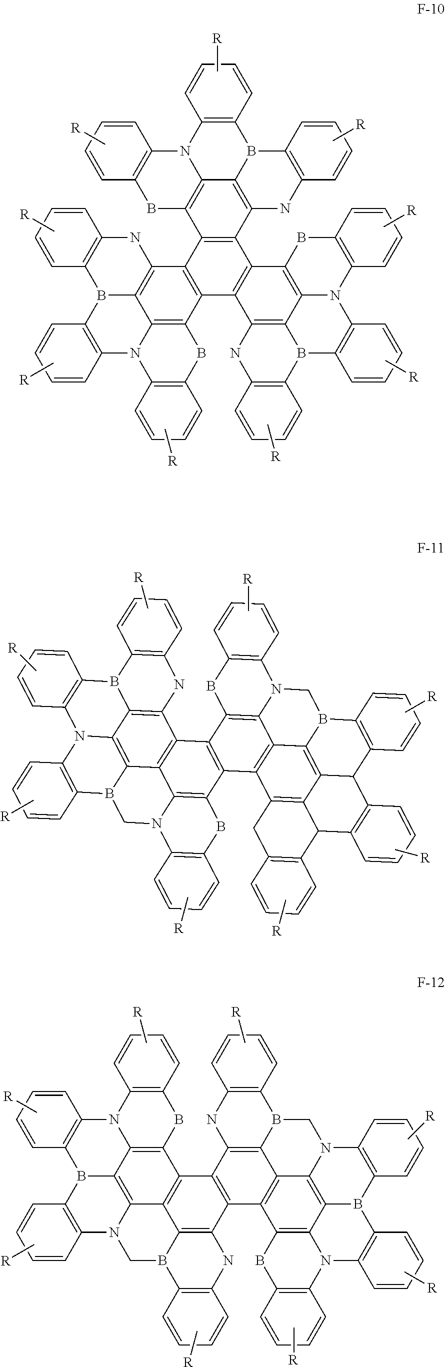

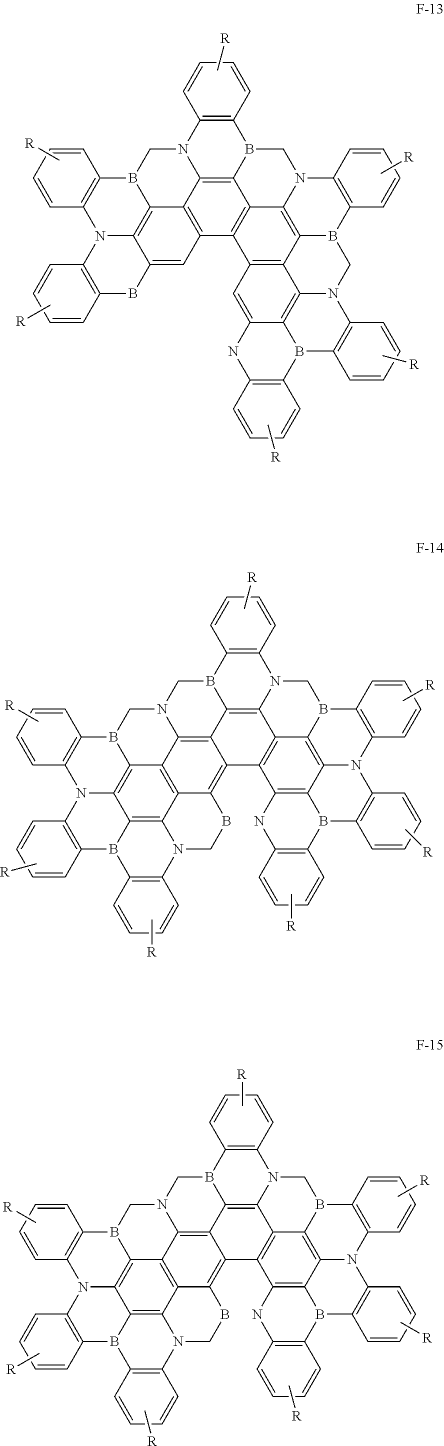

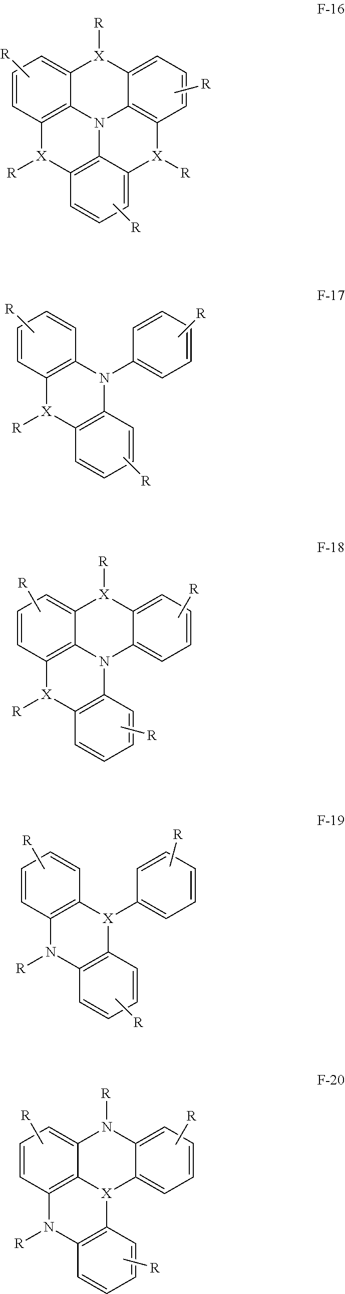

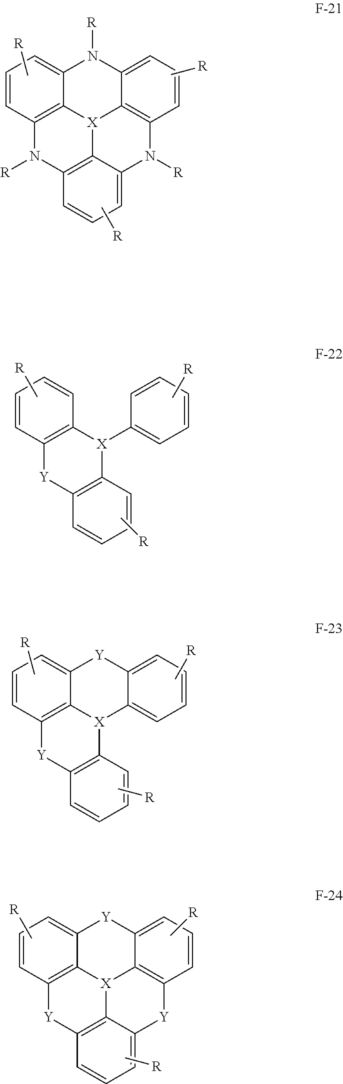

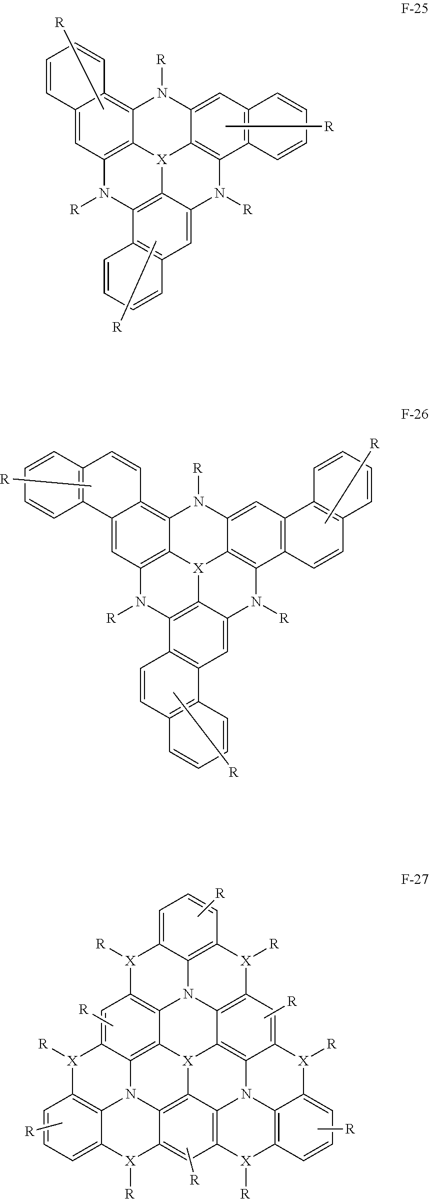

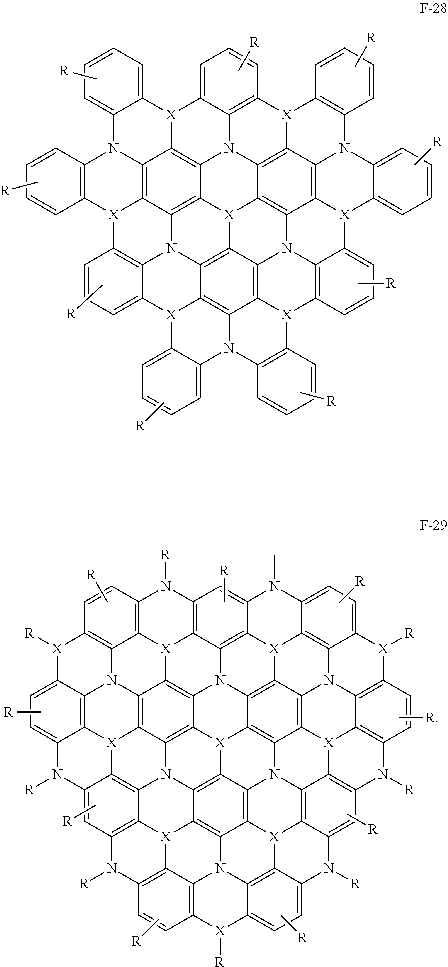

R is independently selected from one or more of H, halogen, cyano, C₁-C₁0 alkyl, C₂-C₆ alkenyl, C₁-C₆ alkoxy or thioalkoxy, C₆-C₃₀ aryl, and C₃-C₃₀ heteroaryl;

Y is independently selected from O, S, or Se.

Preferably, the resonance-type thermally activated delayed fluorescence material of the present application is a compound having one of the following structures:

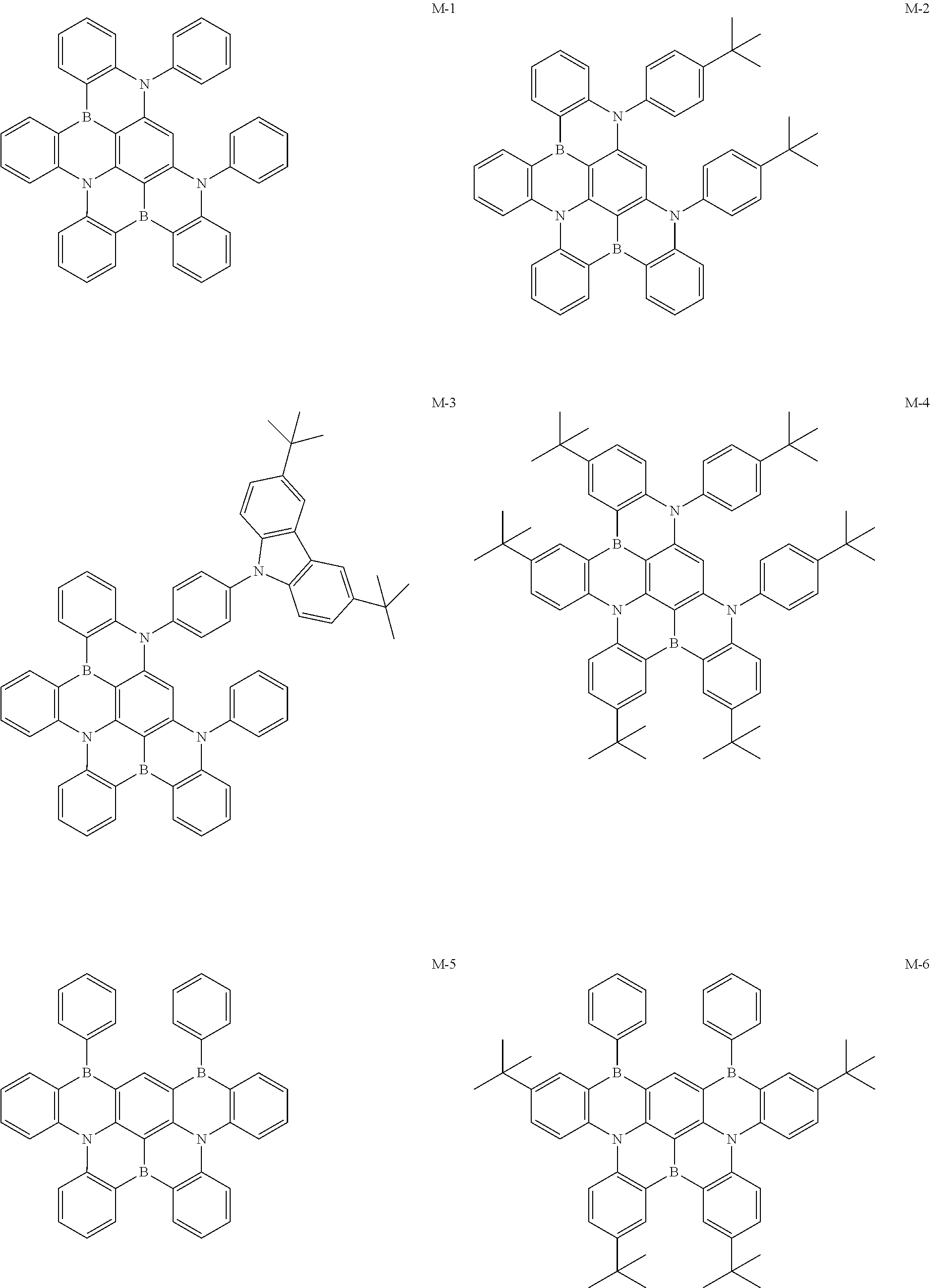

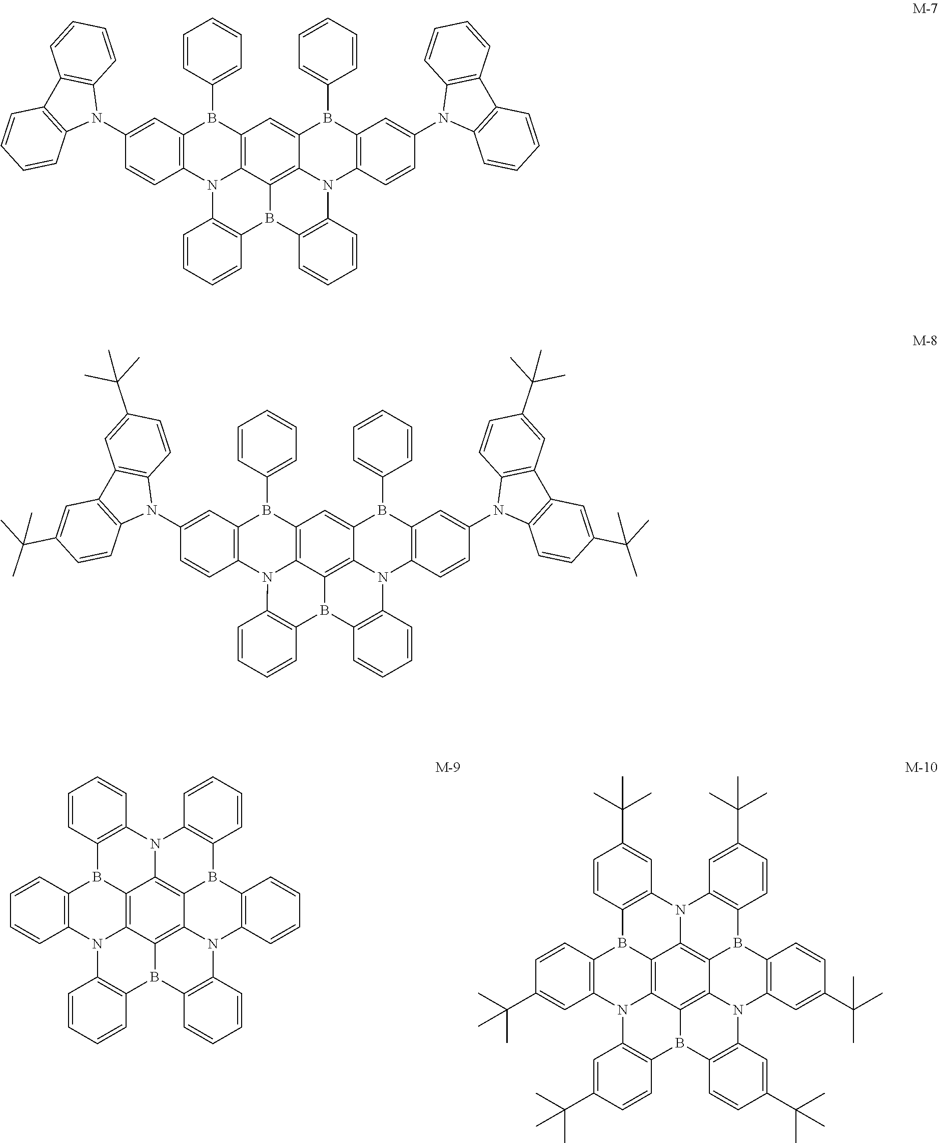

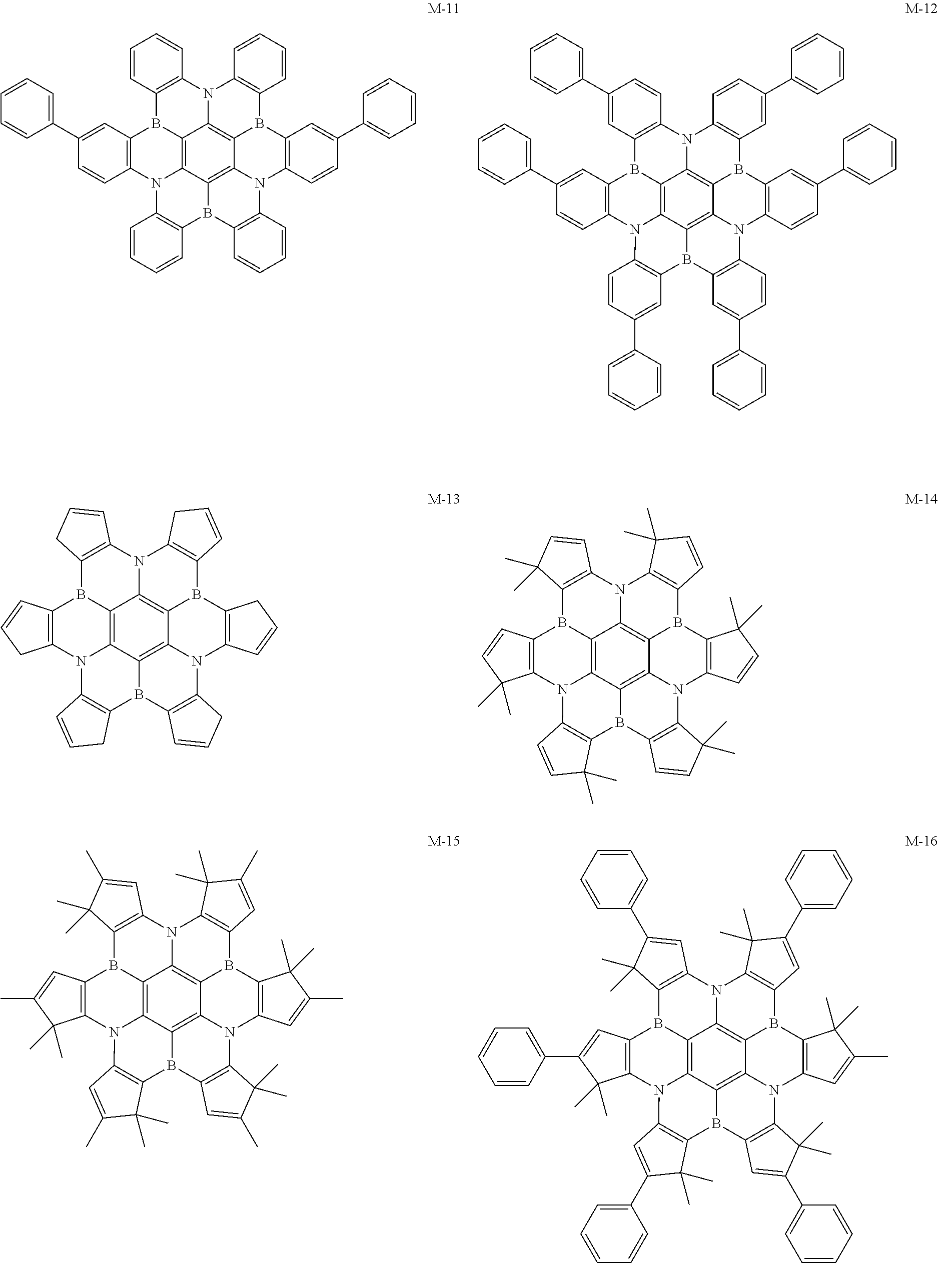

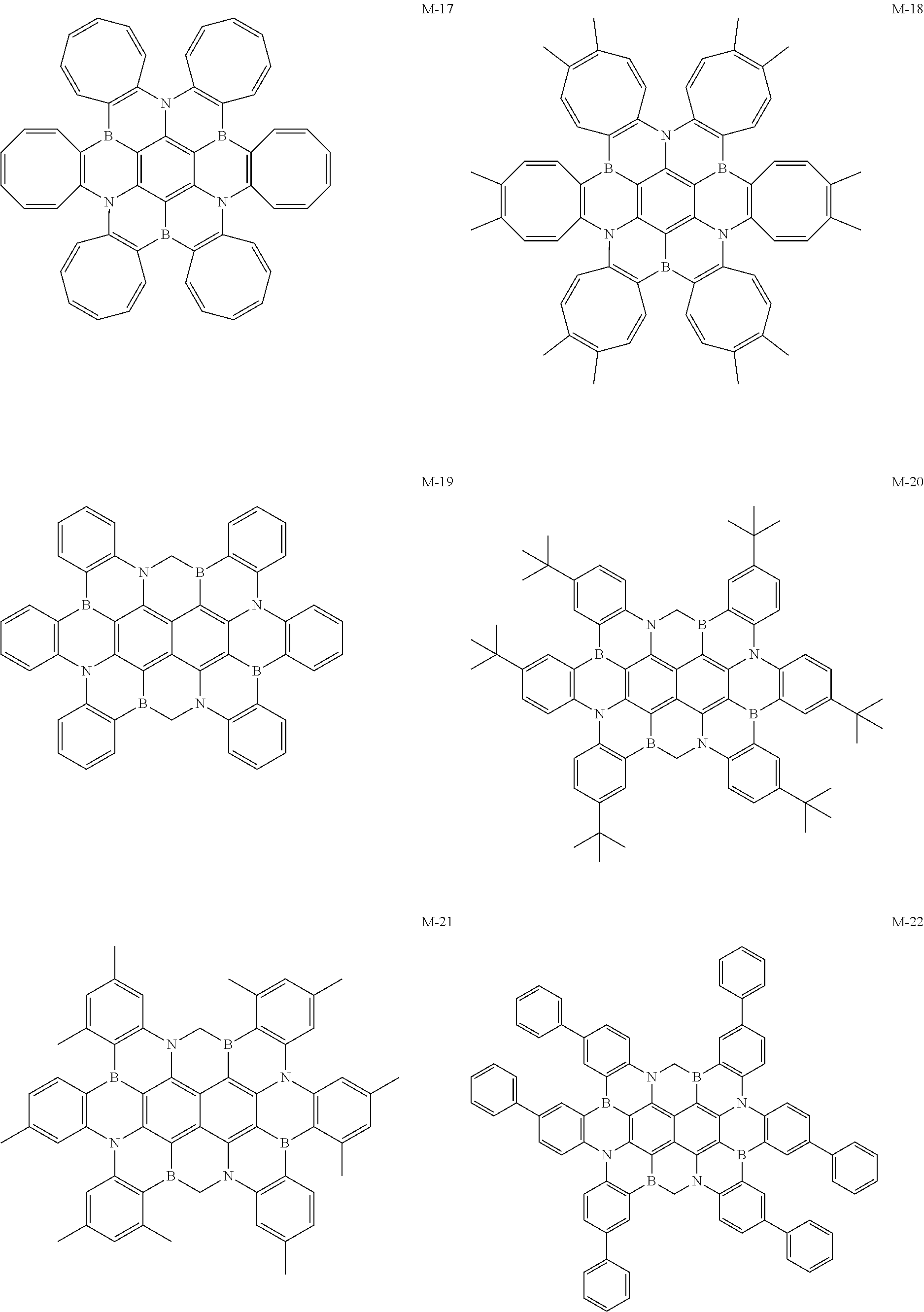

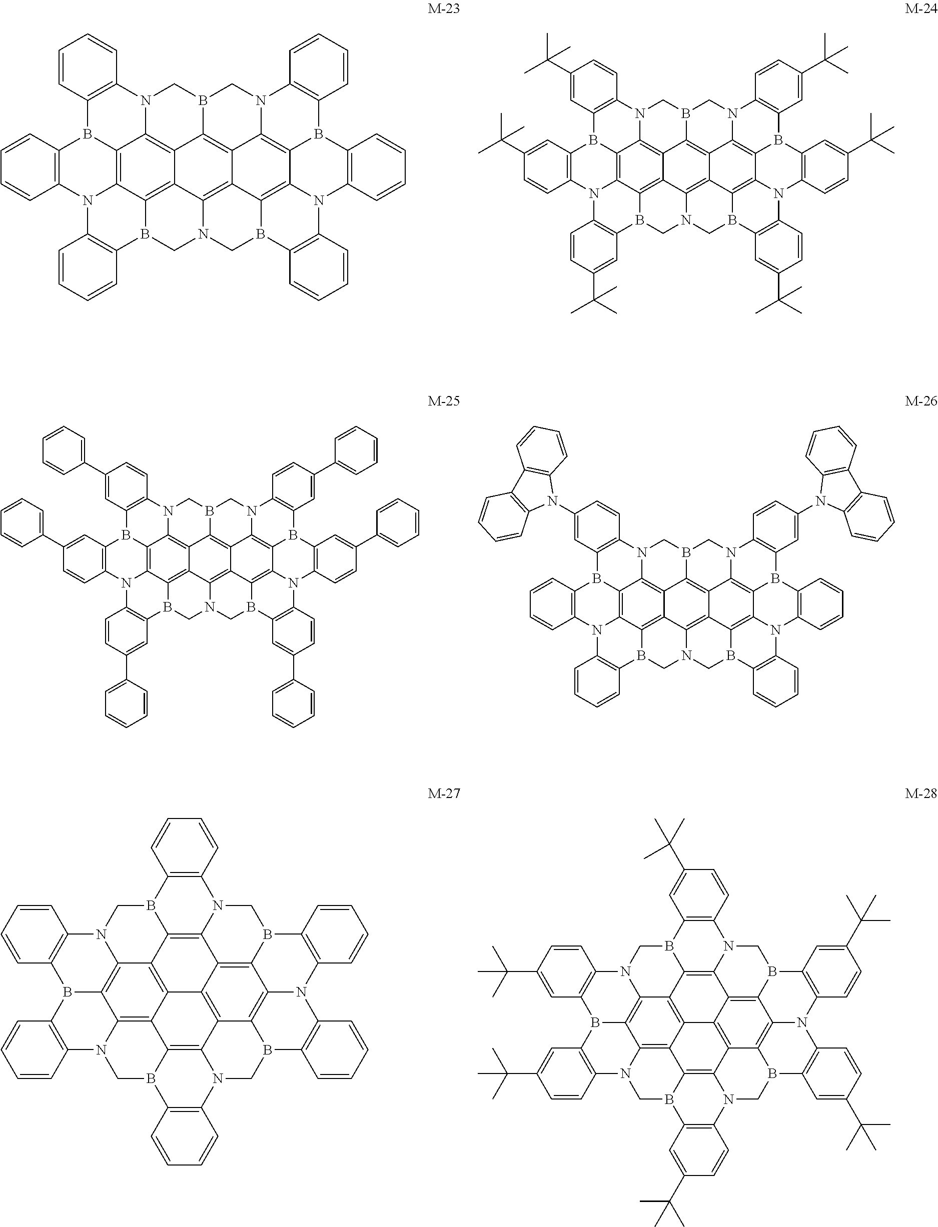

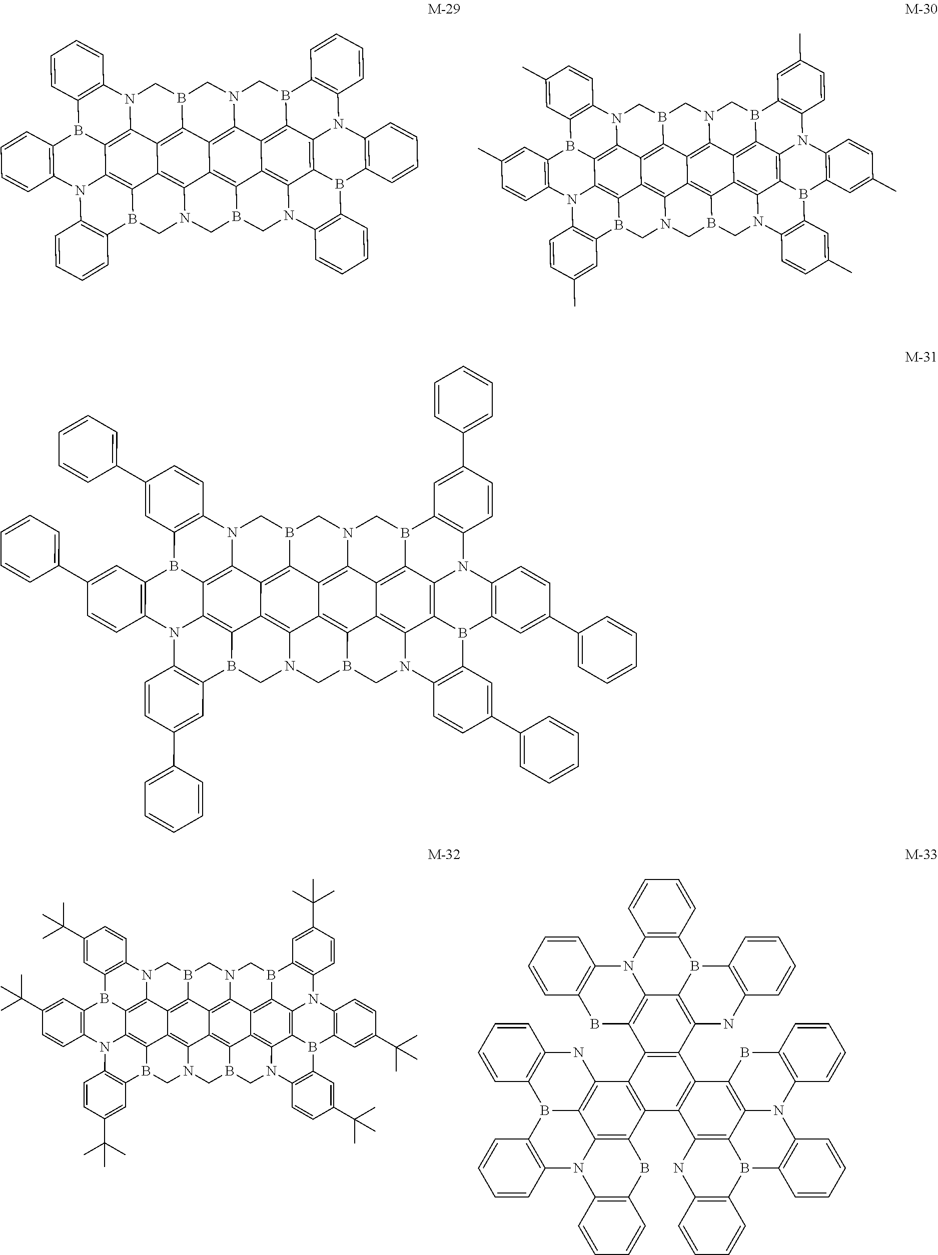

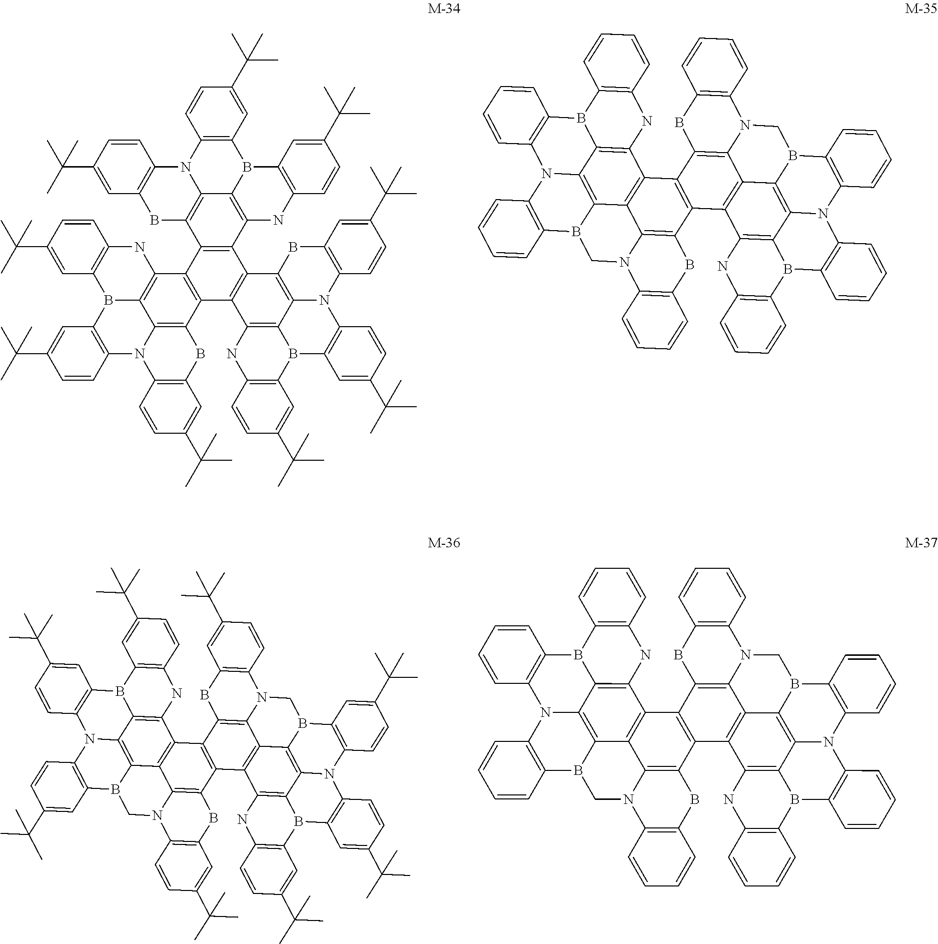

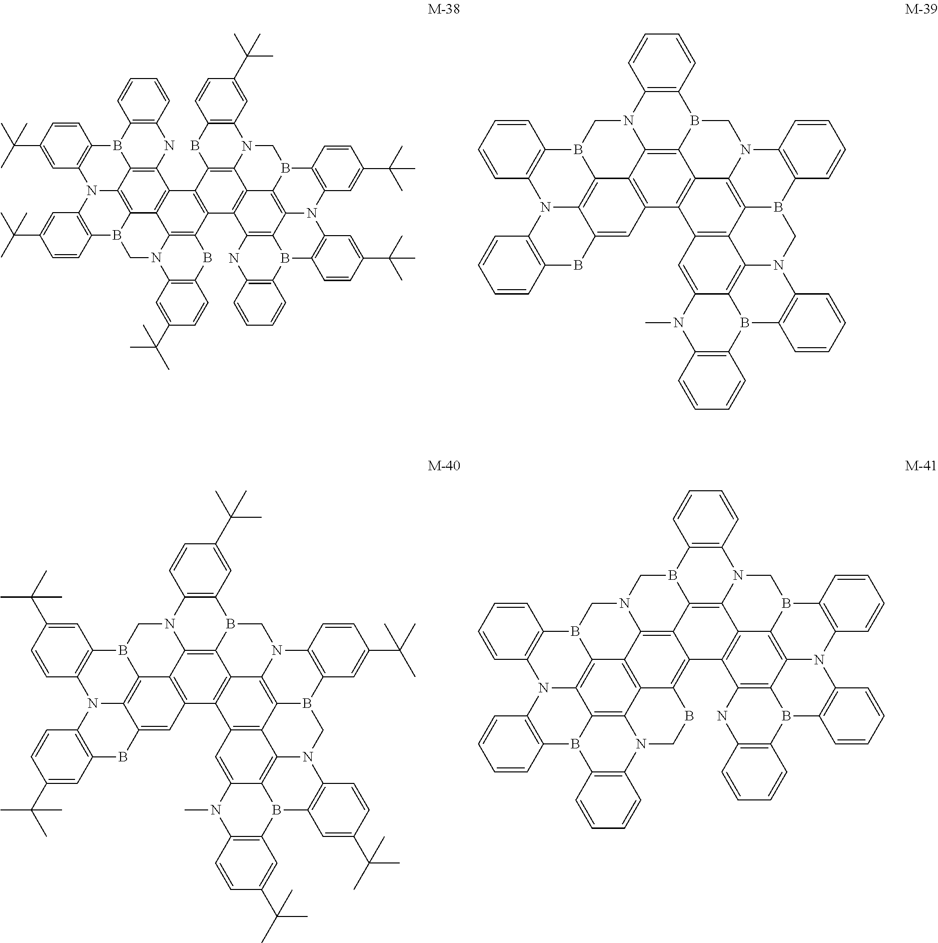

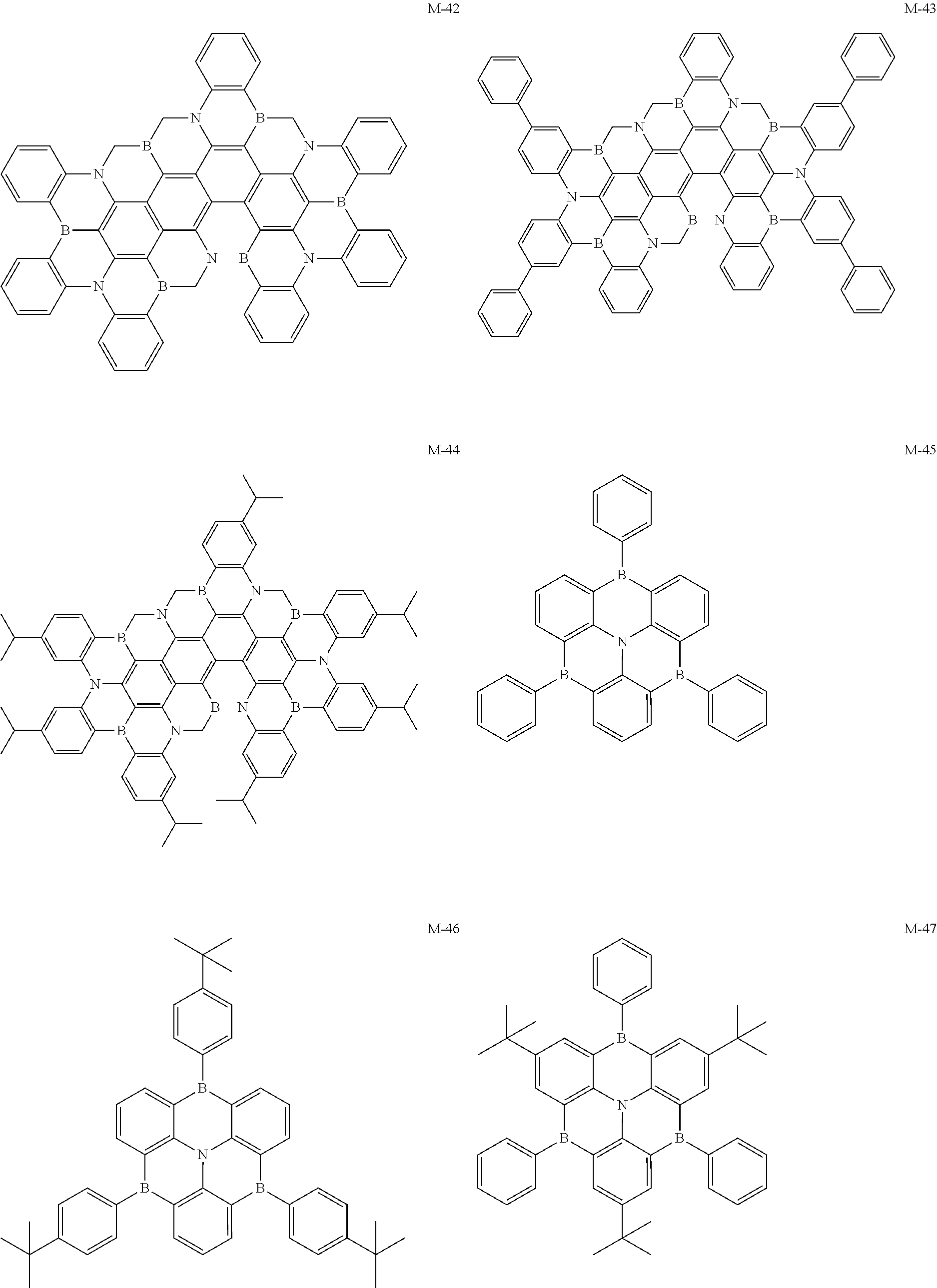

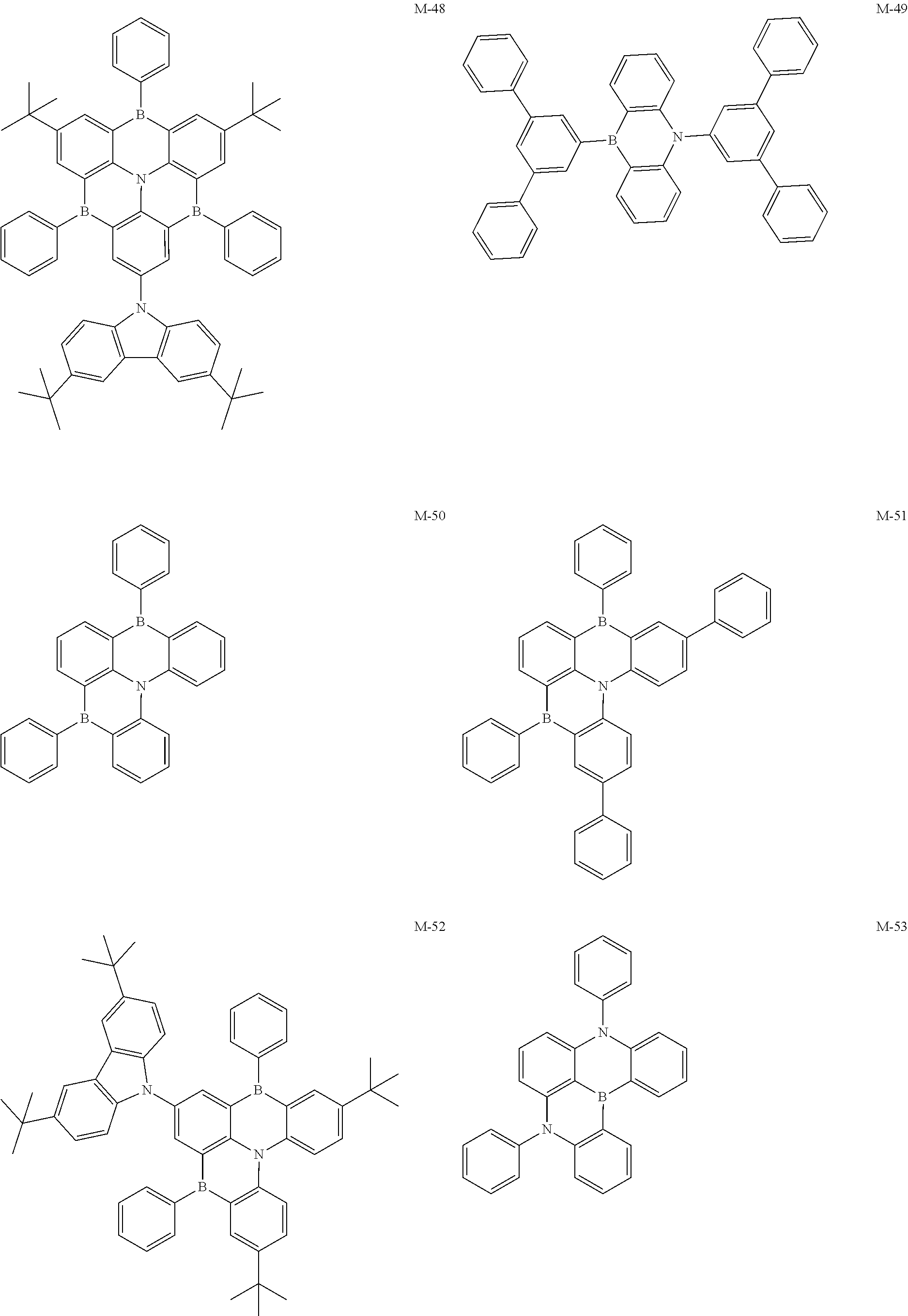

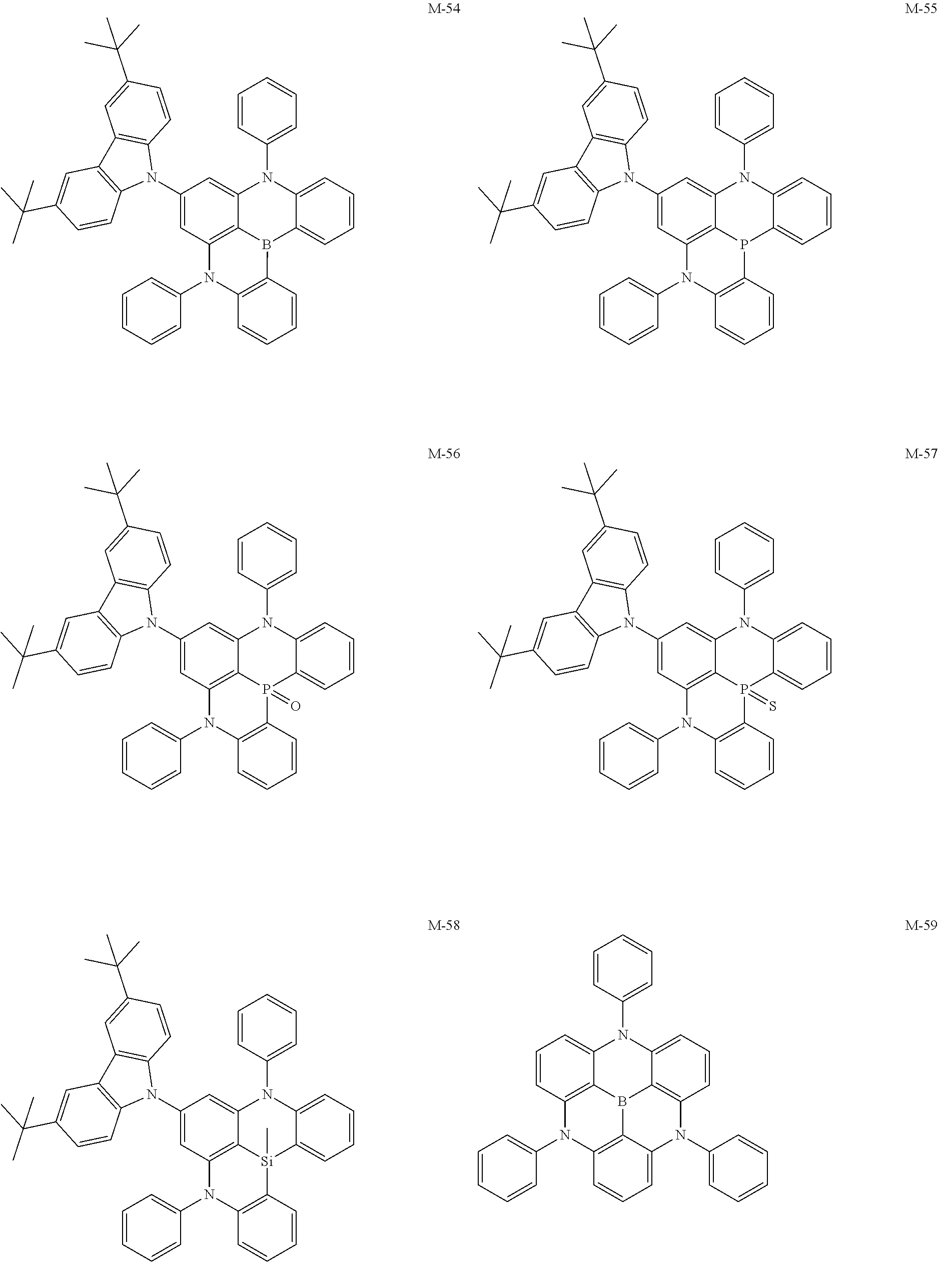

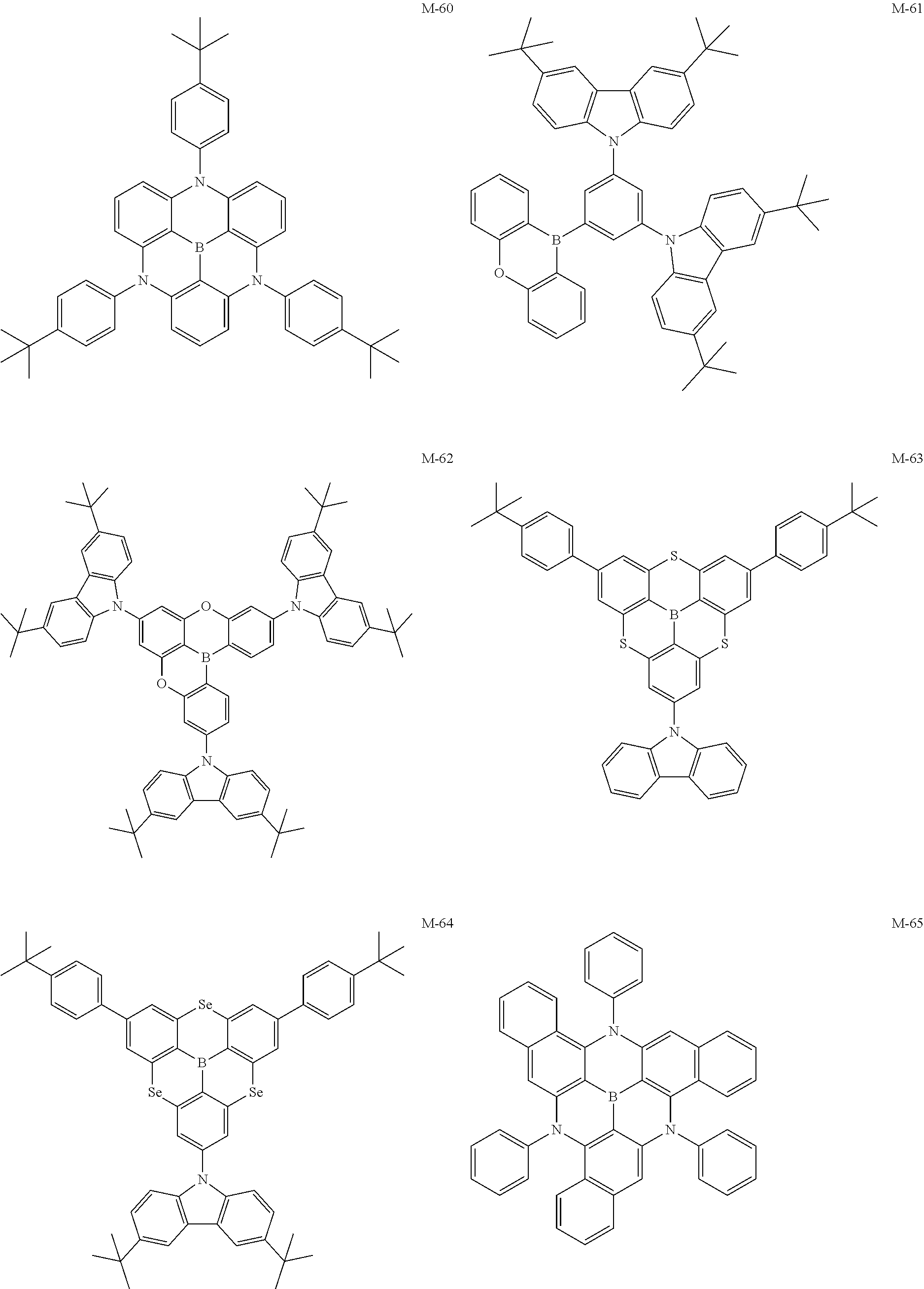

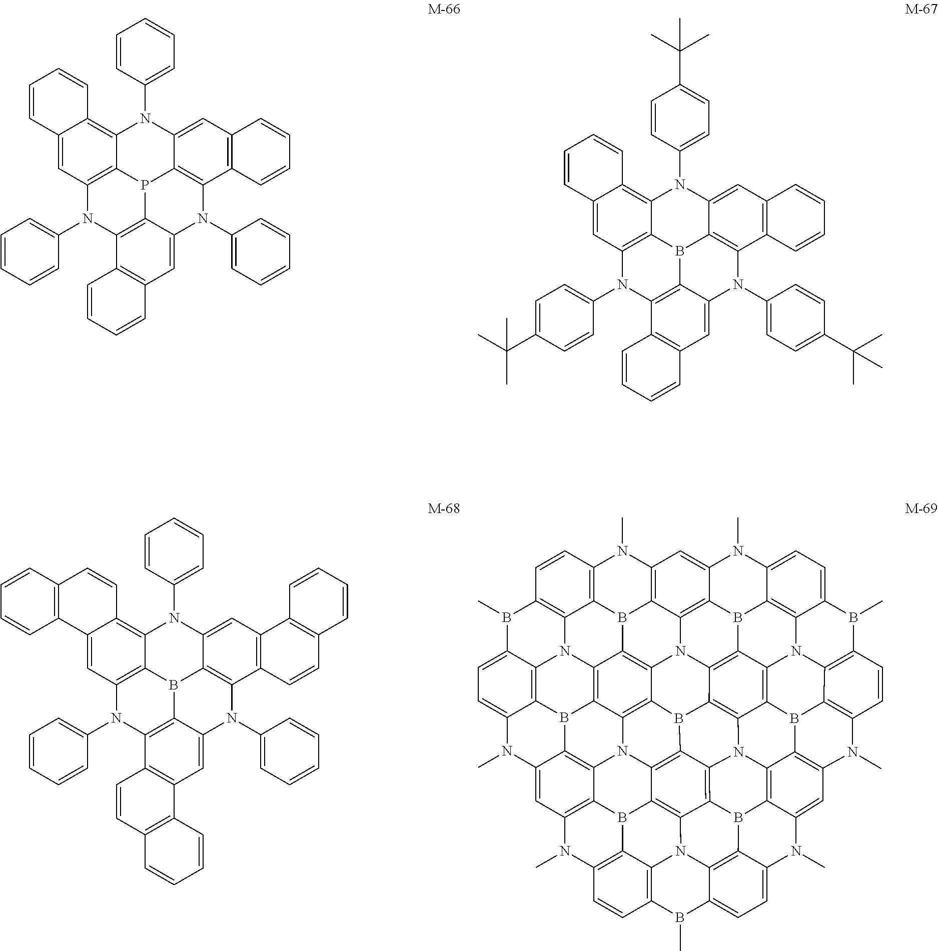

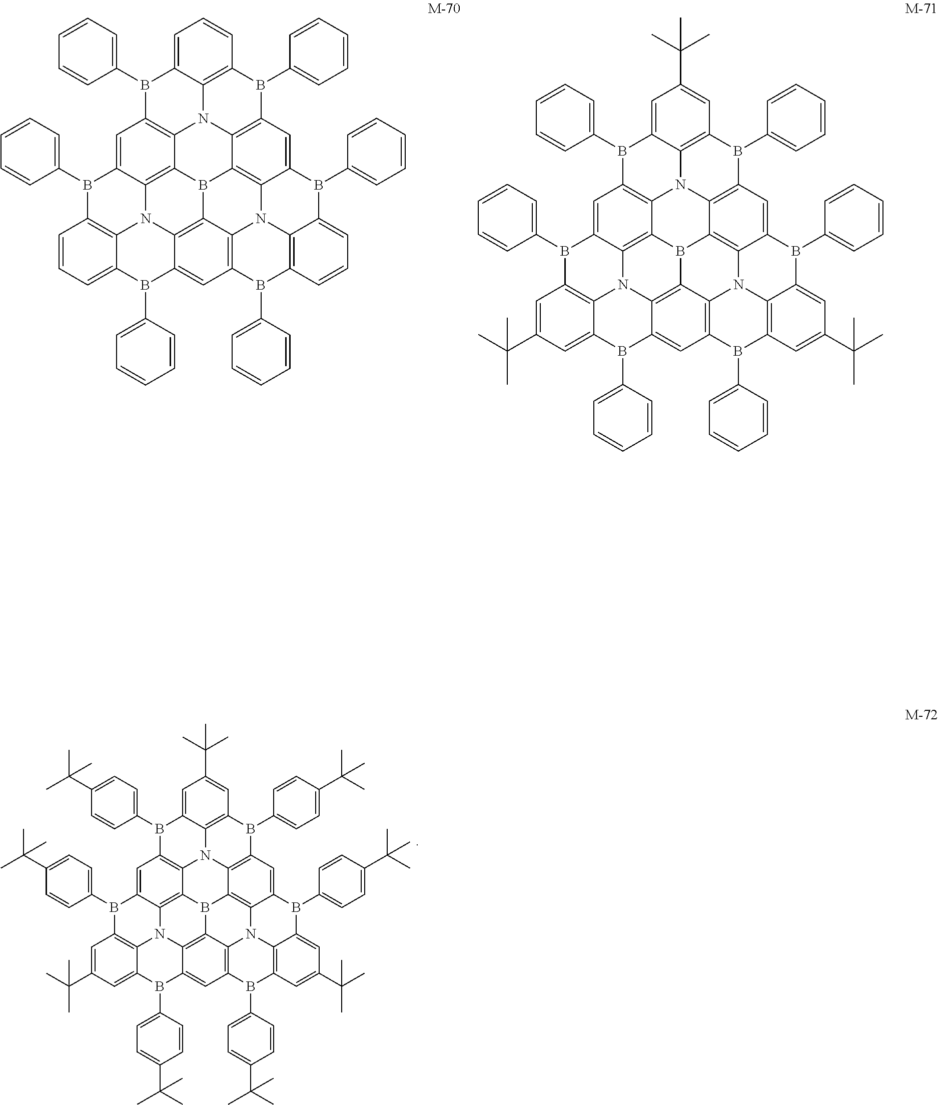

Further, the host material exciplex of the present application is composed of a mixture of a hole type material (electron donor type material) and an electron type material (electron acceptor type material), where the triplet energy level of the electron acceptor type material is greater than the triplet energy level of the exciplex, the triplet energy level of the electron donor type material is greater than the triplet energy level of the exciplex, and the singlet energy level of the electron acceptor type material is greater than the singlet energy level of the exciplex, the singlet energy level of the electron donor type material is greater than the singlet energy level of the exciplex. Therefore, the exciplex not only has the thermally activated delayed fluorescence effect, which enables its own triplet excitons to be effectively used, but also has simultaneous existence of provision and reception of the electrons in the organic light emitting layer, which can effectively balance transport of carriers and widen recombination regions of the excitons, thereby effectively reducing the efficiency roll-off and helping to maintain the stability of the organic electroluminescent device. In order to more easily realize the inverse intersystem crossing of the exciplex, an exciplex that an energy level difference between the singlet state and the triplet state is ≤0.15 eV may be preferred as the host material.

Where the electron donor type material is a compound having a hole-transport property containing at least one group of carbazolyl, arylamino, silicon group, fluorenyl, dibenzothiophenyl, and dibenzofuranyl.

Specifically, the electron donor type material may be, but is not limited to, a compound selected from one of the following structures:

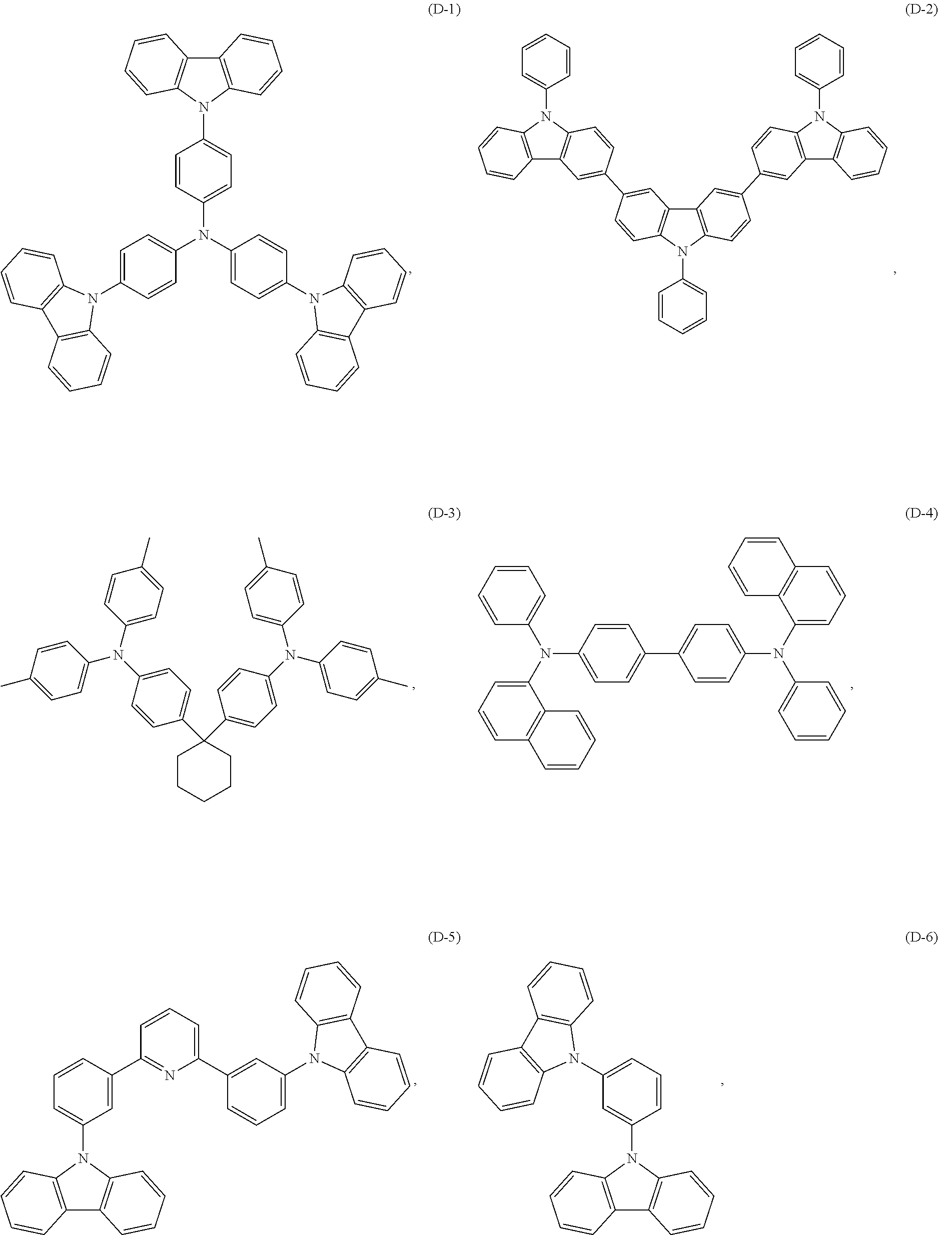

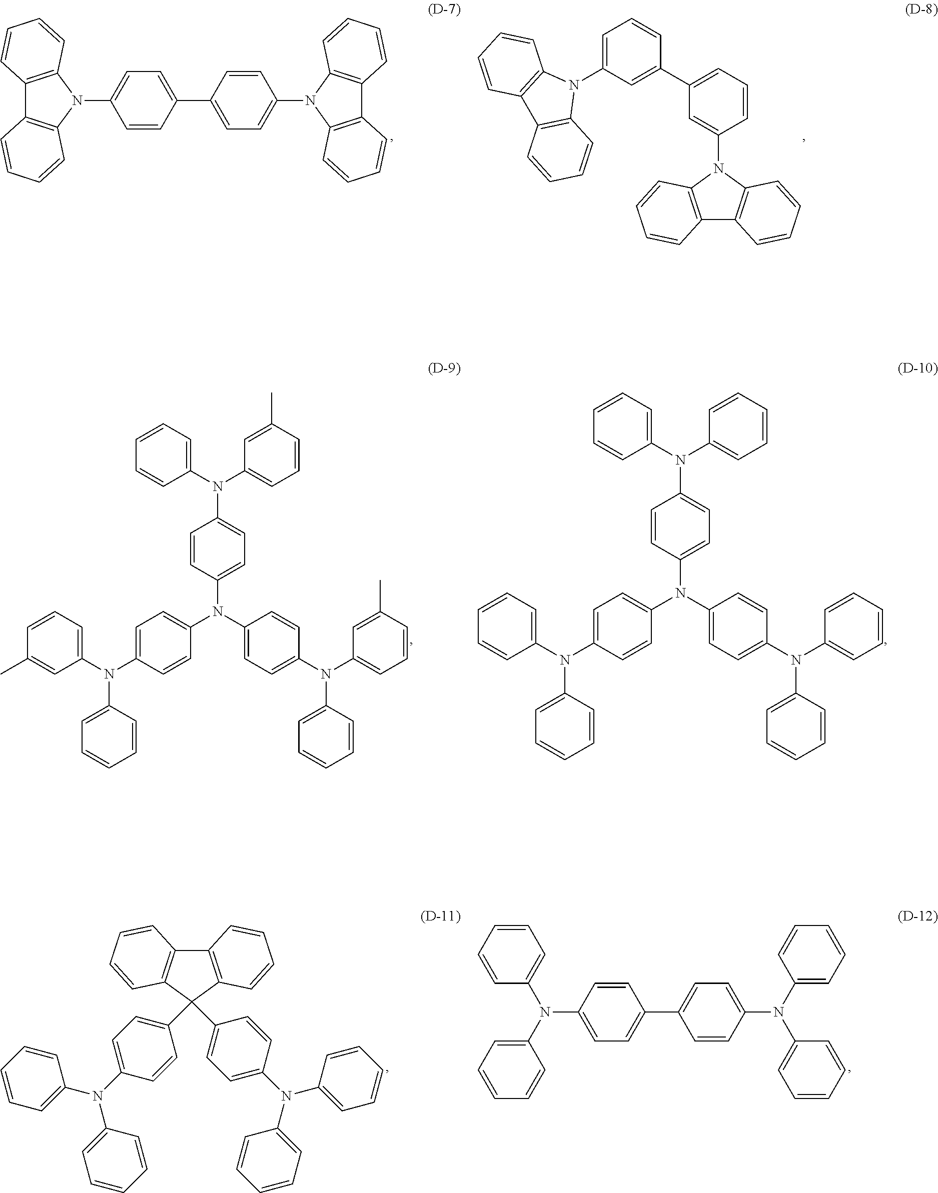 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccccc2)c2ccc(N(c3ccc(N(c4ccccc4)c4ccccc4)cc3)c3ccc(N(c4ccccc4)c4ccccc4)cc3)cc2)cc1 ; c1ccc(N(c2ccccc2)c2ccc(C3(c4ccc(N(c5ccccc5)c5ccccc5)cc4)c4ccccc4-c4ccccc43)cc2)cc1 ; c1ccc(N(c2ccccc2)c2ccc(-c3ccc(N(c4ccccc4)c4ccccc4)cc3)cc2)cc1]

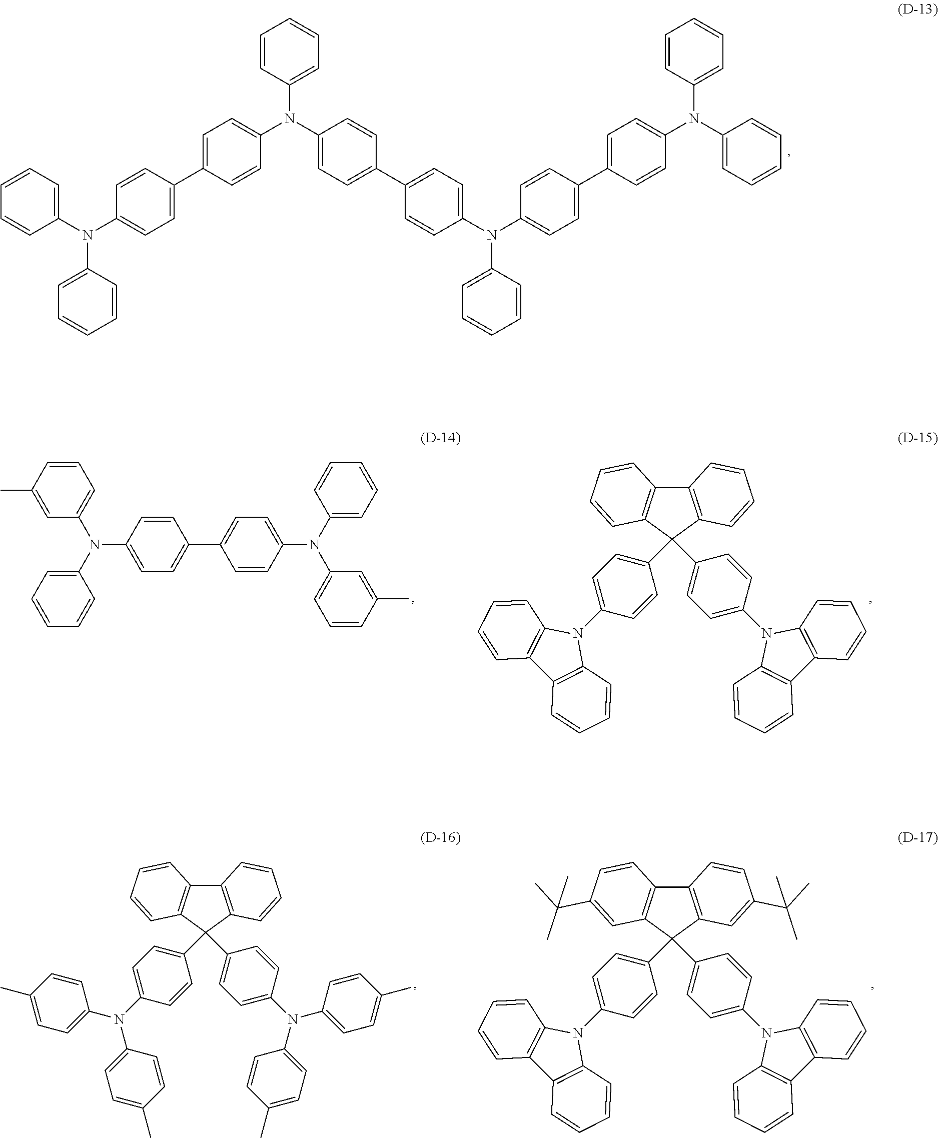

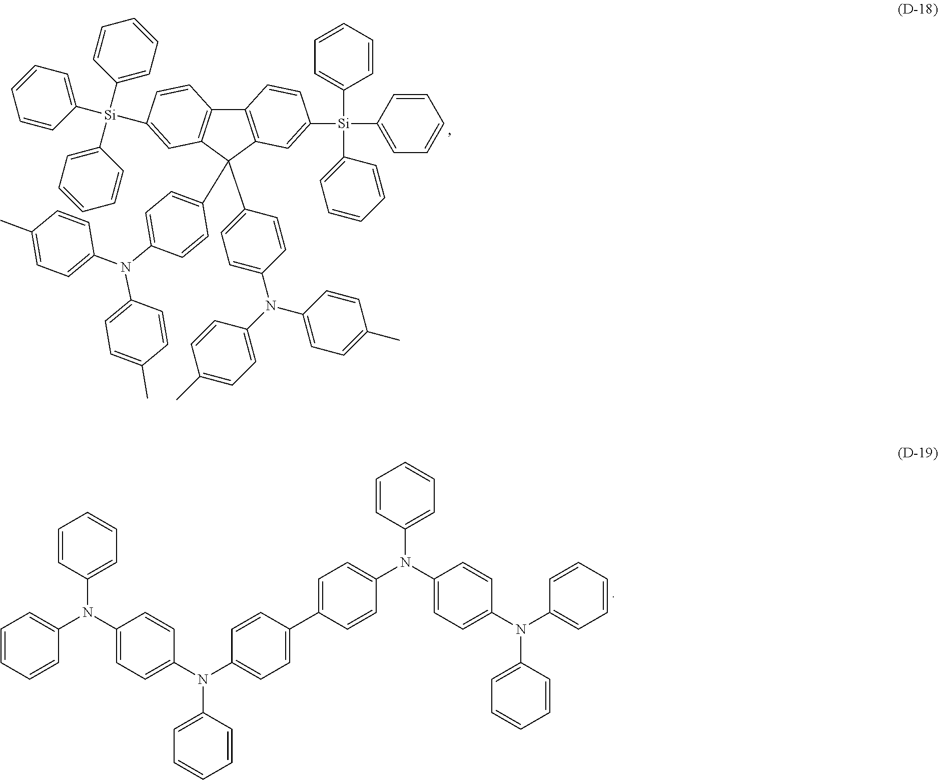 [SMILES: Cc1ccc(N(c2ccc(C)cc2)c2ccc(C3(c4ccc(N(c5ccc(C)cc5)c5ccc(C)cc5)cc4)c4cc([Si](c5ccccc5)(c5ccccc5)c5ccccc5)ccc4-c4ccc([Si](c5ccccc5)(c5ccccc5)c5ccccc5)cc43)cc2)cc1 ; c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1]

Where the electron acceptor type material is a compound having electron transport property containing at least one group of pyridyl, pyrimidyl, triazinyl, imidazolyl, o-phenanthrolinyl, sulfonyl, heptazinyl, oxadiazolyl, cyano, and diphenylphosphonyl.

Specifically, the electron acceptor type material may be, but is not limited to, a compound selected from one of the following structures:

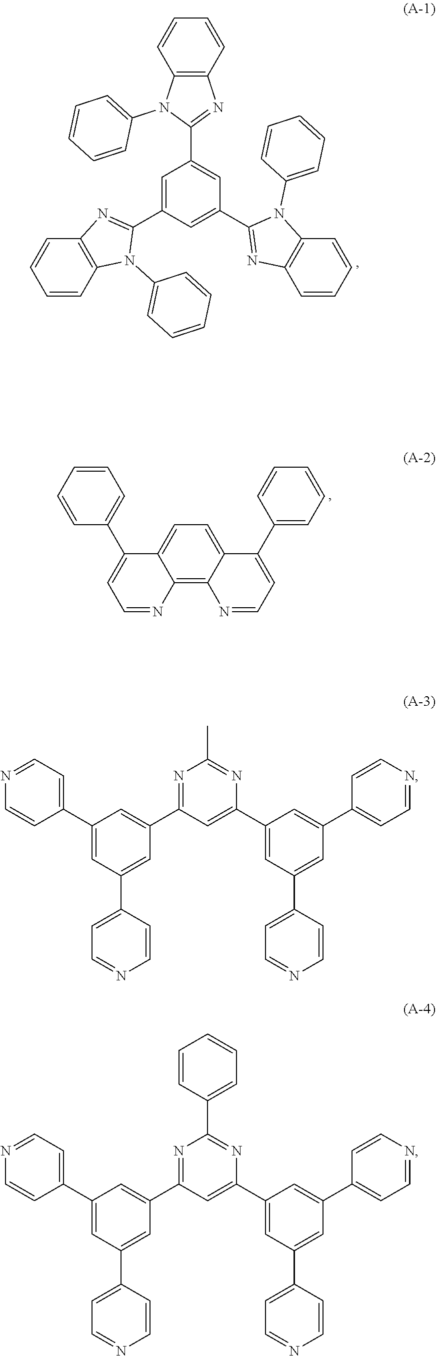 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2ccnc3c2ccc2c(-c4ccccc4)ccnc23)cc1 ; Cc1nc(-c2cc(-c3ccncc3)cc(-c3ccncc3)c2)cc(-c2cc(-c3ccncc3)cc(-c3ccncc3)c2)n1 ; c1ccc(-c2nc(-c3cc(-c4ccncc4)cc(-c4ccncc4)c3)cc(-c3cc(-c4ccncc4)cc(-c4ccncc4)c3)n2)cc1]

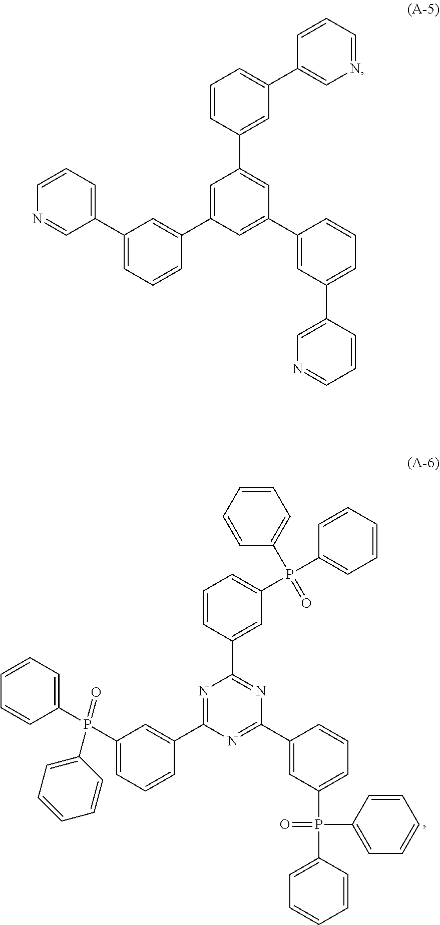 [SMILES: c1cncc(-c2cccc(-c3cc(-c4cccc(-c5cccnc5)c4)cc(-c4cccc(-c5cccnc5)c4)c3)c2)c1 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1]

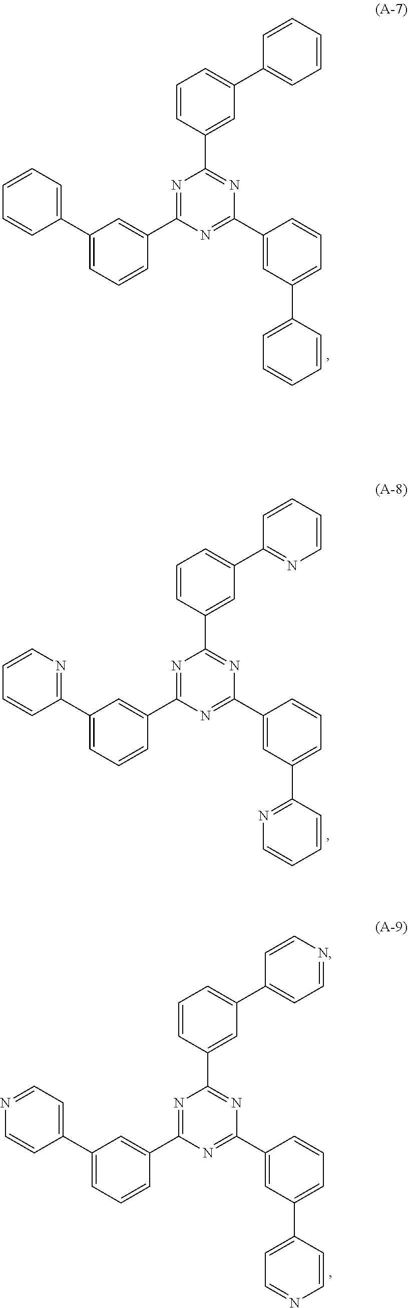 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4cccc(-c5ccccn5)c4)nc(-c4cccc(-c5ccccn5)c4)n3)c2)nc1 ; c1cc(-c2ccncc2)cc(-c2nc(-c3cccc(-c4ccncc4)c3)nc(-c3cccc(-c4ccncc4)c3)n2)c1]

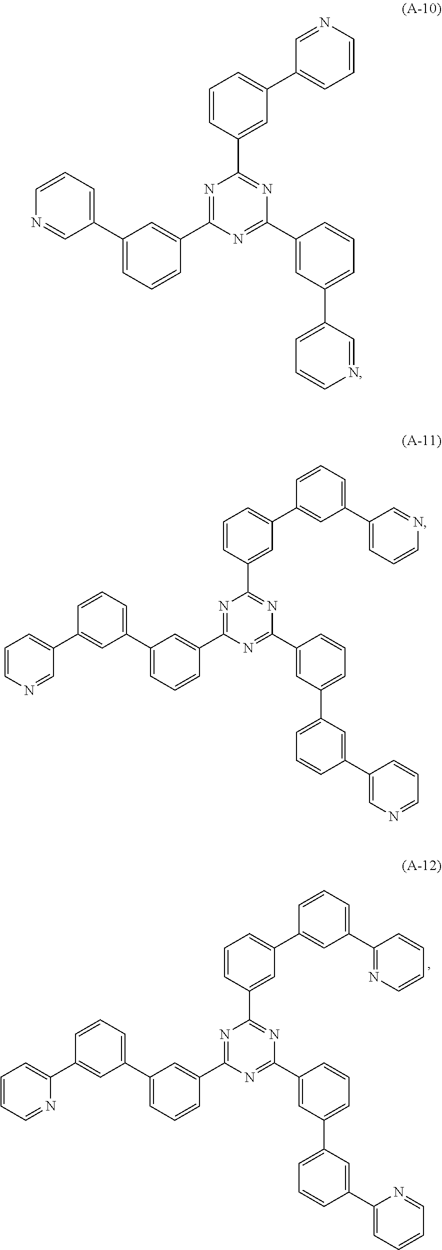 [SMILES: c1cncc(-c2cccc(-c3nc(-c4cccc(-c5cccnc5)c4)nc(-c4cccc(-c5cccnc5)c4)n3)c2)c1 ; c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1 ; c1ccc(-c2cccc(-c3cccc(-c4nc(-c5cccc(-c6cccc(-c7ccccn7)c6)c5)nc(-c5cccc(-c6cccc(-c7ccccn7)c6)c5)n4)c3)c2)nc1]

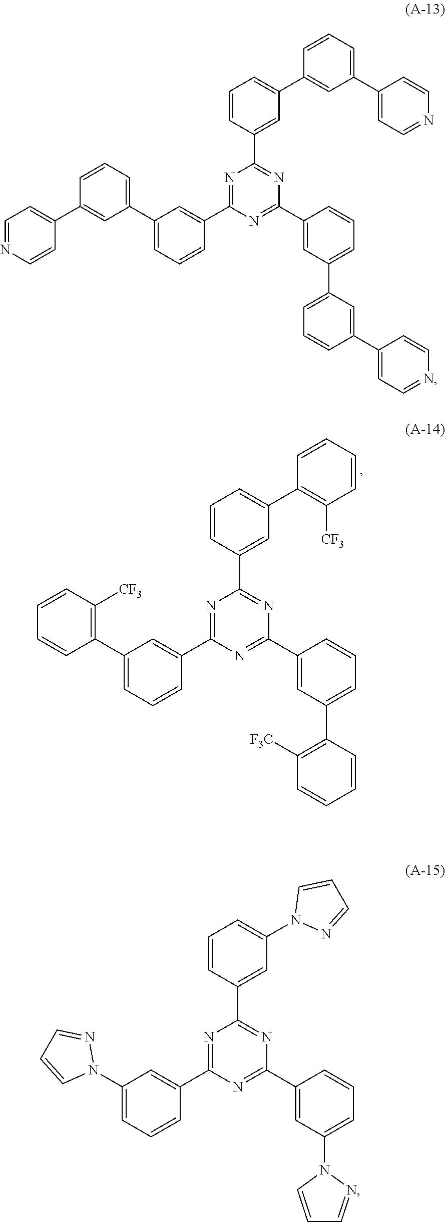 [SMILES: c1cc(-c2ccncc2)cc(-c2cccc(-c3nc(-c4cccc(-c5cccc(-c6ccncc6)c5)c4)nc(-c4cccc(-c5cccc(-c6ccncc6)c5)c4)n3)c2)c1 ; FC(F)(F)c1ccccc1-c1cccc(-c2nc(-c3cccc(-c4ccccc4C(F)(F)F)c3)nc(-c3cccc(-c4ccccc4C(F)(F)F)c3)n2)c1 ; c1cc(-c2nc(-c3cccc(-n4cccn4)c3)nc(-c3cccc(-n4cccn4)c3)n2)cc(-n2cccn2)c1]

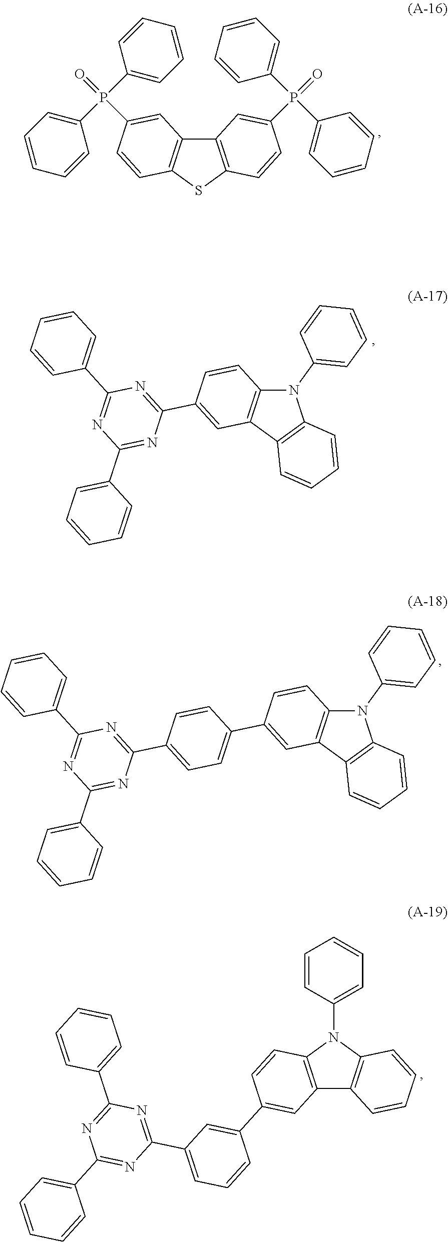 [SMILES: O=P(c1ccccc1)(c1ccccc1)c1ccc2sc3ccc(P(=O)(c4ccccc4)c4ccccc4)cc3c2c1 ; c1ccc(-c2nc(-c3ccccc3)nc(-c3ccc4c(c3)c3ccccc3n4-c3ccccc3)n2)cc1 ; c1ccc(-c2nc(-c3ccccc3)nc(-c3ccc(-c4ccc5c(c4)c4ccccc4n5-c4ccccc4)cc3)n2)cc1 ; c1ccc(-c2nc(-c3ccccc3)nc(-c3cccc(-c4ccc5c(c4)c4ccccc4n5-c4ccccc4)c3)n2)cc1]

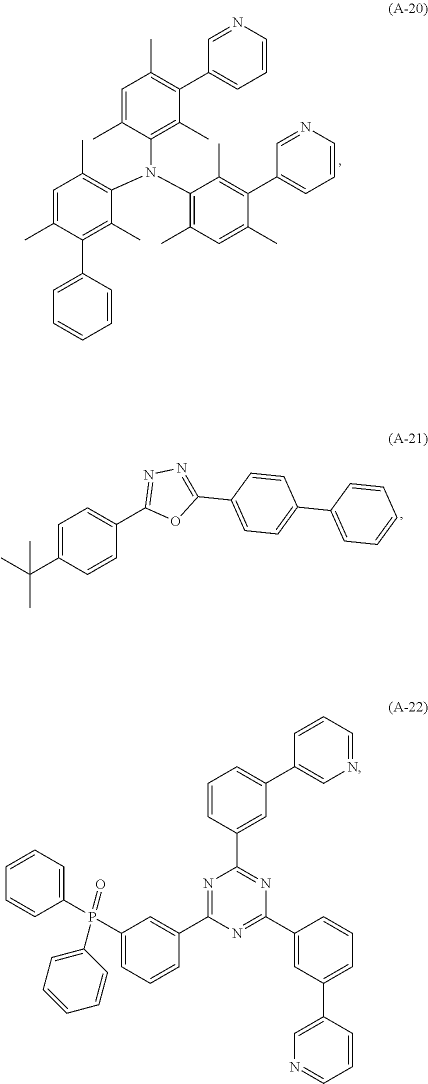 [SMILES: Cc1cc(C)c(N(c2c(C)cc(C)c(-c3cccnc3)c2C)c2c(C)cc(C)c(-c3cccnc3)c2C)c(C)c1-c1ccccc1 ; CC(C)(C)c1ccc(-c2nnc(-c3ccc(-c4ccccc4)cc3)o2)cc1 ; O=P(c1ccccc1)(c1ccccc1)c1cccc(-c2nc(-c3cccc(-c4cccnc4)c3)nc(-c3cccc(-c4cccnc4)c3)n2)c1]

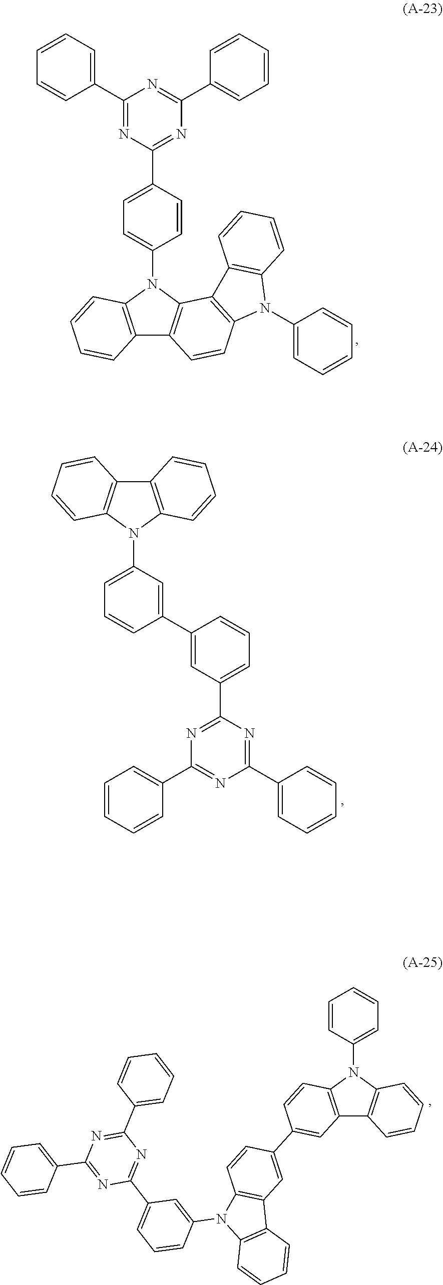 [SMILES: c1ccc(-c2nc(-c3ccccc3)nc(-c3ccc(-n4c5ccccc5c5ccc6c(c7ccccc7n6-c6ccccc6)c54)cc3)n2)cc1 ; c1ccc(-c2nc(-c3ccccc3)nc(-c3cccc(-c4cccc(-n5c6ccccc6c6ccccc65)c4)c3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

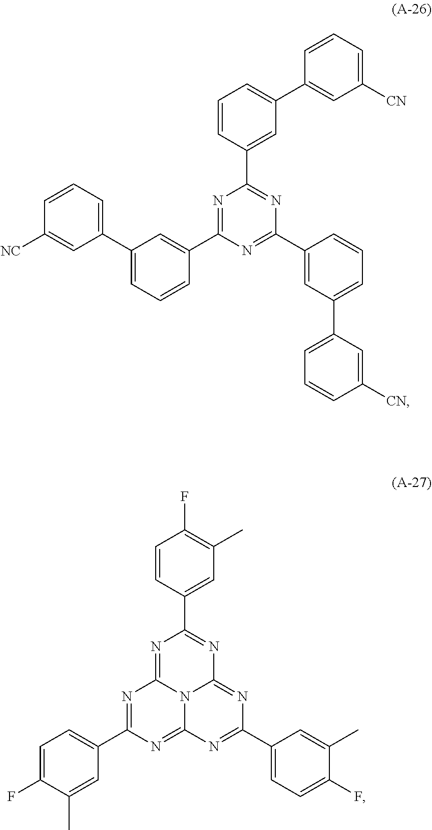 [SMILES: N#Cc1cccc(-c2cccc(-c3nc(-c4cccc(-c5cccc(C#N)c5)c4)nc(-c4cccc(-c5cccc(C#N)c5)c4)n3)c2)c1 ; Cc1cc(C2=NC3=NC(c4ccc(F)c(C)c4)=NC4=NC(c5ccc(F)c(C)c5)=NC(=N2)N34)ccc1F]

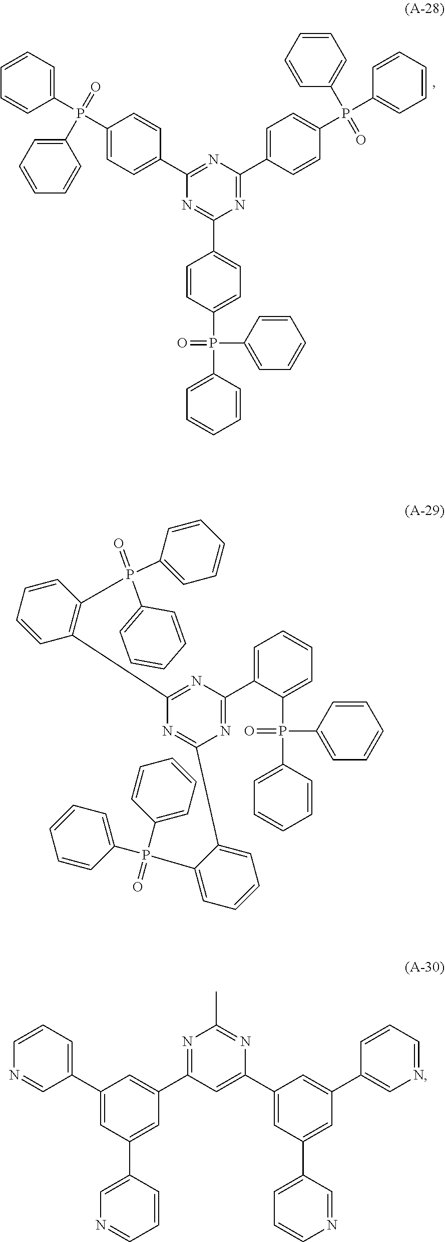 [SMILES: O=P(c1ccccc1)(c1ccccc1)c1ccc(-c2nc(-c3ccc(P(=O)(c4ccccc4)c4ccccc4)cc3)nc(-c3ccc(P(=O)(c4ccccc4)c4ccccc4)cc3)n2)cc1 ; O=P(c1ccccc1)(c1ccccc1)c1ccccc1-c1nc(-c2ccccc2P(=O)(c2ccccc2)c2ccccc2)nc(-c2ccccc2P(=O)(c2ccccc2)c2ccccc2)n1 ; Cc1nc(-c2cc(-c3cccnc3)cc(-c3cccnc3)c2)cc(-c2cc(-c3cccnc3)cc(-c3cccnc3)c2)n1]

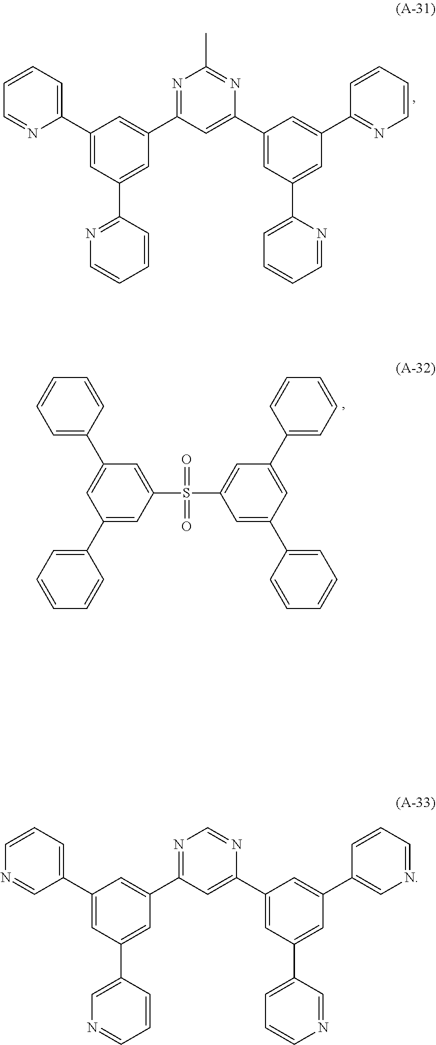 [SMILES: Cc1nc(-c2cc(-c3ccccn3)cc(-c3ccccn3)c2)cc(-c2cc(-c3ccccn3)cc(-c3ccccn3)c2)n1 ; O=S(=O)(c1cc(-c2ccccc2)cc(-c2ccccc2)c1)c1cc(-c2ccccc2)cc(-c2ccccc2)c1 ; c1cncc(-c2cc(-c3cccnc3)cc(-c3cc(-c4cc(-c5cccnc5)cc(-c5cccnc5)c4)ncn3)c2)c1]

In addition, in the exciplex, a mass ratio of the electron donor type material to the electron acceptor type material is 1:9 to 9:1. Under this doping ratio, transports of holes and carriers can be effectively balanced to achieve a bipolar transport effect, thereby optimizing the roll-off and lifetime of the device.

Still referring to FIG. 1, the hole transporting region 3, the electron transporting region 5, and the cathode 6 of the present application will be described. The hole transporting region 3 is located between the anode 2 and the organic light emitting layer 4. The hole transporting region 3 may be a single-layered hole transporting layer (HTL), including a single-layer hole transporting layer containing only one compound and a single-layer hole transporting layer containing a plurality of compounds. The hole transporting region 3 may also have a multilayer structure including at least two layers of a hole injection layer (HIL), a hole transport layer (HTL), and an electron blocking layer (EBL).

The material of the hole transporting region 3 (including HIL, HTL, and EBL) may be selected from, but not limited to, phthalocyanine derivatives such as CuPc, conductive polymers, or polymers containing conductive dopants such as polyphenylene vinylene, polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), polyaniline/poly(4-styrenesulfonate) (Pani/PSS), aromatic amine derivative.

Where the aromatic amine derivative is a compound represented by the following HT-1 to HT-34. If the material of the hole transporting region 3 is an aromatic amine derivative, it may be one or more of the compounds represented by HT-1 to HT-34:

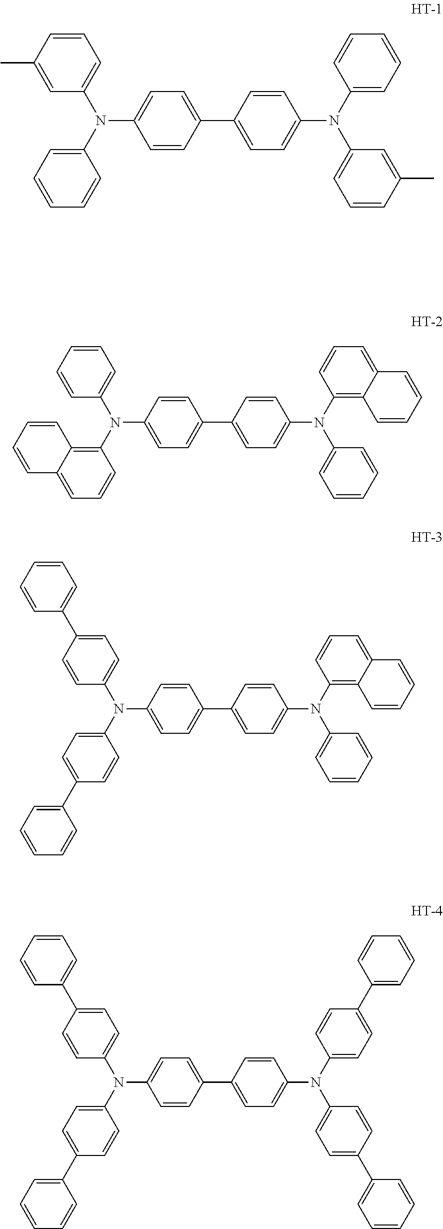

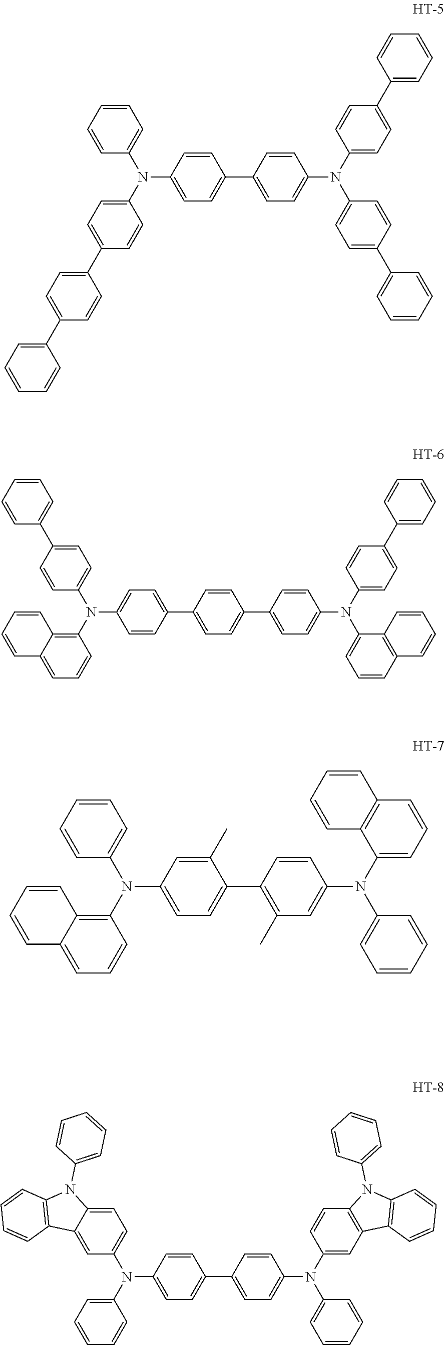 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

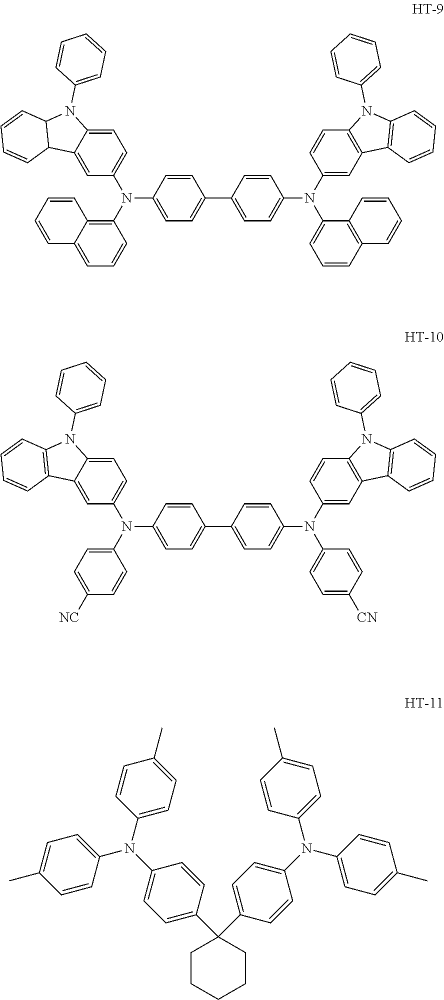

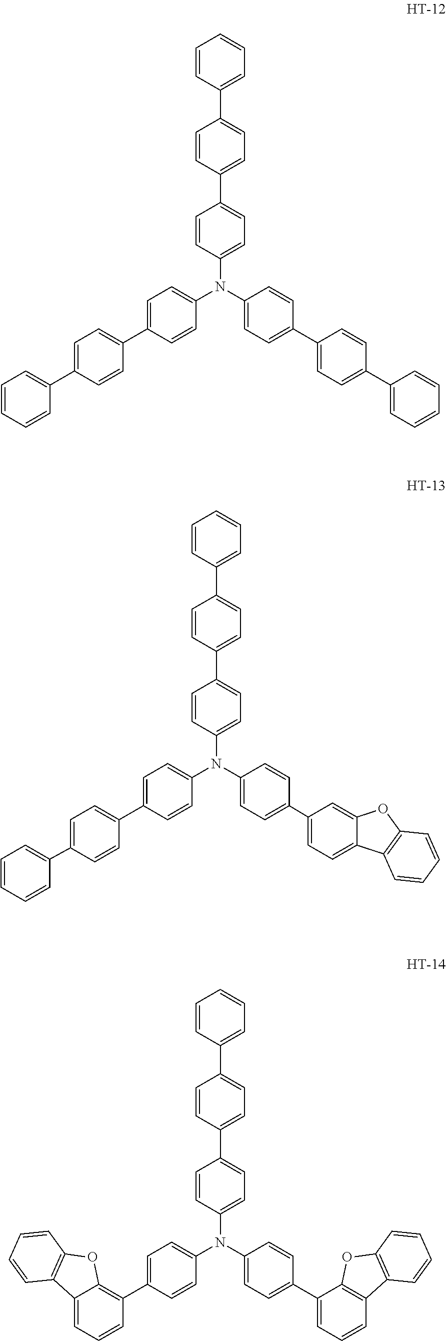 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

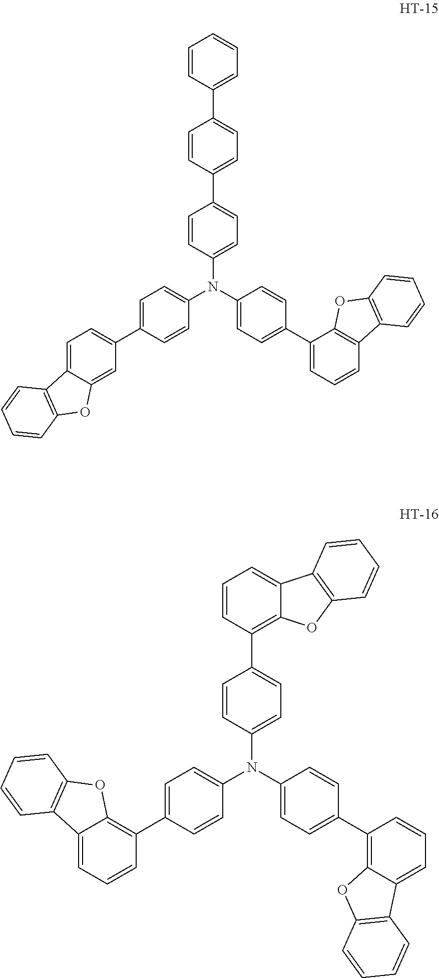 [SMILES: c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12]

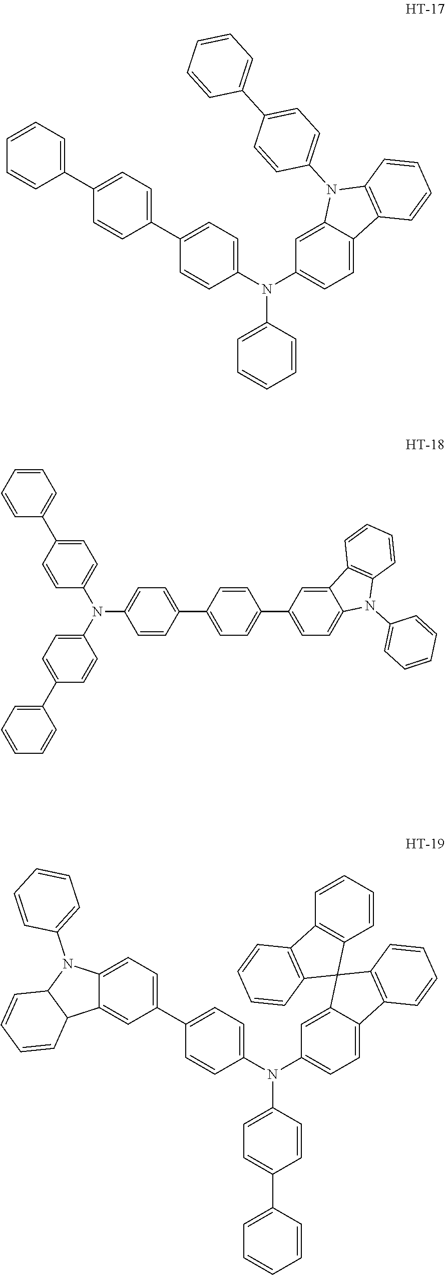 [SMILES: c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1]

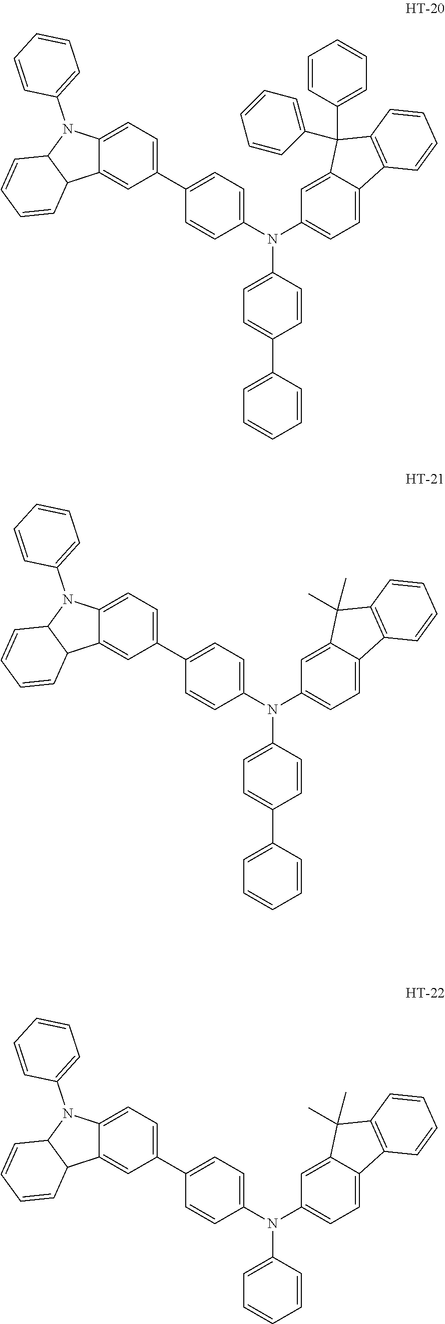 [SMILES: C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)C4C=CC=CC4N5c4ccccc4)cc3)cc21 ; CC1(C)c2ccccc2-c2ccc(N(c3ccccc3)c3ccc(-c4ccc5c(c4)C4C=CC=CC4N5c4ccccc4)cc3)cc21]

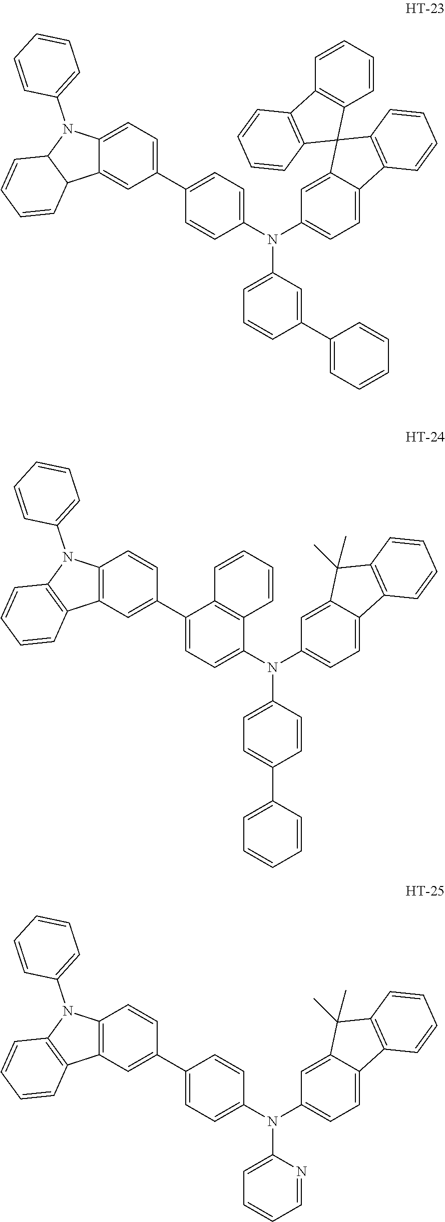 [SMILES: C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccccn3)cc21]

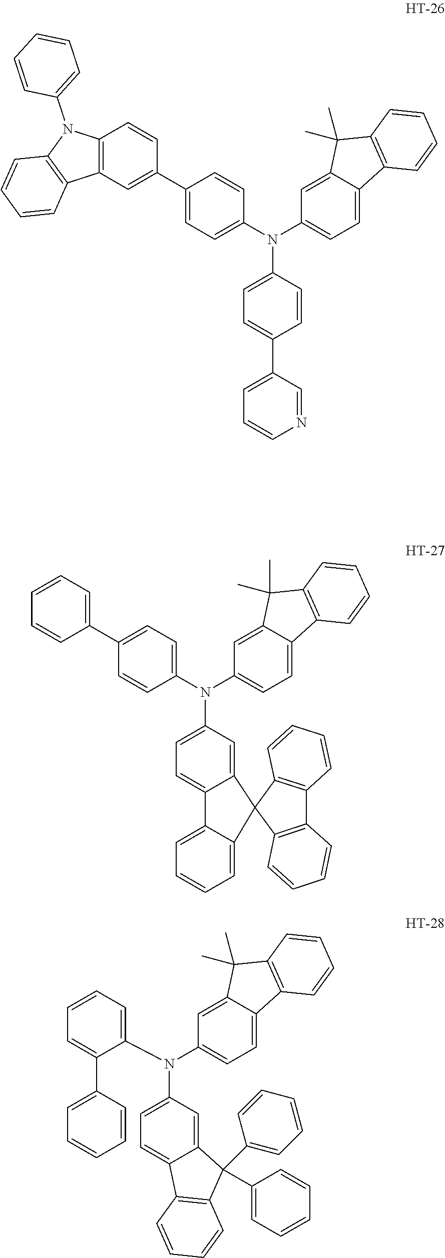

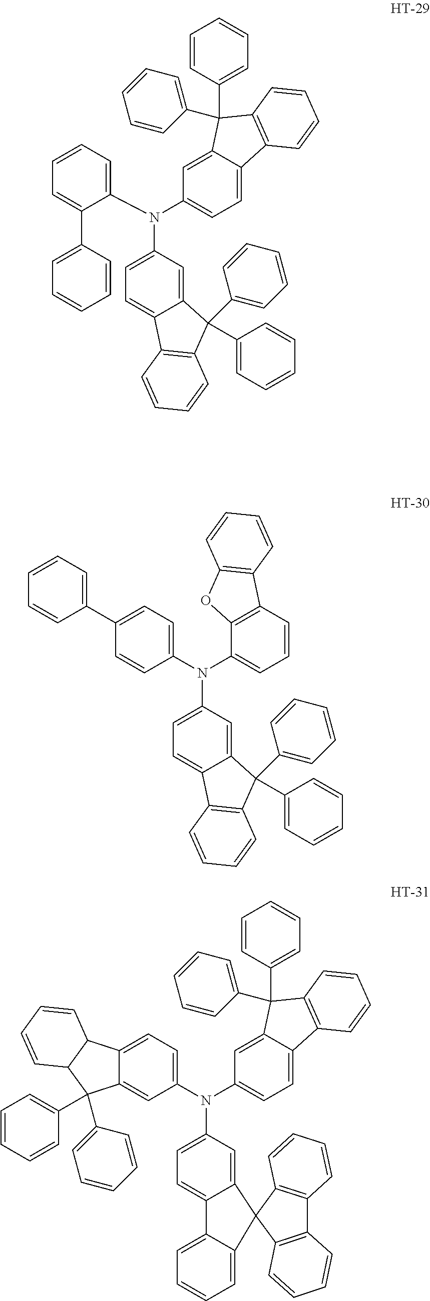 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3cccc4c3oc3ccccc34)cc2)cc1 ; C1=CC2c3ccc(N(c4ccc5c(c4)C(c4ccccc4)(c4ccccc4)c4ccccc4-5)c4ccc5c(c4)C4(c6ccccc6-c6ccccc64)c4ccccc4-5)cc3C(c3ccccc3)(c3ccccc3)C2C=C1]

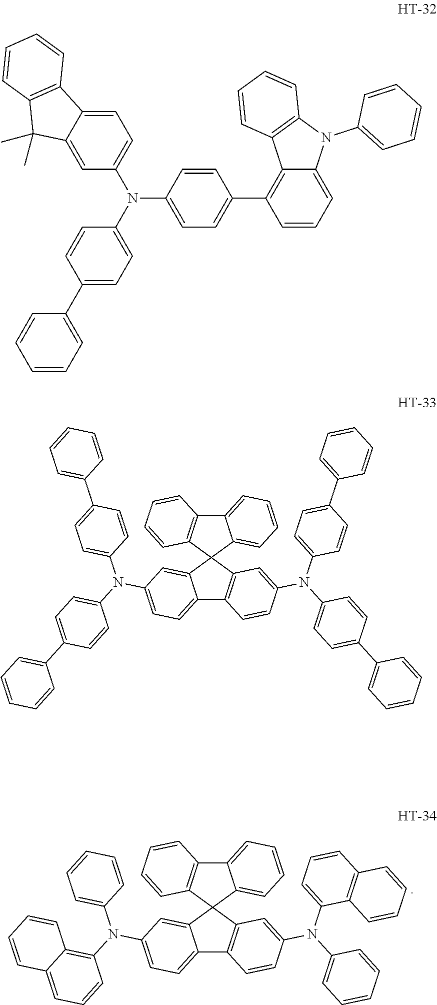 [SMILES: CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1]

The hole injection layer is located between the anode 2 and the hole transporting layer. The hole injection layer may be of a single compound material or a combination of a plurality of compounds. For example, the hole injection layer may use one or more compounds of the aforementioned HT-1 to HT-34, or one or more compounds of the following HI1-HI3; or it may use one or more compounds of HT-1 to HT-34 doping with one or more compounds of the following HI1-HI3:

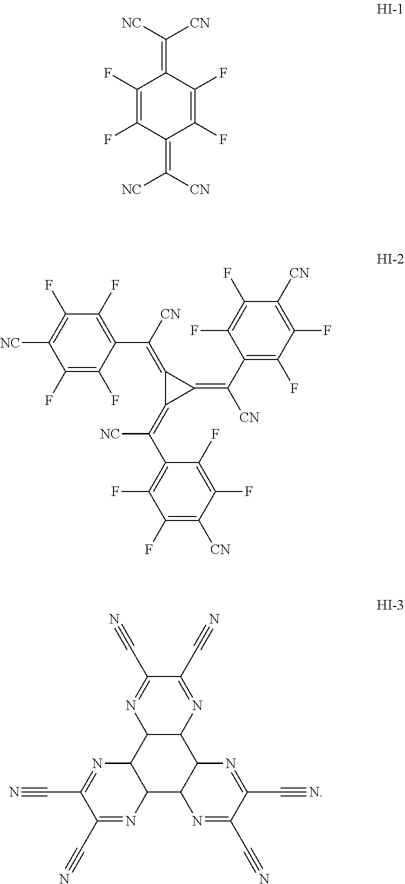 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC1=NC2C3N=C(C#N)C(C#N)=NC3C3N=C(C#N)C(C#N)=NC3C2N=C1C#N]

The electron transporting region 5 may be a single-layered electron transporting layer (ETL), including a single-layer electron transporting layer containing only one compound and a single-layer electron transporting layer containing a plurality of compounds. The electron transporting region 5 may have a multilayer structure including at least two of an electron injection layer (EIL), an electron transporting layer (ETL), and a hole blocking layer (HBL).

In one aspect of the present application, the material of the electron transporting layer may be selected from, but not limited to, one or a combination of more of ET-1 to ET-57 listed below:

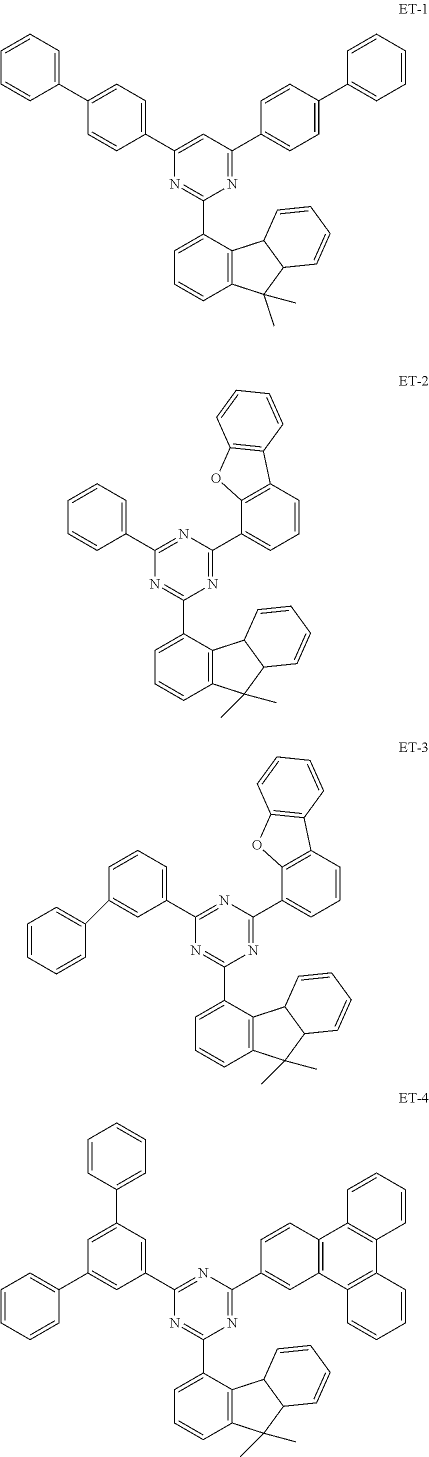 [SMILES: CC1(C)c2cccc(-c3nc(-c4ccc(-c5ccccc5)cc4)cc(-c4ccc(-c5ccccc5)cc4)n3)c2C2C=CC=CC21 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21 ; CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21]

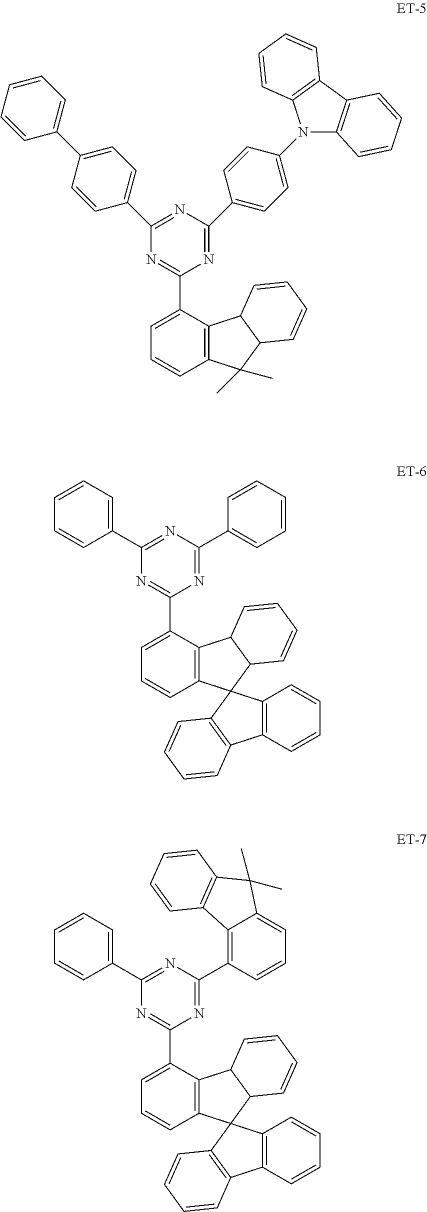 [SMILES: CC1(C)c2cccc(-c3nc(-c4ccc(-c5ccccc5)cc4)nc(-c4ccc(-n5c6ccccc6c6ccccc65)cc4)n3)c2C2C=CC=CC21 ; C1=CC2c3c(-c4nc(-c5ccccc5)nc(-c5ccccc5)n4)cccc3C3(c4ccccc4-c4ccccc43)C2C=C1 ; CC1(C)c2ccccc2-c2c(-c3nc(-c4ccccc4)nc(-c4cccc5c4C4C=CC=CC4C54c5ccccc5-c5ccccc54)n3)cccc21]

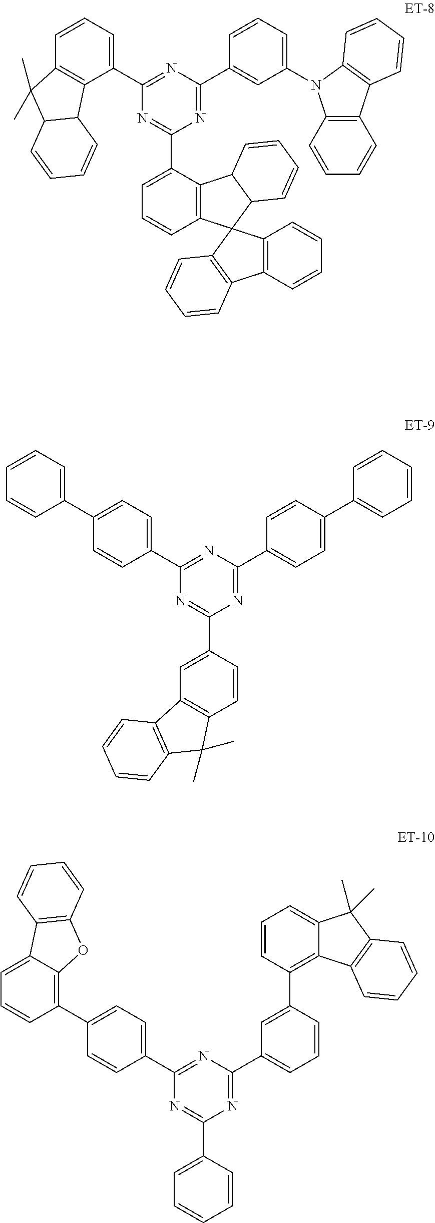 [SMILES: CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21]

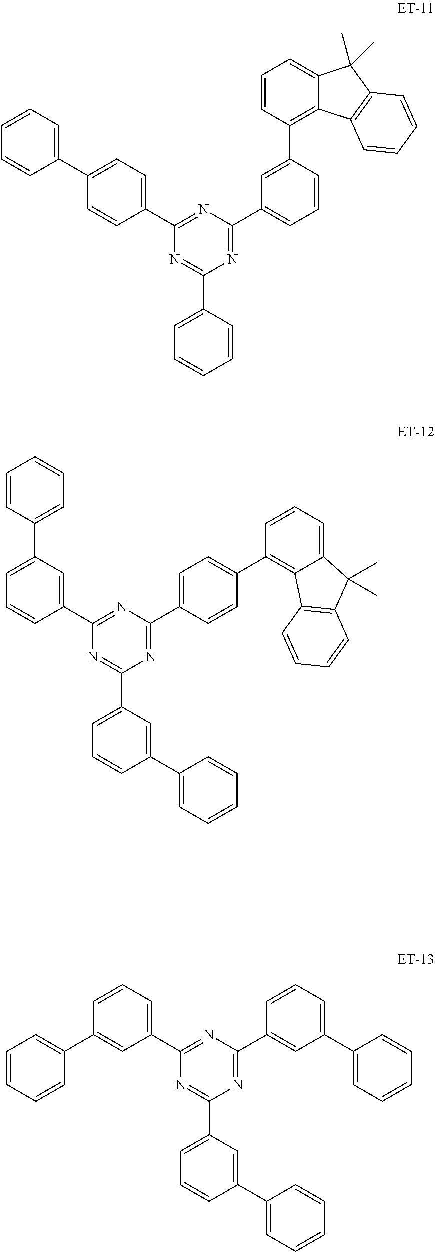 [SMILES: CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21 ; c1ccc(-c2cccc(-c3nc(-c4cccc(-c5ccccc5)c4)nc(-c4cccc(-c5ccccc5)c4)n3)c2)cc1]

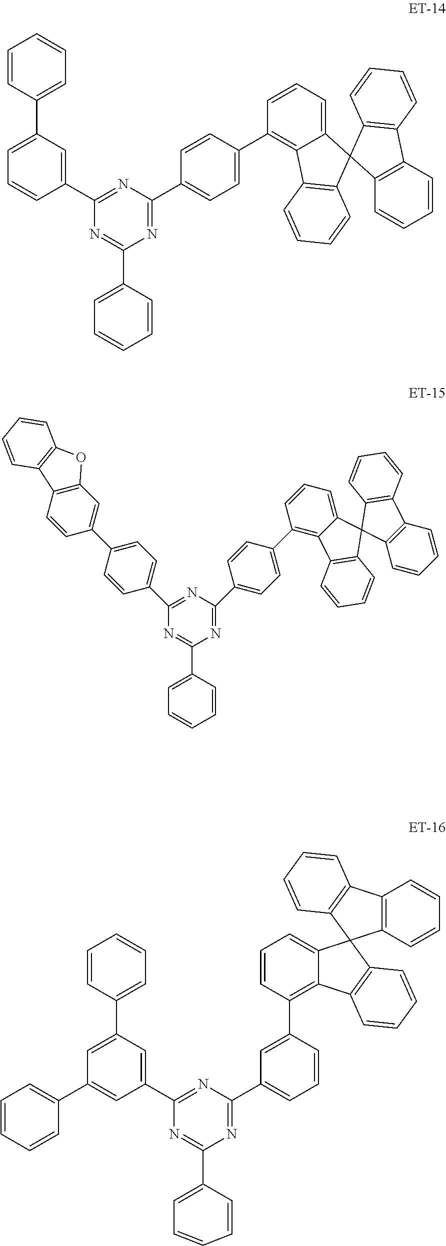 [SMILES: c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1]

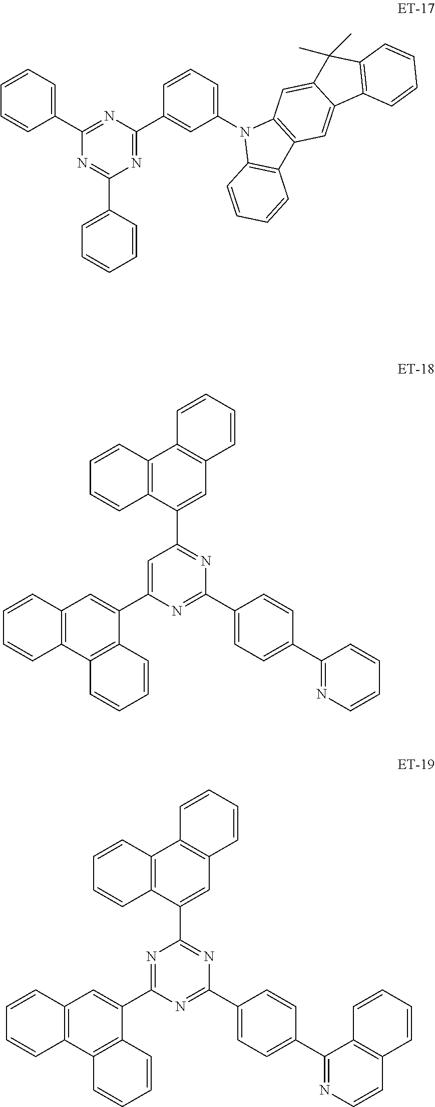 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1 ; c1ccc2c(-c3ccc(-c4nc(-c5cc6ccccc6c6ccccc56)nc(-c5cc6ccccc6c6ccccc56)n4)cc3)nccc2c1]

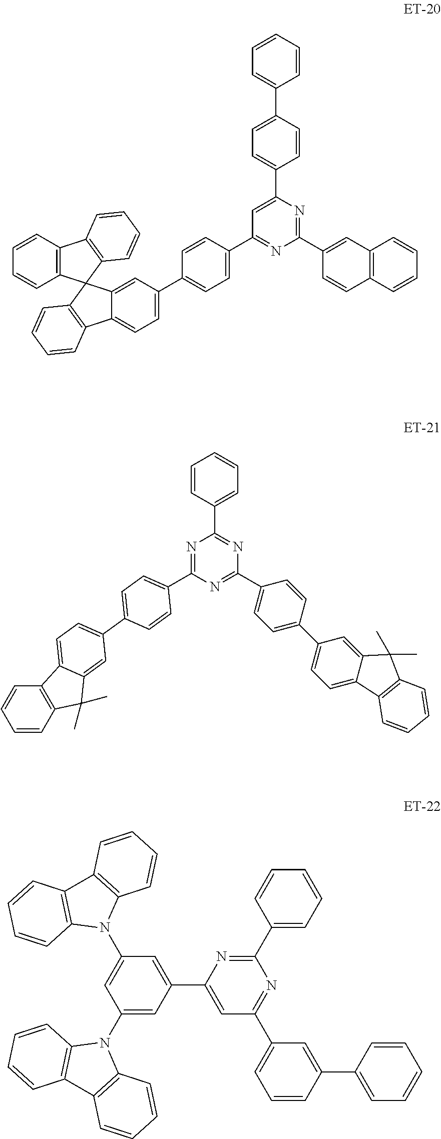 [SMILES: c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

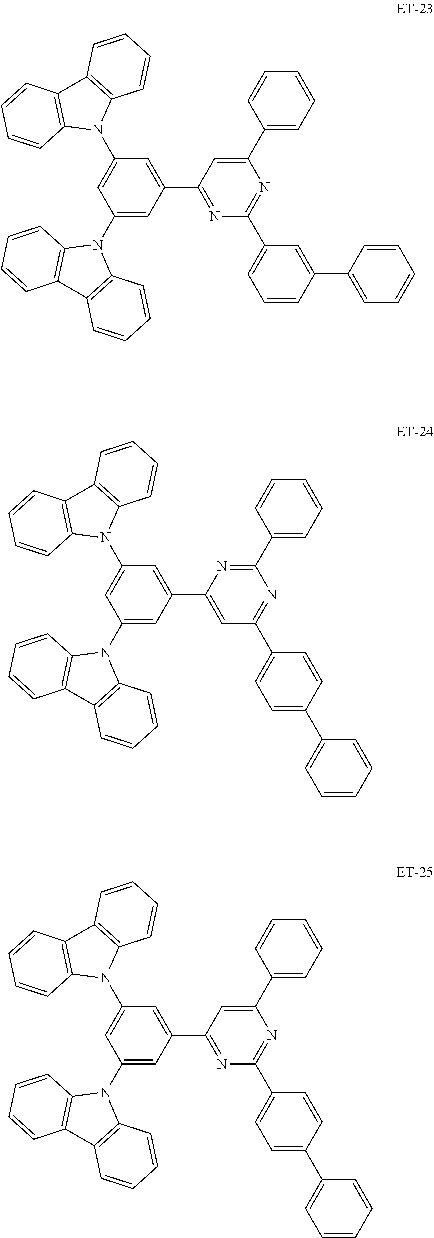 [SMILES: c1ccc(-c2cccc(-c3nc(-c4ccccc4)cc(-c4cc(-n5c6ccccc6c6ccccc65)cc(-n5c6ccccc6c6ccccc65)c4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2ccc(-c3nc(-c4ccccc4)cc(-c4cc(-n5c6ccccc6c6ccccc65)cc(-n5c6ccccc6c6ccccc65)c4)n3)cc2)cc1]

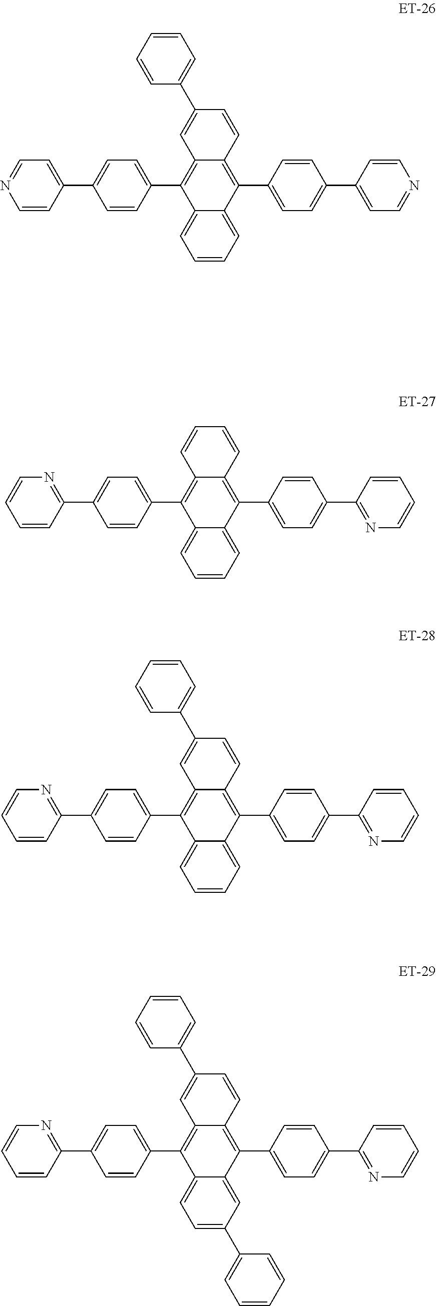 [SMILES: c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1 ; c1ccc(-c2ccc3c(-c4ccc(-c5ccccn5)cc4)c4cc(-c5ccccc5)ccc4c(-c4ccc(-c5ccccn5)cc4)c3c2)cc1]

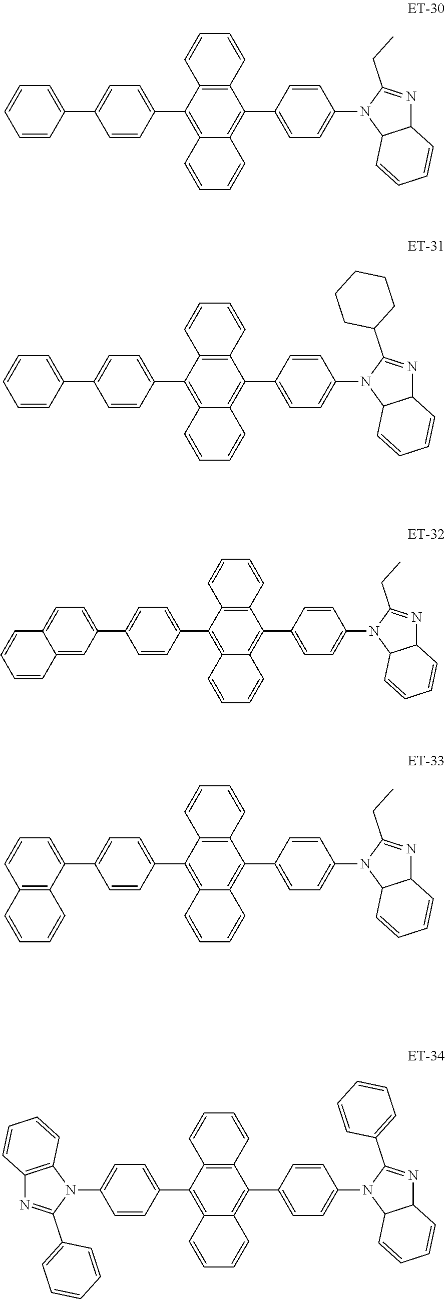 [SMILES: CCC1=NC2C=CC=CC2N1c1ccc(-c2c3ccccc3c(-c3ccc(-c4ccccc4)cc3)c3ccccc23)cc1 ; C1=CC2N=C(C3CCCCC3)N(c3ccc(-c4c5ccccc5c(-c5ccc(-c6ccccc6)cc5)c5ccccc45)cc3)C2C=C1 ; CCC1=NC2C=CC=CC2N1c1ccc(-c2c3ccccc3c(-c3ccc(-c4ccc5ccccc5c4)cc3)c3ccccc23)cc1 ; CCC1=NC2C=CC=CC2N1c1ccc(-c2c3ccccc3c(-c3ccc(-c4cccc5ccccc45)cc3)c3ccccc23)cc1 ; C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1]

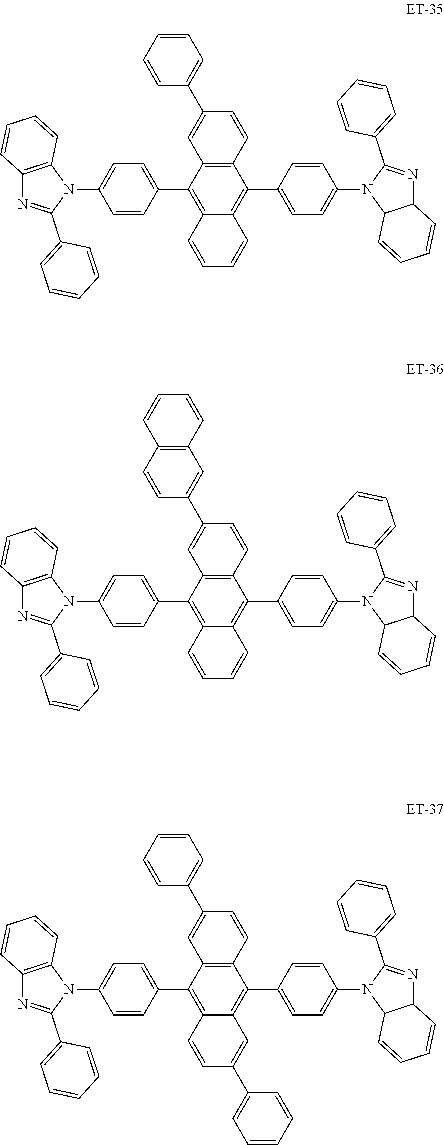 [SMILES: C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1]

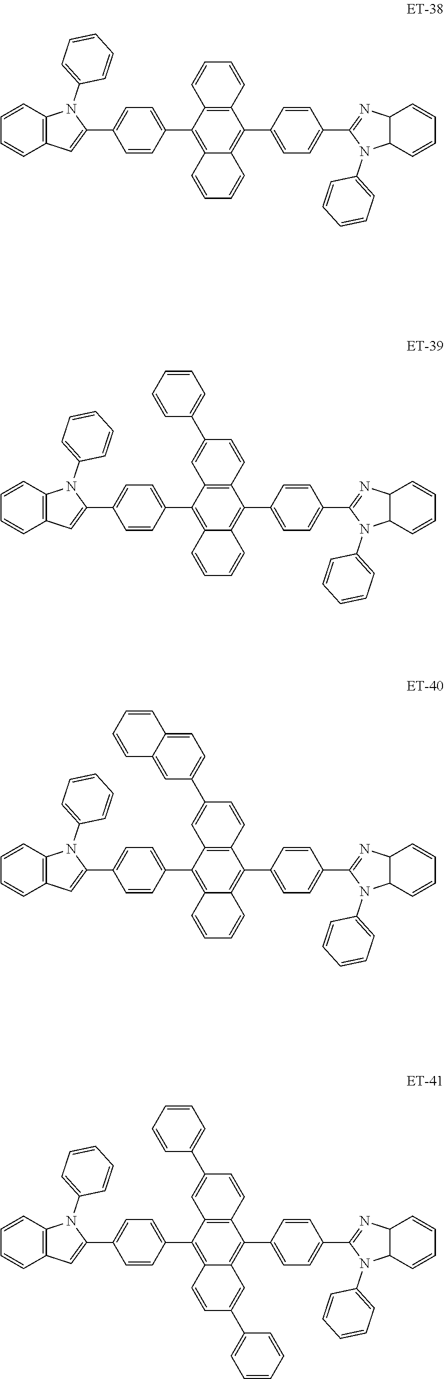 [SMILES: C1=CC2N=C(c3ccc(-c4c5ccccc5c(-c5ccc(-c6cc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6cc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6cc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6cc7ccccc7n6-c6ccccc6)cc5)c5ccc(-c6ccccc6)cc45)cc3)N(c3ccccc3)C2C=C1]

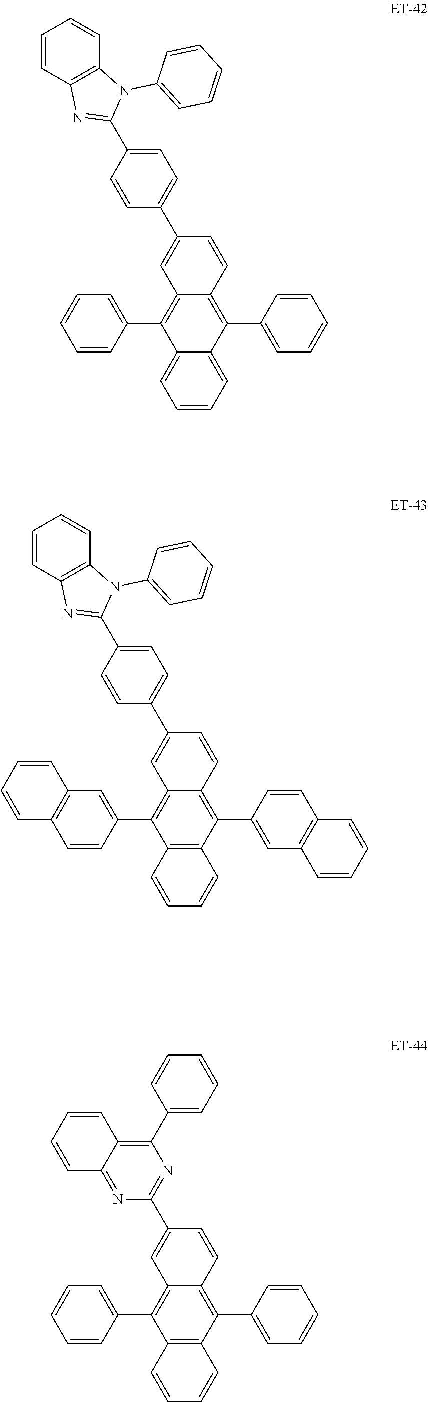 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc(-c3ccc4c(-c5ccccc5)c5ccccc5c(-c5ccccc5)c4c3)nc3ccccc23)cc1]

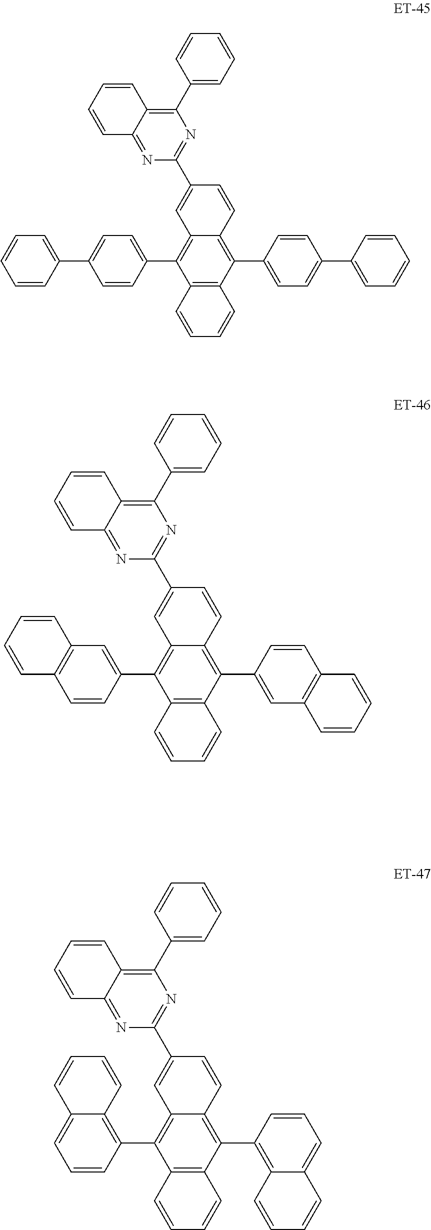 [SMILES: c1ccc(-c2ccc(-c3c4ccccc4c(-c4ccc(-c5ccccc5)cc4)c4cc(-c5nc(-c6ccccc6)c6ccccc6n5)ccc34)cc2)cc1 ; c1ccc(-c2nc(-c3ccc4c(-c5ccc6ccccc6c5)c5ccccc5c(-c5ccc6ccccc6c5)c4c3)nc3ccccc23)cc1 ; c1ccc(-c2nc(-c3ccc4c(-c5cccc6ccccc56)c5ccccc5c(-c5cccc6ccccc56)c4c3)nc3ccccc23)cc1]

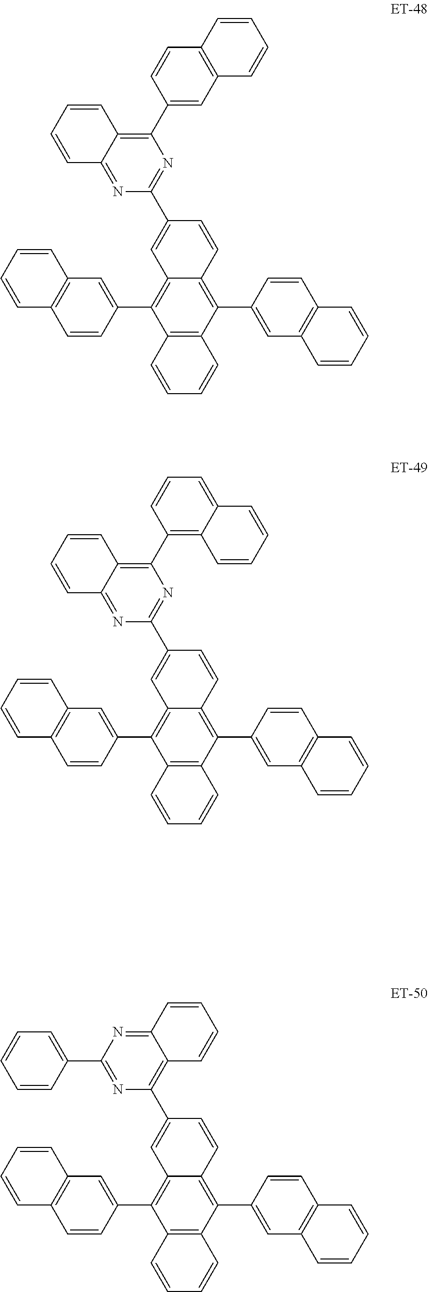 [SMILES: c1ccc2cc(-c3nc(-c4ccc5c(-c6ccc7ccccc7c6)c6ccccc6c(-c6ccc7ccccc7c6)c5c4)nc4ccccc34)ccc2c1 ; c1ccc2cc(-c3c4ccccc4c(-c4ccc5ccccc5c4)c4cc(-c5nc(-c6cccc7ccccc67)c6ccccc6n5)ccc34)ccc2c1 ; c1ccc(-c2nc(-c3ccc4c(-c5ccc6ccccc6c5)c5ccccc5c(-c5ccc6ccccc6c5)c4c3)c3ccccc3n2)cc1]

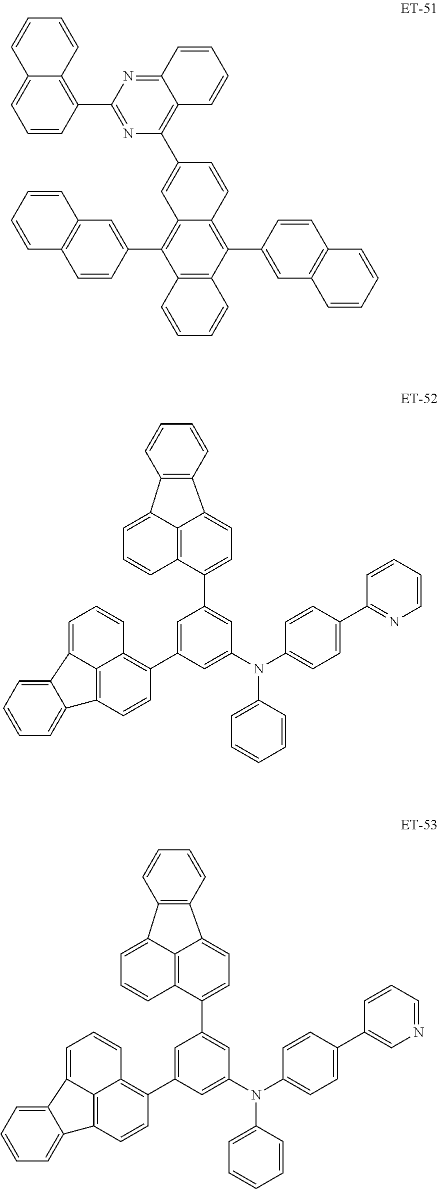 [SMILES: c1ccc2cc(-c3c4ccccc4c(-c4ccc5ccccc5c4)c4cc(-c5nc(-c6cccc7ccccc67)nc6ccccc56)ccc34)ccc2c1 ; c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1]

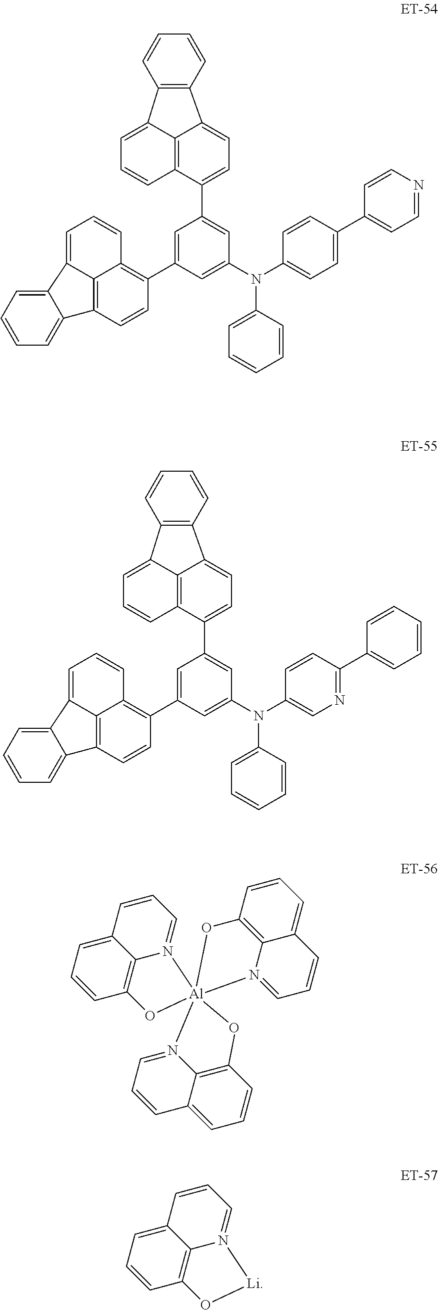

The structure of the organic electroluminescent device may further include an electron injection layer located between the electron transporting layer and the cathode 6, and the material of the electron injection layer includes, but is not limited to, one or a combination of more of the listed below:

LiQ, LiF, NaCl, CsF, Li₂O, Cs₂CO₃, BaO, Na, Li, and Ca.

Thicknesses of the above-mentioned layers can adopt conventional thicknesses of these layers in the art.

The present application also provides a preparation method of the organic electroluminescent device. Taking FIG. 1 as an example, the method includes sequentially depositing an anode 2, a hole transporting region 3, an organic light emitting layer 4, an electron transporting region 5, and a cathode 6 on a substrate 1, then encapsulating them. Where when preparing the organic light emitting layer 4, the organic light emitting layer 4 is formed by a co-evaporation method of an electron donor type material source, an electron acceptor type material source, and a resonance-type TADF material source.

Specifically, the preparation method of the organic electroluminescent device of the present application includes the following steps:

1. sonicating a glass plate coated with an anode material in a commercial cleaning agent, rinsing in deionized water, ultrasonically degreasing in a mixed solvent of acetone: ethanol, and baking in a clean environment to completely remove water, cleaning with UV light and ozone and performing a surface bombardment with a low-energy cation beam;

2. placing the above glass plate with an anode in a vacuum chamber, and evacuating to 1×10⁻⁵˜9×10⁻³ Pa, and vacuum-evaporating a hole injection layer on this anode layer film with an evaporation rate of 0.1-0.5 nm/s;

3. vacuum-evaporating a hole transporting layer on the hole injection layer with an evaporation rate of 0.1-0.5 nm/s;

4. vacuum-evaporating an organic light emitting layer of the device on the hole transporting layer, the organic light emitting layer including a host material and a resonance-type TADF dye, and using a multi-source co-evaporation method to adjust an evaporation rate of the host material and an evaporation rate of the dye so that the dye reaches a preset doping ratio;

5. vacuum-evaporating a material of an electron transporting layer of the device on the organic light emitting layer with an evaporation rate of 0.1-0.5 nm/s;

6. vacuum-evaporating LiF as an electron injection layer on the electron transporting layer at an evaporation rate of 0.1-0.5 nm/s, and vacuum-evaporating an Al layer as a cathode of the device at an evaporation rate of 0.5-1 nm/s.

An embodiment of the present application further provides a display apparatus, including the organic electroluminescent device provided as described above. The display apparatus may specifically be a display device such as an OLED display, and any product or component including the display device and having a display function, such as a television, a digital camera, a mobile phone, a tablet computer, etc. This display apparatus has the same advantages as the above-mentioned organic electroluminescent device over the prior art, and is not repeated here.

The organic electroluminescent device of the present application is further described below by specific embodiments.

Embodiment 1

The device of the present embodiment has a structure as follows:

ITO/HI-2 (10 nm)/HT-27 (40 nm)/(D-1:A-6=1:9):20 wt %M-20 (30 nm)/ET-53 (30 nm)/LiF (0.5 nm)/Al(150 nm)

Where the anode is ITO; the material of the hole injection layer is HI-2, and the total thickness is generally 5-30 nm, and specifically is 10 nm in the present embodiment; the material of the hole transporting layer is HT-27, and the total thickness is generally 5-50 nm, and specifically is 40 nm in the present embodiment; the host material of the organic light emitting layer is an exciplex, where a mass ratio of D-1 to A-6 is 1:9, and the dye is a resonance-type TADF material M-20 with a doping concentration of 20 wt %, the thickness of the organic light emitting layer is generally 1-60 nm, and specifically is 30 nm in the present embodiment; the material of the electron transporting layer is ET-53, with a thickness of generally 5-30 nm, and specifically 30 nm in the present embodiment; materials of the electron injection layer and the cathode are LiF (0.5 nm) and metal aluminum (150 nm).

In addition, an energy level difference ΔE_{ST} between the singlet state and triplet state of the host material and an energy level difference ΔE_{ST} between the singlet state and triplet state of the resonance-type TADF dye are shown in Table 1.

Embodiment 2

The device of the present embodiment has a structure as follows:

ITO/HI-2 (10 nm)/HT-27 (40 nm)/(D-1:A-6=4:6):20 wt % M-20 (30 nm)/ET-53 (30 nm)/LiF (0.5 nm)/Al (150 nm)

Embodiment 3

The device of the present embodiment has a structure as follows:

ITO/HI-2 (10 nm)/HT-27 (40 nm)/(D-1:A-6=5:5):20 wt % M-20 (30 nm)/ET-53 (30 nm)/LiF (0.5 nm)/Al (150 nm)

Embodiment 4

The device of the present embodiment has a structure as follows:

ITO/HI-2 (10 nm)/HT-27 (40 nm)/(D-1:A-6=6:4):20 wt % M-20 (30 nm)/ET-53 (30 nm)/LiF (0.5 nm)/Al (150 nm)

Embodiment 5

The device of the present embodiment has a structure as follows:

ITO/HI-2 (10 nm)/HT-27 (40 nm)/(D-1:A-6=1:9):35 wt % M-20 (30 nm)/ET-53 (30 nm)/LiF (0.5 nm)/Al (150 nm)

Embodiment 6

The device of the present embodiment has a structure as follows:

ITO/HI-2 (10 nm)/HT-27 (40 nm)/(D-1:A-10=2:8):17 wt % M-24 (30 nm)/ET-53 (30 nm)/LiF (0.5 nm)/Al (150 nm)

Embodiment 7

The device of the present embodiment has a structure as follows:

ITO/HI-2 (10 nm)/HT-27 (40 nm)/(D-16:A-11=3:7):0.6 wt % M-20 (30 nm)/ET-53 (30 nm)/LiF (0.5 nm)/Al (150 nm)

Embodiment 8

The device of the present embodiment has a structure as follows:

ITO/HI-2 (10 nm)/HT-27 (40 nm)/(D-2:A-11=5:5):40 wt % M-32 (30 nm)/ET-53 (30 nm)/LiF (0.5 nm)/Al (150 nm)

Embodiment 9

The device of the present embodiment has a structure as follows:

ITO/HI-2 (10 nm)/HT-27 (40 nm)/(D-1:A-13=4.5:5.5):1 wt % M-32 (30 nm)/ET-53 (30 nm)/LiF (0.5 nm)/Al (150 nm)

Embodiment 10

The device of the present embodiment has a structure as follows:

ITO/HI-2 (10 nm)/HT-27 (40 nm)/(D-1:A-17=9:1):5 wt % M-40 (30 nm)/ET-53 (30 nm)/LiF (0.5 nm)/Al (150 nm)

Embodiment 11

The device of the present embodiment has a structure as follows:

ITO/HI-2 (10 nm)/HT-27 (40 nm)/(D-3:A-26=6:4):25 wt % M-44 (30 nm)/ET-53 (30 nm)/LiF (0.5 nm)/Al (150 nm)

Embodiment 12

The device of the present embodiment has a structure as follows:

ITO/HI-2 (10 nm)/HT-27 (40 nm)/(D-9:A-28=5.5:4.5):30 wt % M-62 (30 nm)/ET-53 (30nm)/LiF (0.5 nm)/Al (150 nm)

Embodiment 13

The device of the present embodiment has a structure as follows:

ITO/HI-2 (10 nm)/HT-27 (40 nm)/(D-18:A-31=5.5:4.5):10 wt % M-72 (30 nm)/ET-53 (30 nm)/LiF (0.5 nm)/Al (150 nm)

Embodiment 14

The device of the present embodiment has a structure as follows:

ITO/HI-2 (10 nm)/HT-27 (40 nm)/(D-9:A-14=5.5:4.5):6 wt % M-16 (30 nm)/ET-53 (30 nm)/LiF (0.5 nm)/Al (150 nm)

Embodiment 15

The device of the present embodiment has a structure as follows:

ITO/HI-2 (10 nm)/HT-27 (40 nm)/(D-13:A-18=5.5:4.5):12 wt % M-20 (30 nm)/ET-53 (30 nm)/LiF (0.5 nm)/Al (150 nm)

Embodiment 16

The device of the present embodiment has a structure as follows:

ITO/HI-2 (10 nm)/HT-27 (40 nm)/(D-17:A-33=5.5:4.5):15 wt % M-28 (30 nm)/ET-53 (30 nm)/LiF (0.5 nm)/Al (150 nm)

Embodiment 17

The device of the present embodiment has a structure as follows:

ITO/HI-2 (10 nm)/HT-27 (40 nm)/(D-18:A-17=5.5:4.5):8 wt % M-54 (30 nm)/ET-53 (30 nm)/LiF (0.5 nm)/Al (150 nm)

Embodiment 18

The device of the present embodiment has a structure as follows:

ITO/HI-2 (10 nm)/HT-27 (40 nm)/(D-9:A-31=5.5:4.5):9 wt % M-56 (30 nm)/ET-53 (30 nm)/LiF (0.5 nm)/Al (150 nm)

Embodiment 19

The device of the present embodiment has a structure as follows:

ITO/HI-2 (10 nm)/HT-27 (40 nm)/(D-13:A-30=5.5:4.5):10 wt % M-66 (30 nm)/ET-53 (30 nm)/LiF (0.5 nm)/Al (150 nm)

Embodiment 20

The device of the present embodiment has a structure as follows:

ITO/HI-2 (10 nm)/HT-27 (40 nm)/(D-17:A-31=5.5:4.5):5 wt % M-71 (30 nm)/ET-53 (30 nm)/LiF (0.5 nm)/Al (150 nm)

Comparative Example 1

The device of this present Comparative Example has a structure as follows:

ITO/HI-2 (10 nm)/HT-27 (40 nm)/D-1:10 wt % M-20 (30 nm)/ET-53 (30 nm)/LiF (0.5 nm)/Al (150 nm)

Comparative Example 2

The device of this present Comparative Example has a structure as follows:

ITO/HI-2 (10 nm)/HT-27 (40 nm)/D-1:50 wt % A-6 (30 nm)/ET-53 (30 nm)/LiF (0.5 nm)/Al (150 nm)

Comparative Example 3

The device of this present Comparative Example has a structure as follows:

ITO/HI-2 (10 nm)/HT-27 (40 nm)/D-2:10 wt % M-32 (30 nm)/ET-53 (30 nm)/LiF (0.5 nm)/Al (150 nm)

Comparative Example 4

The device structure of this Comparative Example is shown below:

ITO/HI-2 (10 nm)/HT-27 (40 nm)/D-2:20 wt % A-11=5:5) (30 nm)/ET-53 (30 nm)/LiF (0.5 nm)/Al (150 nm)

Comparative Example 5

The device of this present Comparative Example has a structure as follows:

ITO/HI-2 (10 nm)/HT-27 (40 nm)/A-15:10 wt % M-20 (30 nm)/ET-53 (30 nm)/LiF (0.5nm)/Al (150 nm)

Comparative Example 6

The device structure of this Comparative Example is shown below:

ITO/HI-2 (10 nm)/HT-27 (40 nm)/A-18:10 wt % M-32 (30 nm)/ET-53 (30 nm)/LiF (0.5nm)/Al (150 nm)

Comparative Example 7

The device of this present Comparative Example has a structure as follows:

ITO/HI-2 (10 nm)/HT-27 (40 nm)/(D-2:A-11=5:5):58 wt % M-40 (30 nm)/ET-53 (30 nm)/LiF (0.5 nm)/Al (150 nm)

Comparative Example 8

The device of this present Comparative Example has a structure as follows:

ITO/HI-2 (10 nm)/HT-27 (40 nm)/(D-2:A-11=5:5):78 wt % M-32 (30 nm)/ET-53 (30 nm)/LiF (0.5 nm)/Al (150 nm)

Comparative Example 9

The device of this present Comparative Example has a structure as follows:

ITO/HI-2 (10 nm)/HT-27 (40 nm)/(D-15:A-23=5:5):10 wt % M-32 (30 nm)/ET-53 (30 nm)/LiF (0.5 nm)/Al (150 nm)

Comparative Example 10

The device of this present Comparative Example has a structure as follows:

ITO/HI-2 (10 nm)/HT-27 (40 nm)/(D-15:A-24=5:5):10 wt % M-32 (30 nm)/ET-53 (30 nm)/LiF (0.5 nm)/Al (150 nm)

TABLE 1

| | Δ E_{ST} of the | Δ E_{ST} |
|---|---|---|
| | host material | of the dye |
| Embodiment 1 | 0.02 eV | 0.11 eV |
| Embodiment 2 | 0.02 eV | 0.11 eV |
| Embodiment 3 | 0.02 eV | 0.11 eV |
| Embodiment 4 | 0.02 eV | 0.11 eV |
| Embodiment 5 | 0.02 eV | 0.11 eV |
| Embodiment 6 | 0.05 eV | 0.12 eV |
| Embodiment 7 | 0.10 eV | 0.11 eV |
| Embodiment 8 | 0.08 eV | 0.20 eV |
| Embodiment 9 | 0.08 eV | 0.20 eV |
| Embodiment 10 | 0.04 eV | 0.21 eV |
| Embodiment 11 | 0.01 eV | 0.08 eV |
| Embodiment 12 | 0.13 eV | 0.13 eV |
| Embodiment 13 | 0.14 eV | 0.14 eV |
| Embodiment 14 | 0.08 eV | 0.22 eV |
| Embodiment 15 | 0.10 eV | 0.11 eV |
| Embodiment 16 | 0.05 eV | 0.19 eV |
| Embodiment 17 | 0.12 eV | 0.21 eV |
| Embodiment 18 | 0.12 eV | 0.20 eV |
| Embodiment 19 | 0.13 eV | 0.14 eV |
| Embodiment 20 | 0.14 eV | 0.12 eV |
| Comparative Example 7 | 0.08 eV | 0.21 eV |
| Comparative Example 8 | 0.08 eV | 0.20 eV |
| Comparative Example 9 | 0.21 eV | 0.20 eV |
| Comparative Example 10 | 0.25 eV | 0.20 eV |

Test Example

1. The following performance measurements were performed on the organic electroluminescent devices (Embodiments 1-20, Comparative Examples 1-10) prepared by the above process: current, voltage, brightness, luminescence spectrum, current efficiency, and external quantum efficiency and other characteristics of the devices are tested synchronously with a PR 655 spectral scanning luminance meter and a Keithley K 2400 digital source meter system, and the lifetime is tested by MC-6000.

2. The lifetime test of LT90 is as follows: by setting different test brightness, a brightness and lifetime decay curve of the organic electroluminescent device is obtained, so as to obtain a lifetime value of the device under the required decay brightness. That is, set the test brightness to 5000 cd/m², maintain a constant current, and measure the time for the brightness of the organic electroluminescent device to decrease to 4500 cd/m², in hours.

The above specific test results are shown in Table 2.

TABLE 2

| | | Dye and | Maximum external | External quantum | | | |
|---|---|---|---|---|---|---|---|
| | | doping | quantum | efficiency at | Efficiency | Half-peak | |
| | Host material | concentration | efficiency/100% | 5000 cd/m²/100% | roll-off | width | LT90²/h |
| Embodiment 1 | D-1:A-6 = 1:9 | 20 wt % M-20 | 17.7 | 16.8 | 9.7% | 38 | 80 |
| Embodiment 2 | D-1:A-6 = 4:6 | 20 wt % M-20 | 18.5 | 17.8 | 9.5% | 38 | 87 |
| Embodiment 3 | D-1:A-6 = 5:5 | 20 wt % M-20 | 19.1 | 17.8 | 7.9% | 38 | 105 |
| Embodiment 4 | D-1:A-6 = 6:4 | 20 wt % M-20 | 18.7 | 17.1 | 9.9% | 38 | 85 |
| Embodiment 5 | D-1:A-6 = 1:9 | 35 wt % M-20 | 18.4 | 16.5 | 11.1% | 38 | 89 |
| Embodiment 6 | D-1:A-10 = 2:8 | 17 wt % M-24 | 17.3 | 16.2 | 10.7% | 36 | 73 |
| Embodiment 7 | D-16:A-11 = 3:7 | 0.6 wt % M-20 | 20.3 | 18.9 | 12.3% | 38 | 70 |
| Embodiment 8 | D-2:A-11 = 5:5 | 40 wt % M-32 | 21.4 | 19.6 | 11.8% | 35 | 75 |
| Embodiment 9 | D-1:A-13 = 4.5:5.5 | 1 wt % M-32 | 19.3 | 16.5 | 14.5% | 35 | 100 |
| Embodiment | D-1:A-17 = 9:1 | 5 wt % M-40 | 19.2 | 16.8 | 12.5% | 32 | 121 |
| 10 | | | | | | | |
| Embodiment | D-3:A-26 = 6:4 | 25 wt % M-44 | 21.1 | 19.3 | 12.9% | 36 | 90 |
| 11 | | | | | | | |
| Embodiment | D-9:A-28 = 5.5:4.5 | 30 wt % M-62 | 21.8 | 19.1 | 14.3% | 34 | 85 |
| 12 | | | | | | | |
| Embodiment | D-18:A-31 = 5.5:4.5 | 10 wt % M-72 | 17.6 | 15.8 | 10.2% | 37 | 91 |
| 13 | | | | | | | |
| Embodiment | D-9:A-14 = 5.5:4.5 | 6 wt % M-16 | 18.6 | 16.4 | 9.5% | 37 | 85 |
| 14 | | | | | | | |
| Embodiment | D-13:A-18 = 5.5:4.5 | 12 wt % M-20 | 18.1 | 16.3 | 10.2% | 39 | 83 |
| 15 | | | | | | | |
| Embodiment | D-17:A-33 = 5.5:4.5 | 15 wt % M-28 | 17.4 | 15.9 | 11.8% | 40 | 77 |
| 16 | | | | | | | |
| Embodiment | D-18:A-17 = 5.5:4.5 | 8 wt % M-54 | 19.3 | 17.6 | 12.9% | 39 | 76 |
| 17 | | | | | | | |
| Embodiment | D-9:A-31 = 5.5:4.5 | 9 wt % M-56 | 20.1 | 18.3 | 13.2% | 37 | 90 |
| 18 | | | | | | | |
| Embodiment | D-13:A-30 = 5.5:4.5 | 10 wt % M-66 | 17.9 | 15.6 | 11.8% | 40 | 87 |
| 19 | | | | | | | |
| Embodiment | D-17:A-31 = 5.5:4.5 | 5 wt % M-71 | 18.0 | 16.6 | 10.6% | 38 | 91 |
| 20 | | | | | | | |
| Comparative | D-1 | 10 wt % M-20 | 16.9 | 12.1 | 28.6% | 40 | 48 |
| Example 1 | | | | | | | |
| Comparative | D-1 | 50 wt % A-6 | 13.5 | 9.9 | 26.1% | 78 | 20 |
| Example 2 | | | | | | | |
| Comparative | D-2 | 10 wt % M-32 | 18.1 | 13.2 | 27.2% | 39 | 39 |
| Example 3 | | | | | | | |
| Comparative | D-2 | 20 wt % A-11 | 11.9 | 9.7 | 18.9% | 82 | 12 |
| Example 4 | | | | | | | |
| Comparative | A-15 | 10 wt % M-20 | 17.9 | 13.4 | 25.2% | 39 | 48 |
| Example 5 | | | | | | | |
| Comparative | A-18 | 10 wt % M-32 | 19.8 | 14.0 | 29.5% | 40 | 36 |
| Example 6 | | | | | | | |
| Comparative | D-2:A-11 = 5:5 | 58 wt % M-40 | 18.3 | 15.5 | 17.1% | 35 | 54 |
| Example 7 | | | | | | | |
| Comparative | D-2:A-11 = 5:5 | 78 wt % M-32 | 18.7 | 15.8 | 15.6% | 35 | 52 |
| Example 8 | | | | | | | |
| Comparative | D-15:A-23 = 5:5 | 10 wt % M-32 | 18.5 | 15.6 | 15.8% | 36 | 43 |
| Example 9 | | | | | | | |
| Comparative | D-15:A-24 = 5:5 | 10 wt % M-32 | 17.4 | 14.6 | 16.0% | 35 | 39 |
| Example 10 | | | | | | | |

It can be seen from Table 2:

1. Compared with Comparative Examples 1-10, the technical solution provided in the present application, i.e., the organic electroluminescent device when the organic light emitting layer is an exciplex as a host material and a resonance-type TADF as a dye, has a small efficiency roll-off under high brightness, and a narrow half-peak width, and thus shows better color purity. At the same time, the device has a long lifetime, and its overall characteristics are significantly better than those of the Comparative Examples 1-10;

2. According to Embodiments 1-4, it can be seen that when a mass ratio of the electron donor type material to the electron acceptor type material in the exciplex is 1:9 to 9:1, the device has good performances in roll-off, lifetime and peak width; and when the mass ratio of the electron donor type material and the electron acceptor type material is 1:1, the performances are better;

3. According to the comparison between Comparative Examples 7-8 and Embodiments 1-20, it can be known that the ratio of the host material in the organic light emitting layer of the present application is 1 wt % -99 wt %, and the ratio of the resonance-type thermally activated delayed fluorescence material in the organic light emitting layer is 0.1 wt %-50 wt %, the device has better performances in roll-off, lifetime, and peak width;

4. According to the comparison between Comparative Examples 9-10 and Embodiments 1-20, it can be seen that when the energy level difference between the singlet and triplet states of the exciplex of the present application is less than or equal to 0.15 eV, the organic electroluminescent device has a small efficiency roll-off under high brightness, a narrow half-peak width and a better color purity, and a long device lifetime.

Finally, it should be noted that the above embodiments are only used to describe technical solutions of the present application, rather than limiting them present. Although the present application has been described in detail with reference to the foregoing embodiments, those skilled in the art should understand that: the technical solutions described in the foregoing embodiments may still be modified, or some or all of the technical features therein may be equivalently replaced; and these modifications or replacements do not deviate the essence of the corresponding technical solutions from the scope of the technical solutions of the embodiments of the present application.

What is claimed is:

1. An organic electroluminescent device, comprising: an organic light emitting layer, wherein the organic light emitting layer comprises a host material and a resonance-type thermally activated delayed fluorescence material;
the host material is an exciplex;
a singlet energy level of the exciplex is greater than a singlet energy level of the resonance-type thermally activated delayed fluorescence material, and a triplet energy level of the exciplex is larger than a triplet energy level of the resonance-type thermally activated delayed fluorescence material.

2. The organic electroluminescent device according to claim 1, wherein the resonance-type thermally activated delayed fluorescence material has a structure represented by Formula [1]: 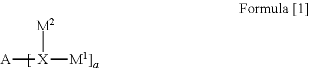
wherein
X is independently selected from one of B, P, P═O, P═S, and SiR₁; R₁ is selected from H, a substituted or unsubstituted C₁-C₃₆ alkyl, a substituted or unsubstituted C₆-C₃₀ aryl, or a substituted or unsubstituted C₃-C₃₀ heteroaryl;
A is selected from a substituted or unsubstituted C₆-C₃₀ aryl, a substituted or unsubstituted C₃-C₃₀ heteroaryl, or a substituted or unsubstituted C₆-C₃₀ arylamino;
M¹ and M² are each independently selected from H, a substituted or unsubstituted C₁-C₃₆ alkyl, a substituted or unsubstituted C₆-C₃₀ aryl, a substituted or unsubstituted C₃-C₃₀ heteroaryl;
at least three of adjacent X, A, M¹, M² are connected to form a ring, and the ring comprises X;
a is an integer of 1 to 12;
when substituents are present in the above groups, the substituents are each independently selected from one or more of halogen, cyano, C₁-C₁₀ alkyl, C₂-C₆ alkenyl, C₁-C₆ alkoxy or thioalkoxy, C₆-C₃₀ aryl and C₃-C₃₀ heteroaryl.

3. The organic electroluminescent device according to claim 2, wherein three of adjacent X, A, M¹, and M² are connected to form a six-membered ring containing two heteroatoms;
the heteroatoms are selected from two of B, P, Si, O, S, N, and Se.

4. The organic electroluminescent device according to claim 3, wherein the resonance-type thermally activated delayed fluorescence material has a molecular weight of 200-2000.

5. The organic electroluminescent device according to claim 4, wherein a is an integer of 1 to 6.

6. The organic electroluminescent device according to claim 3, wherein the resonance-type thermally activated delayed fluorescence material is a compound having one of the following general formulae: 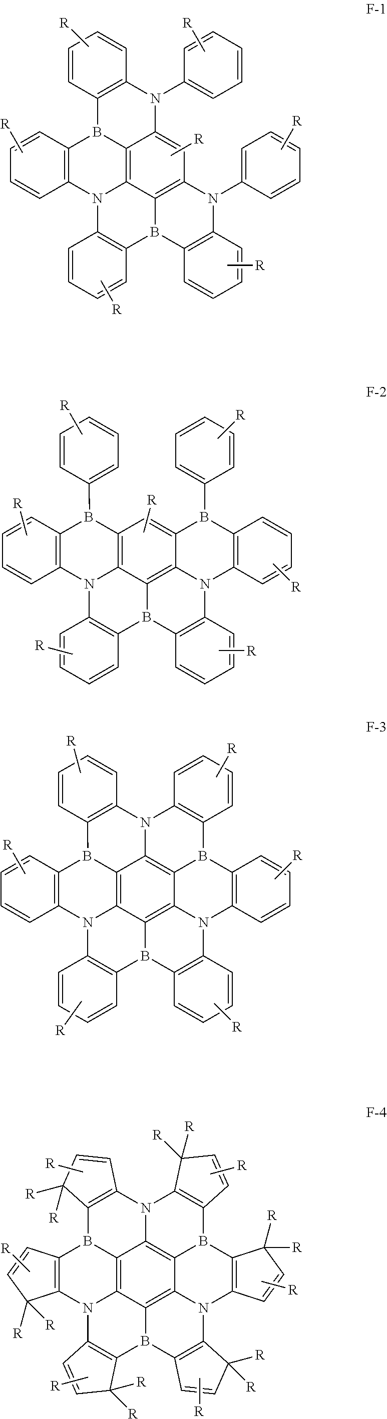 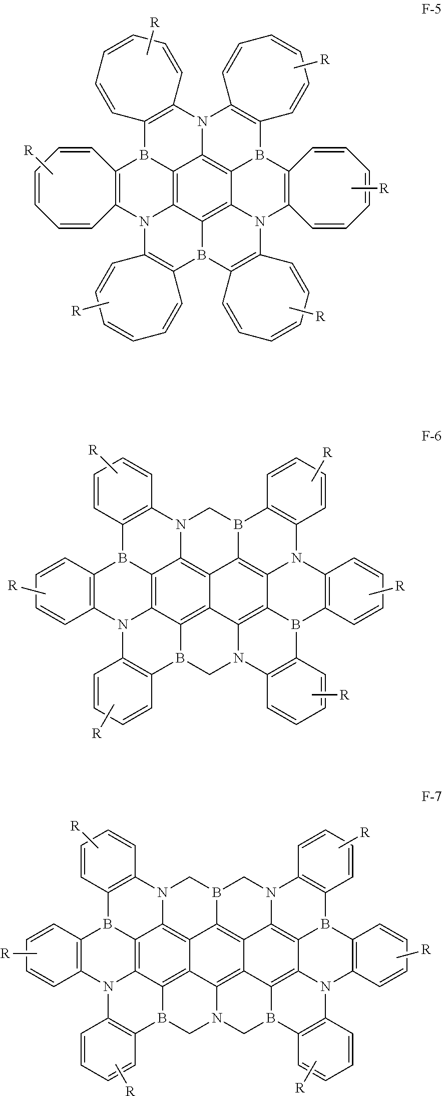 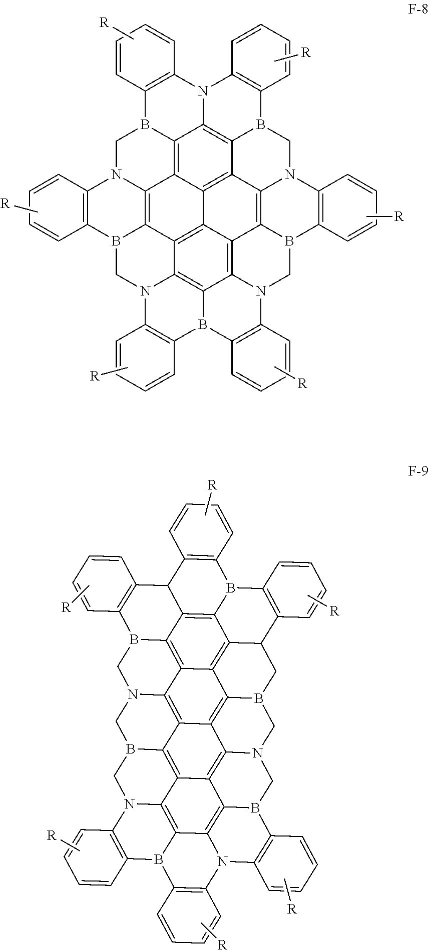 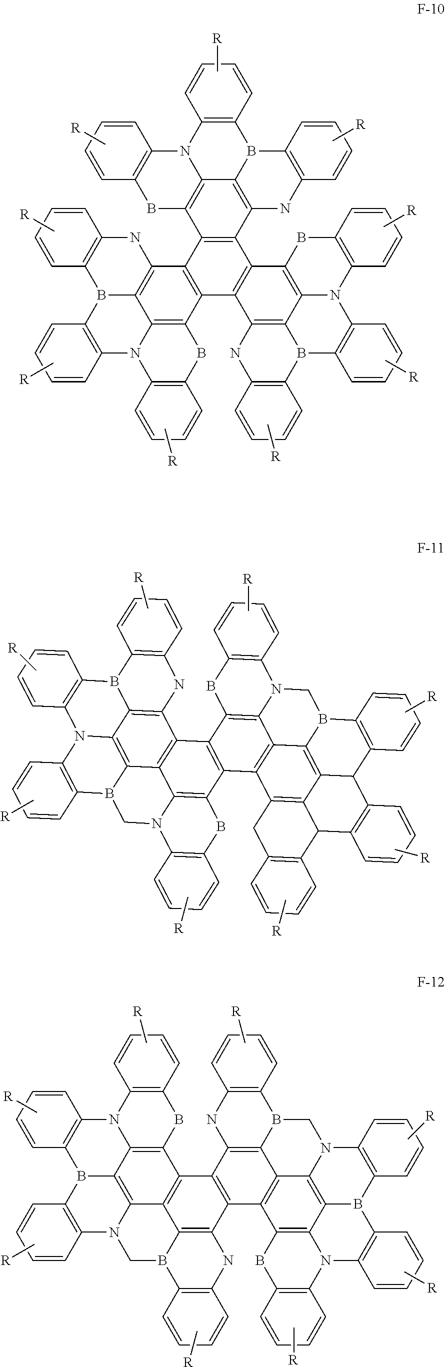 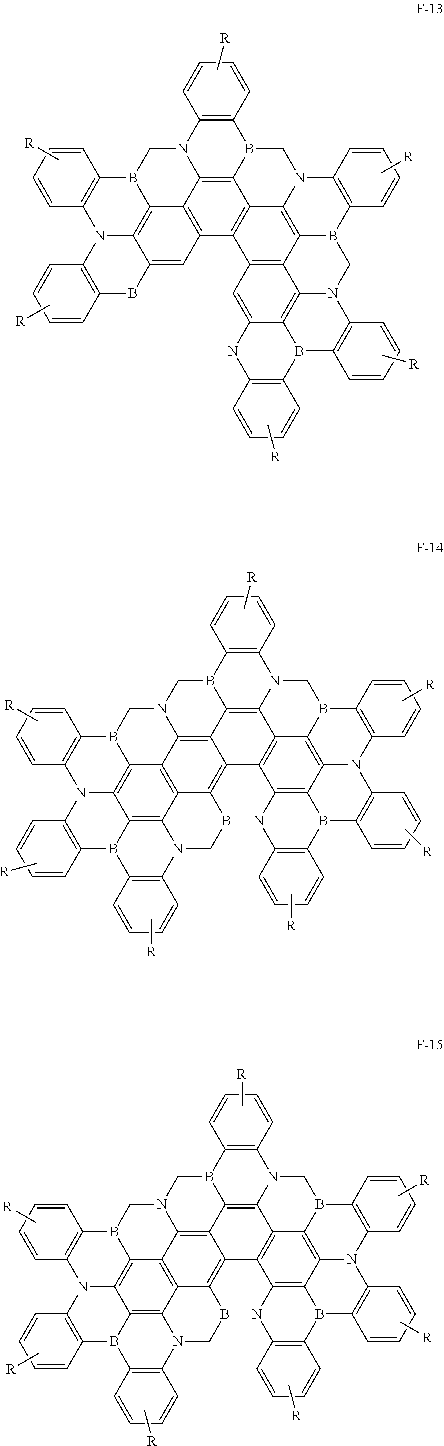 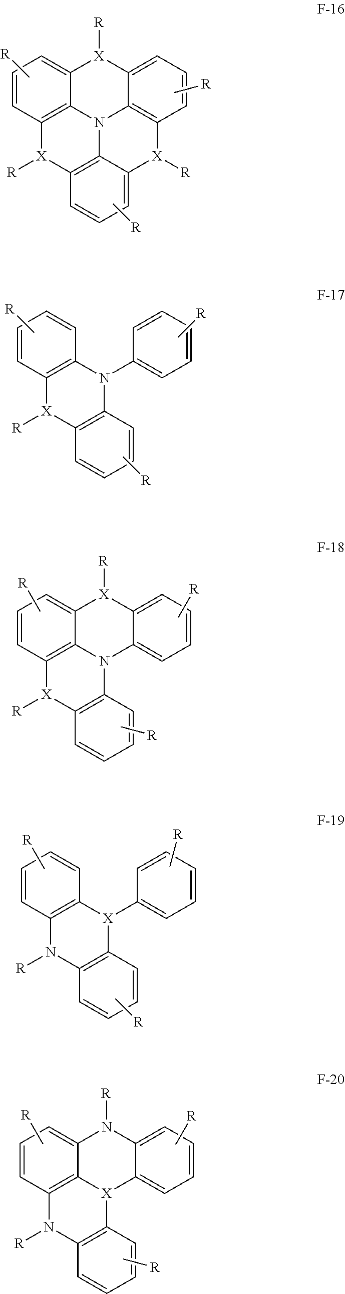 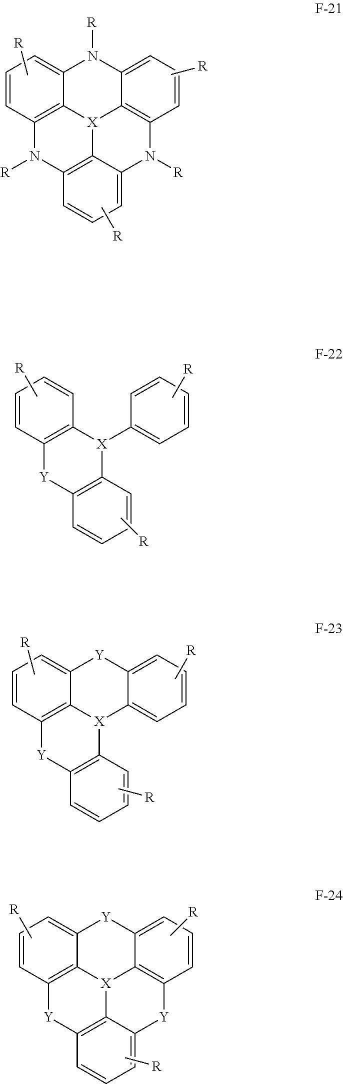 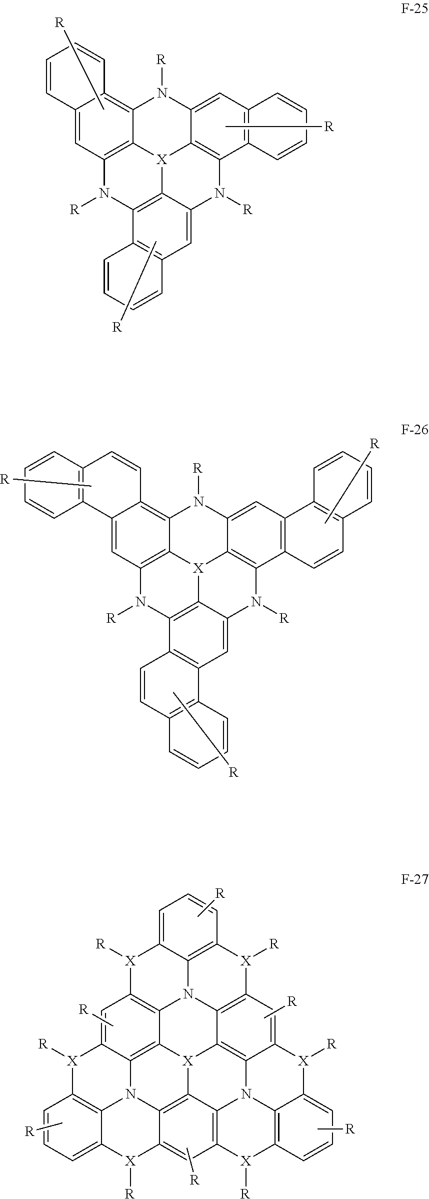 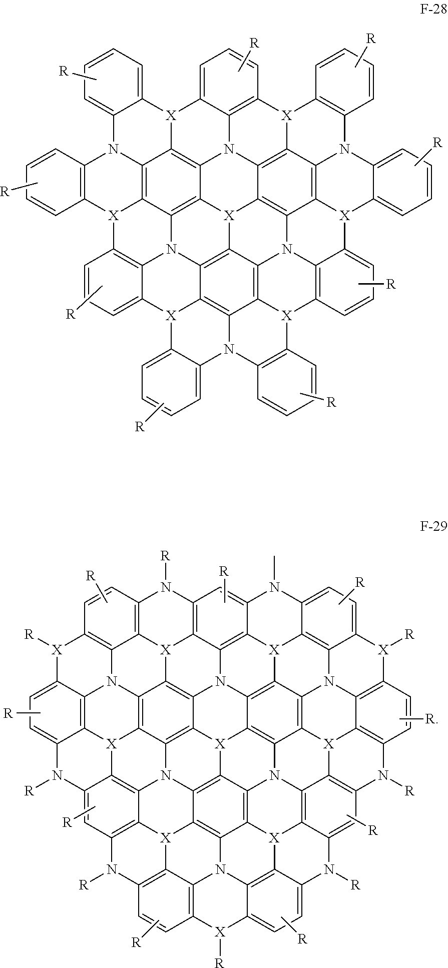
wherein R is independently selected from one or more of H, halogen, cyano, C₁-C₁0 alkyl, C₂-C₆ alkenyl, C₁-C₆ alkoxy or thioalkoxy, C₆-C₃₀ aryl, and C₃-C₃₀ heteroaryl;
Y is independently selected from O, S, or Se.

7. The organic electroluminescent device according to claim 6, wherein the resonance-type thermally activated delayed fluorescence material is a compound having one of the following structures:

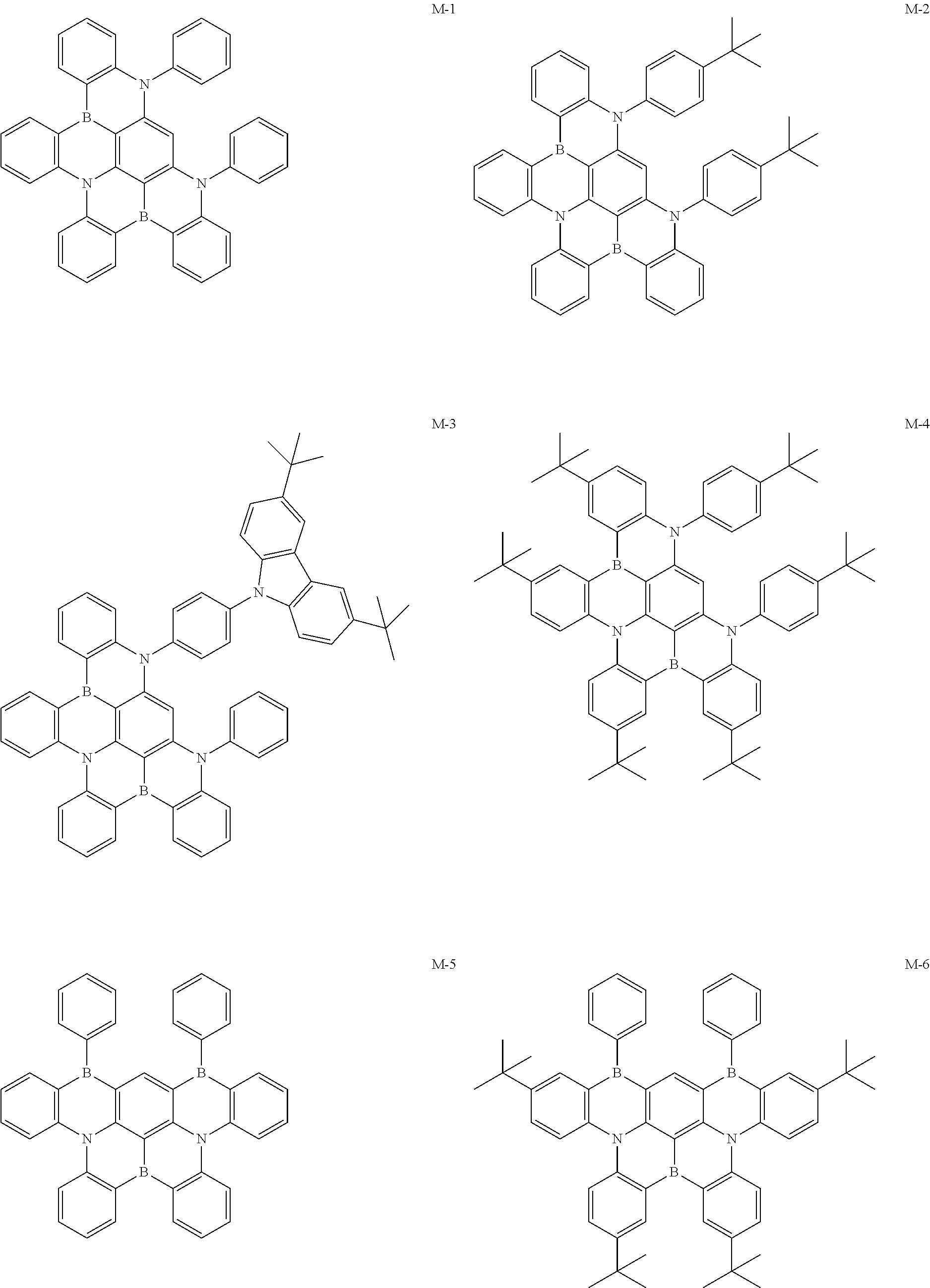

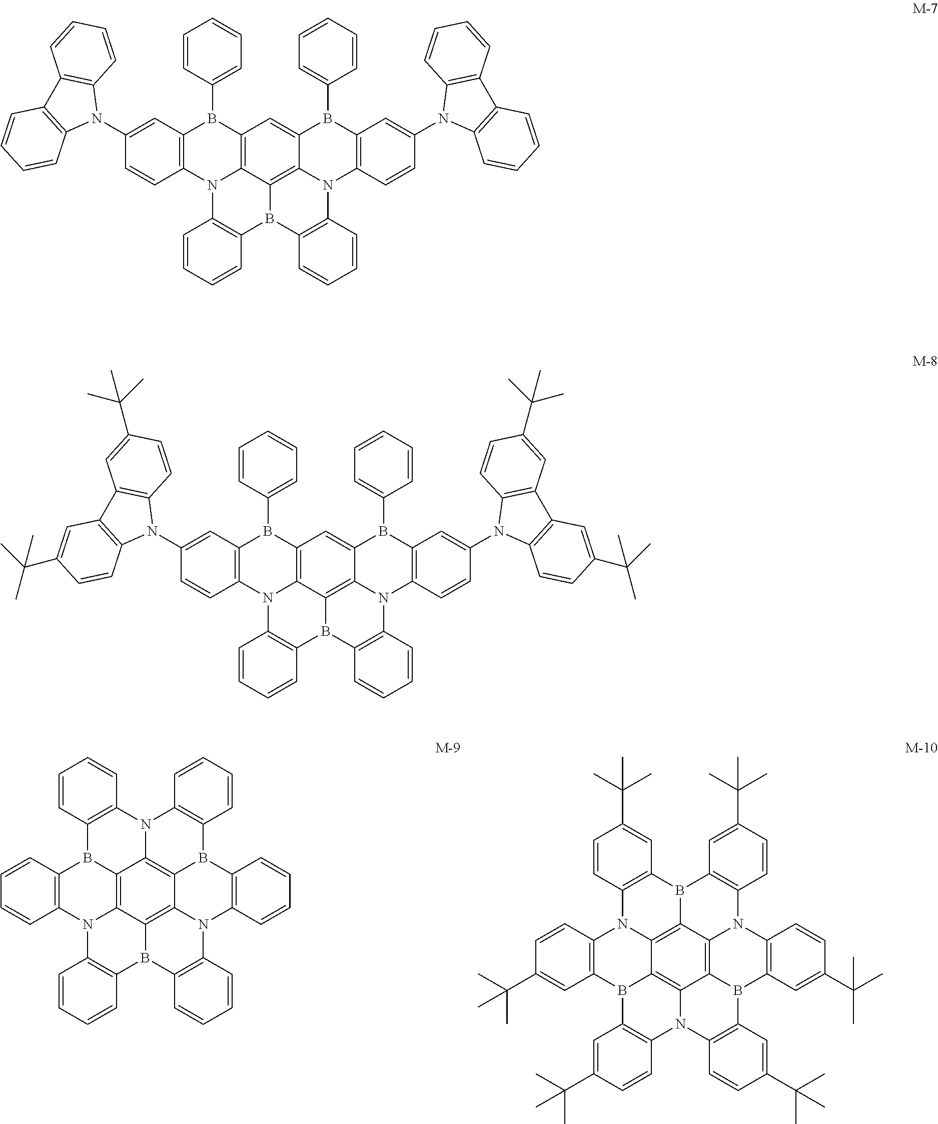

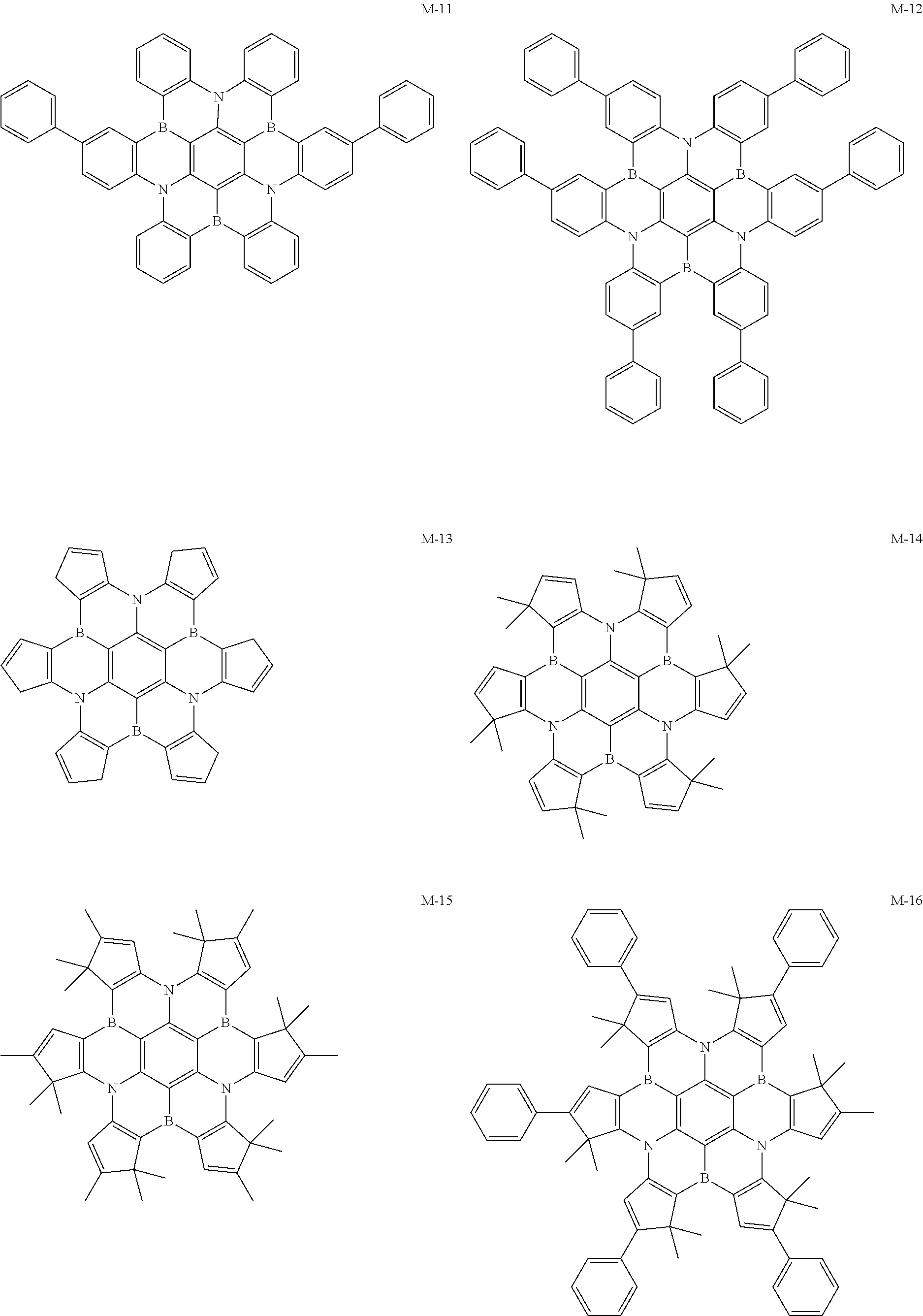

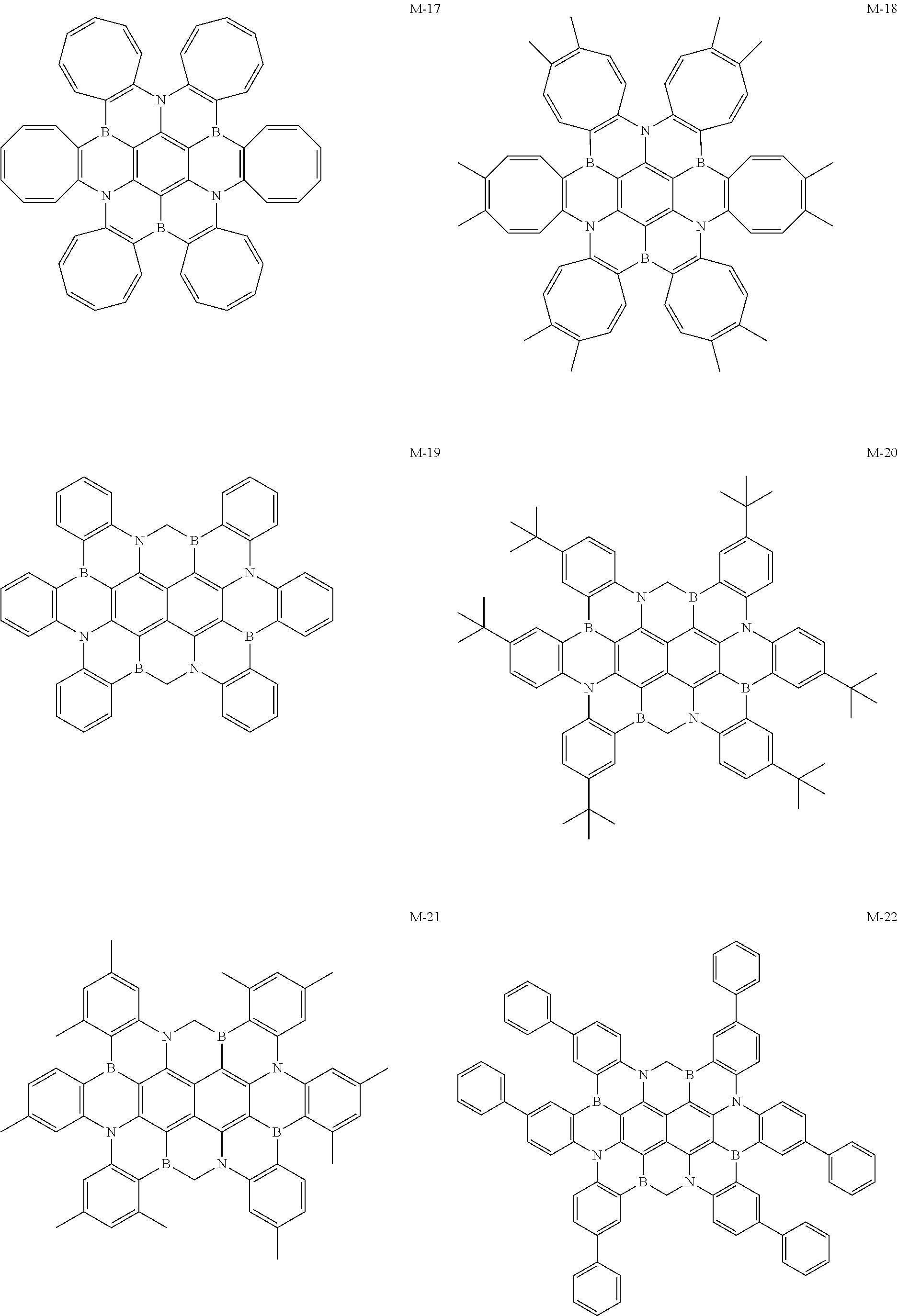

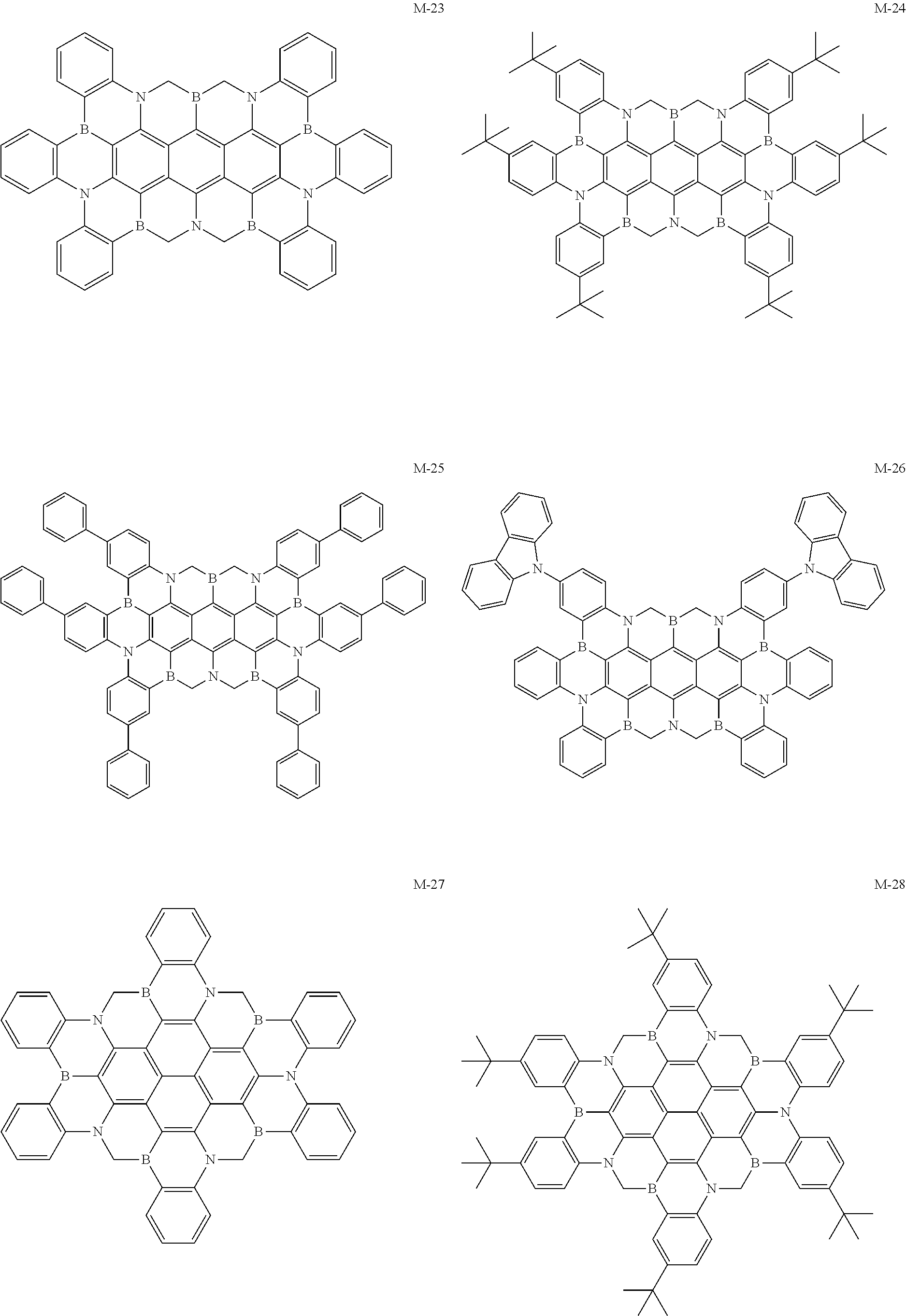

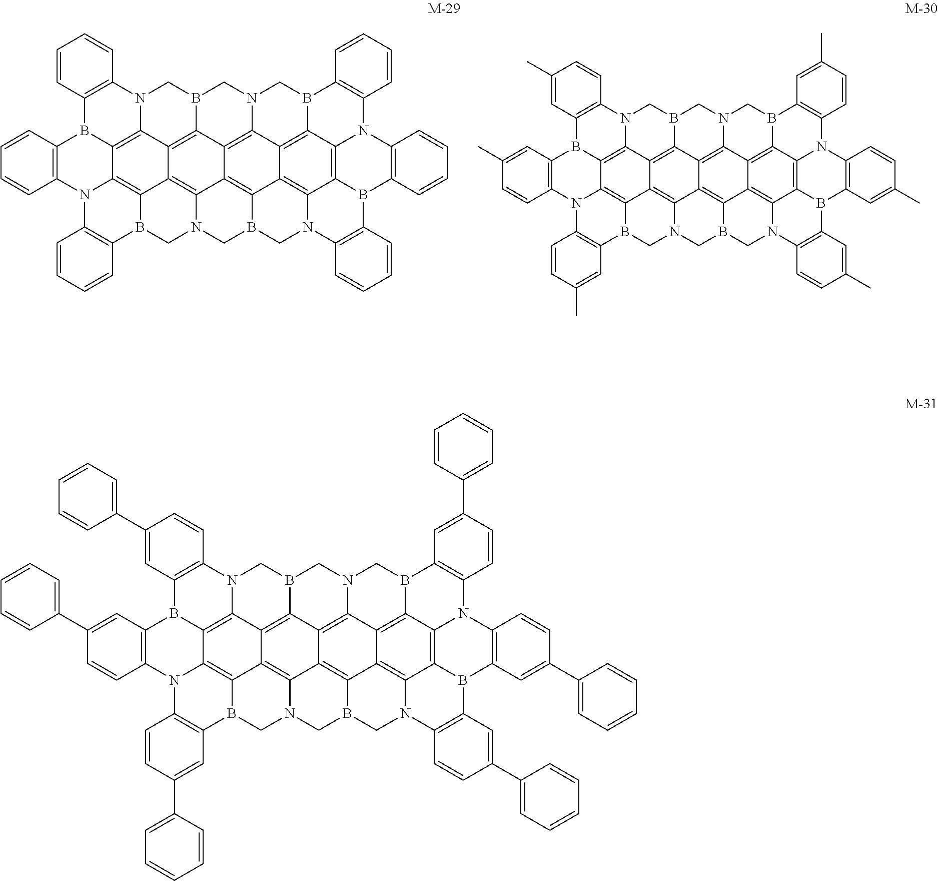

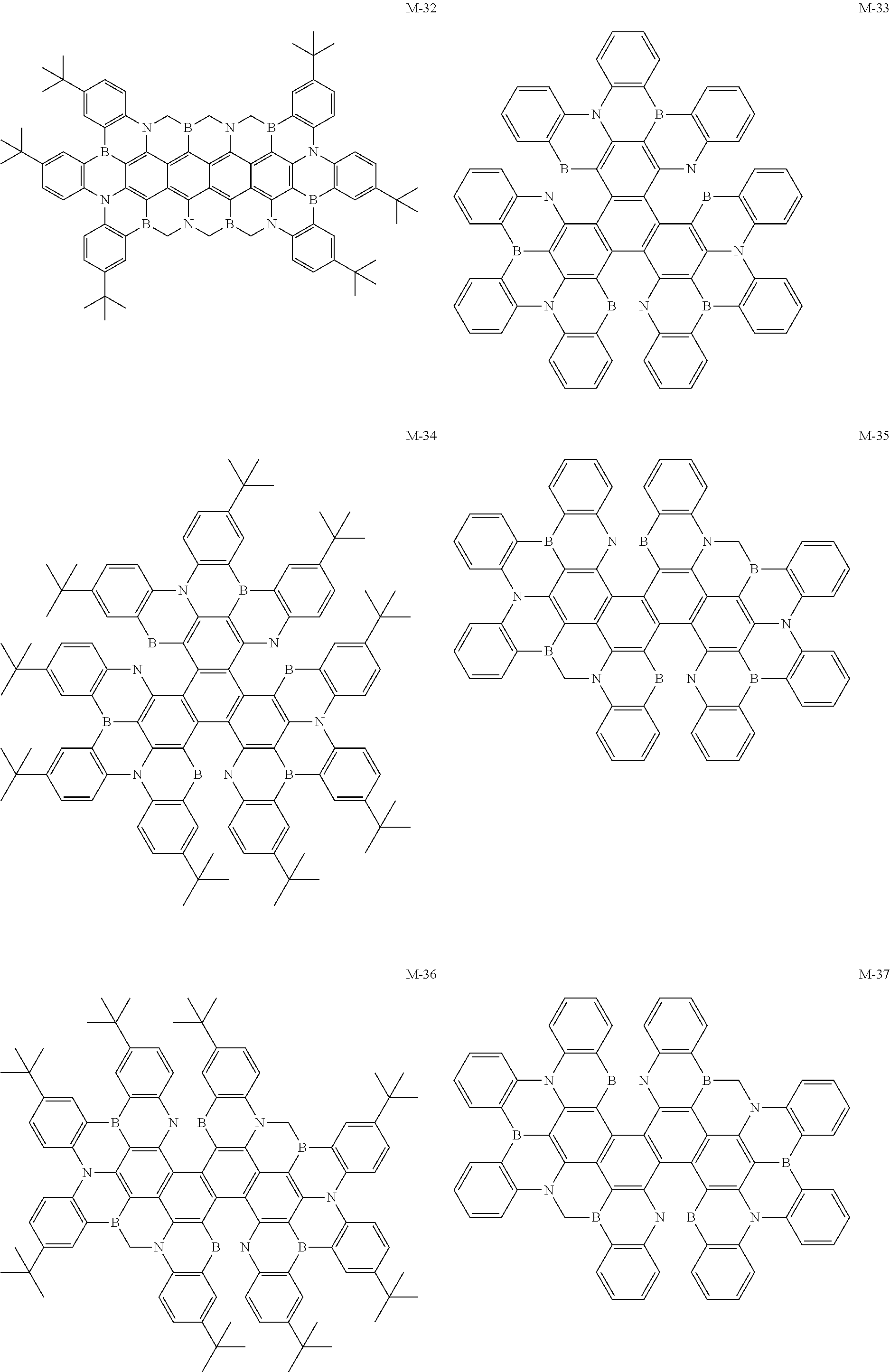

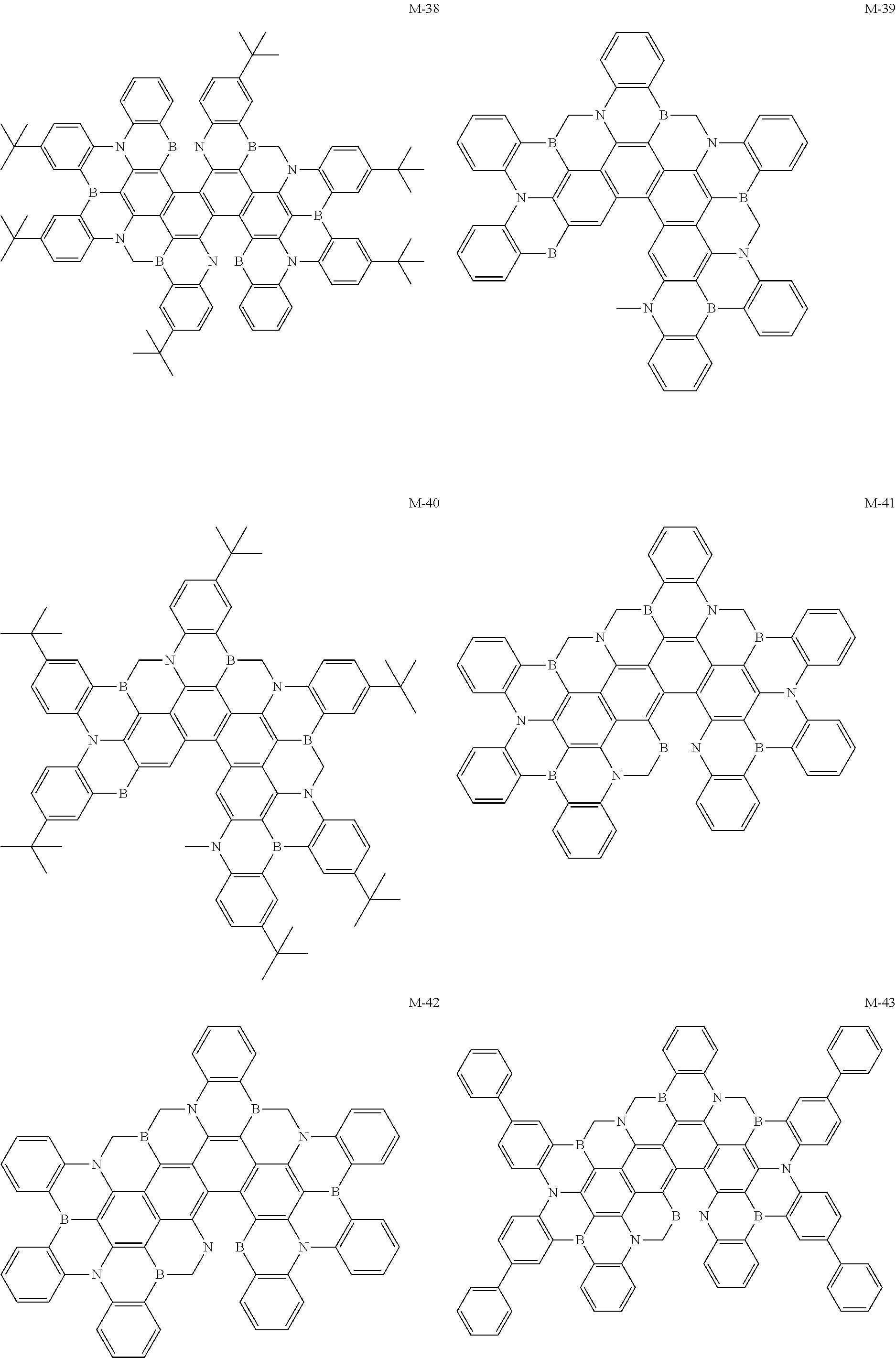

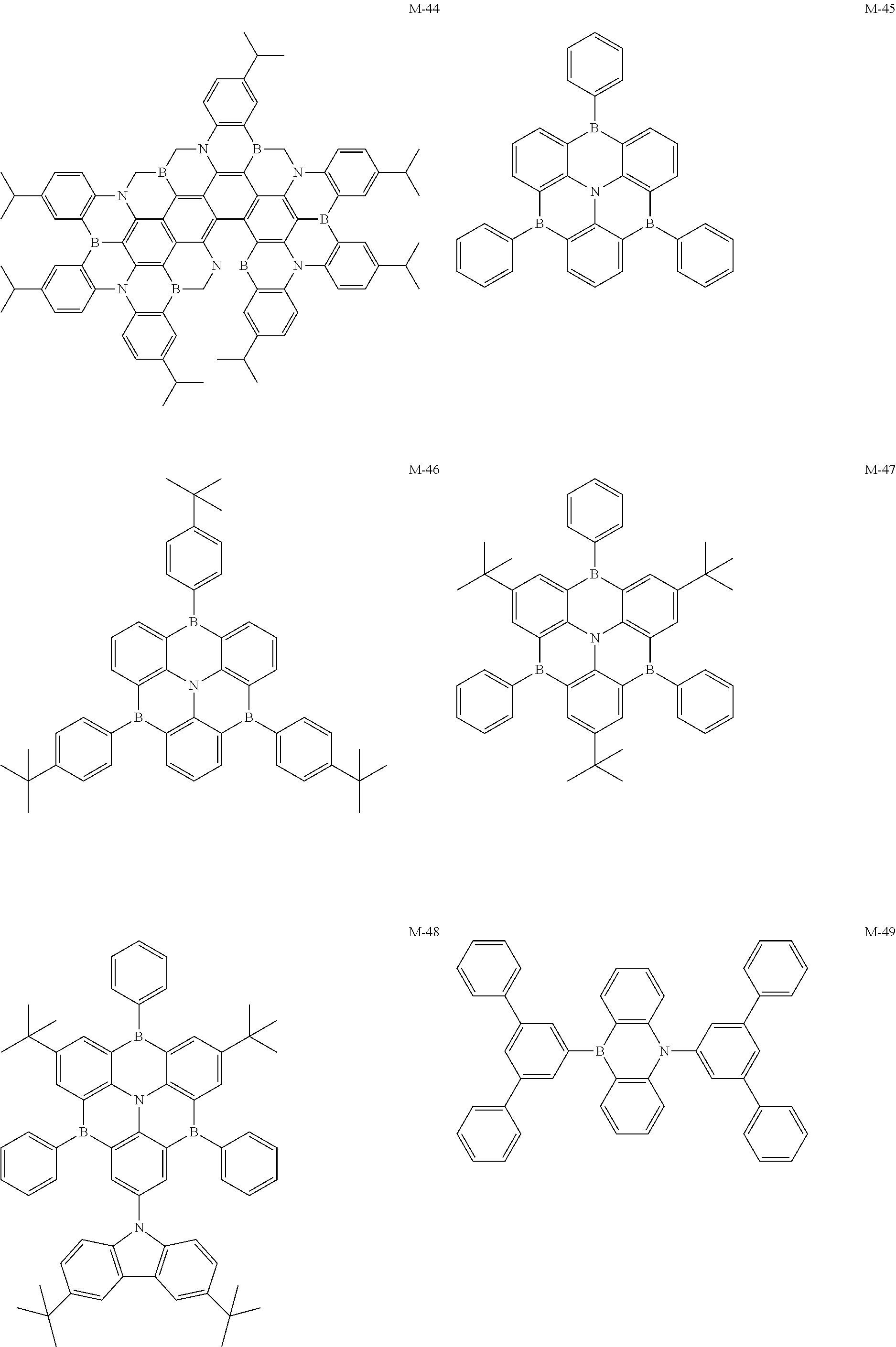

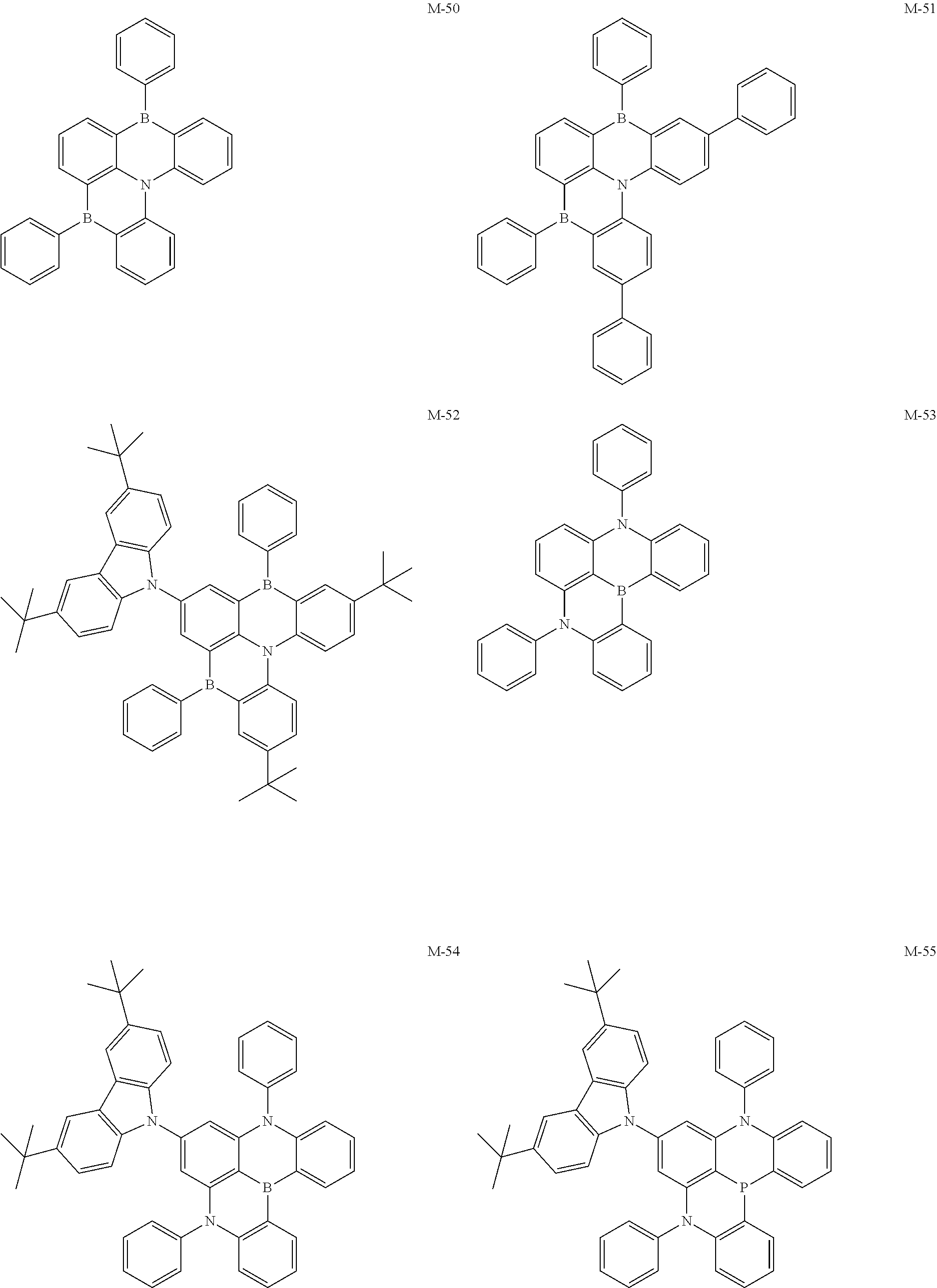

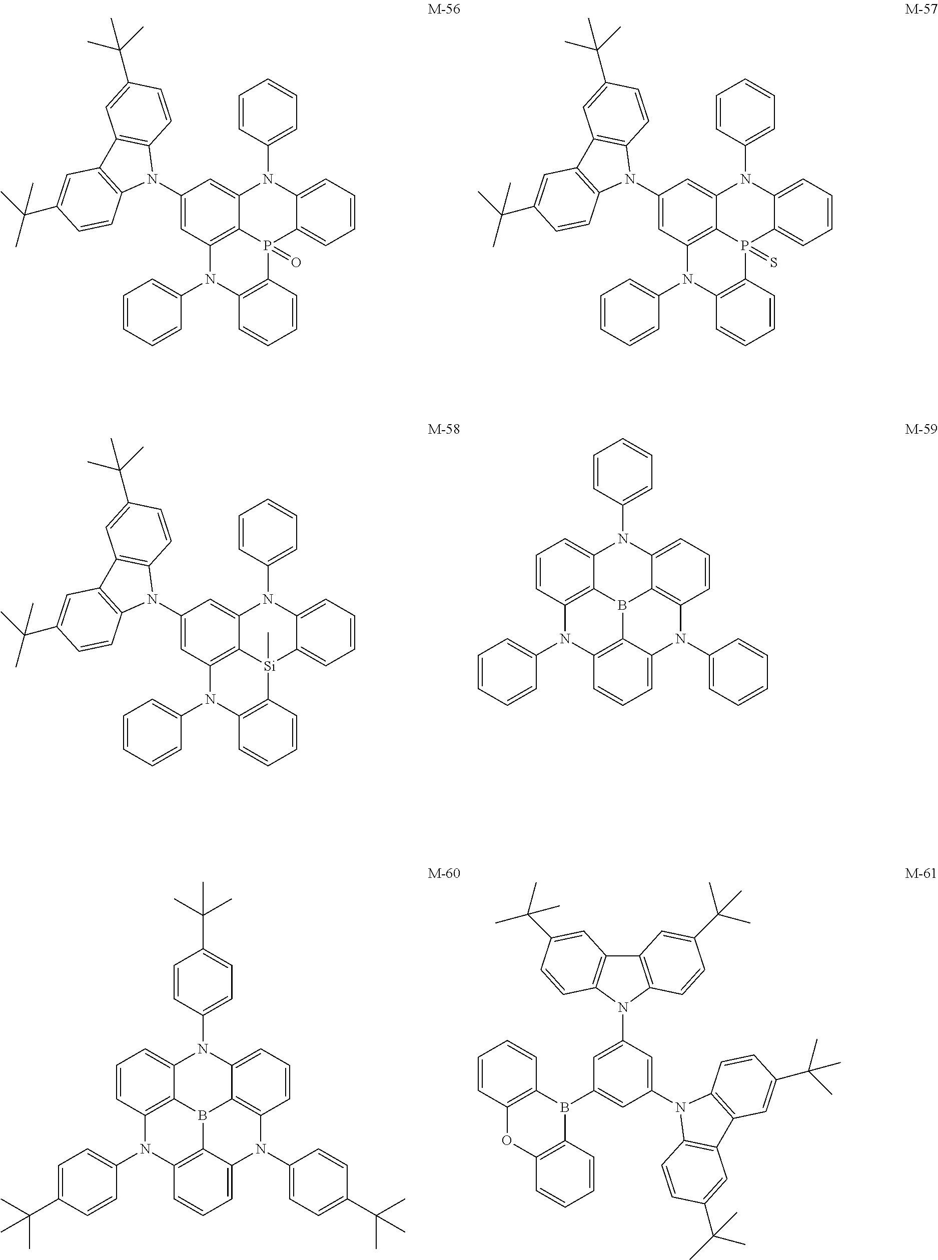

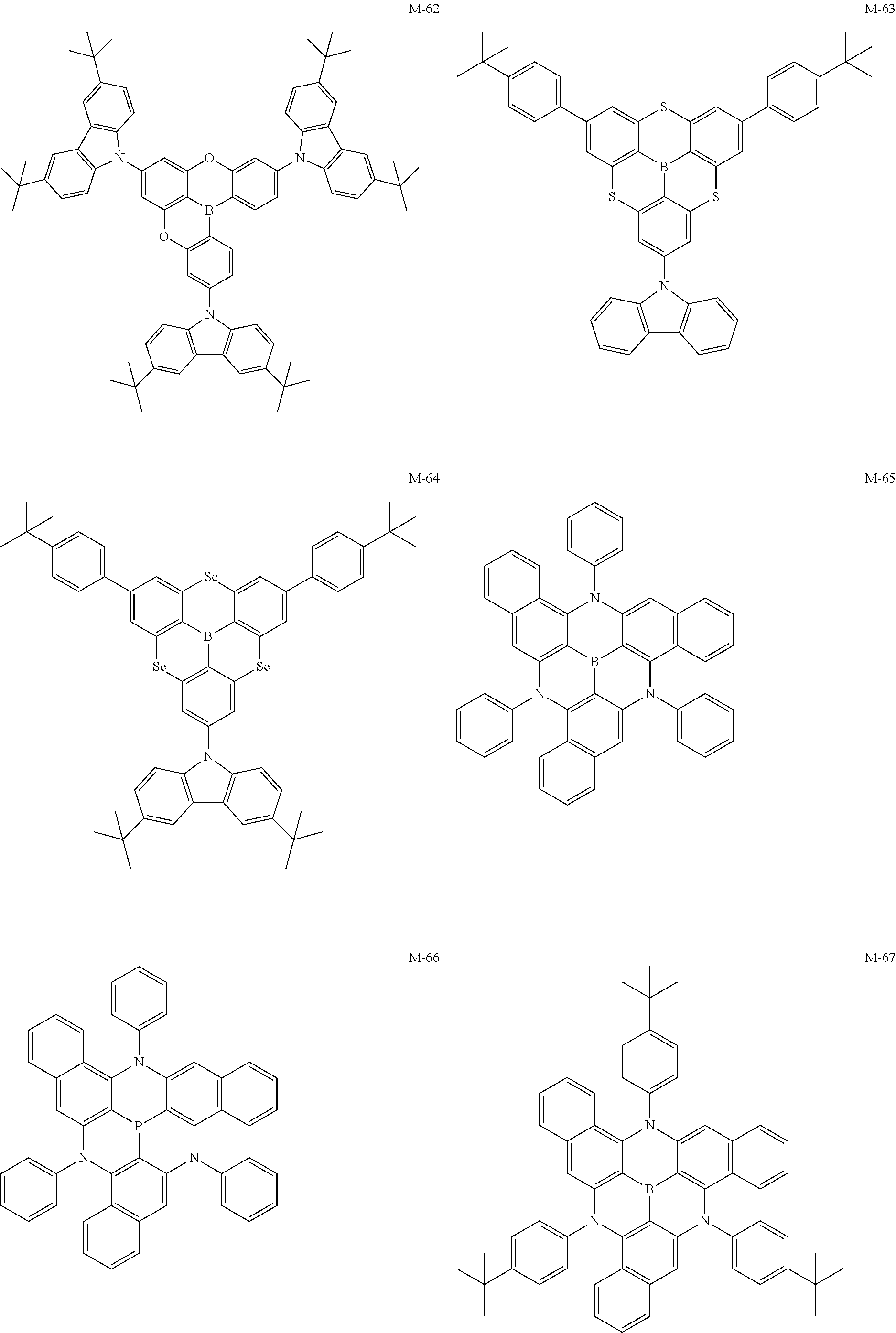

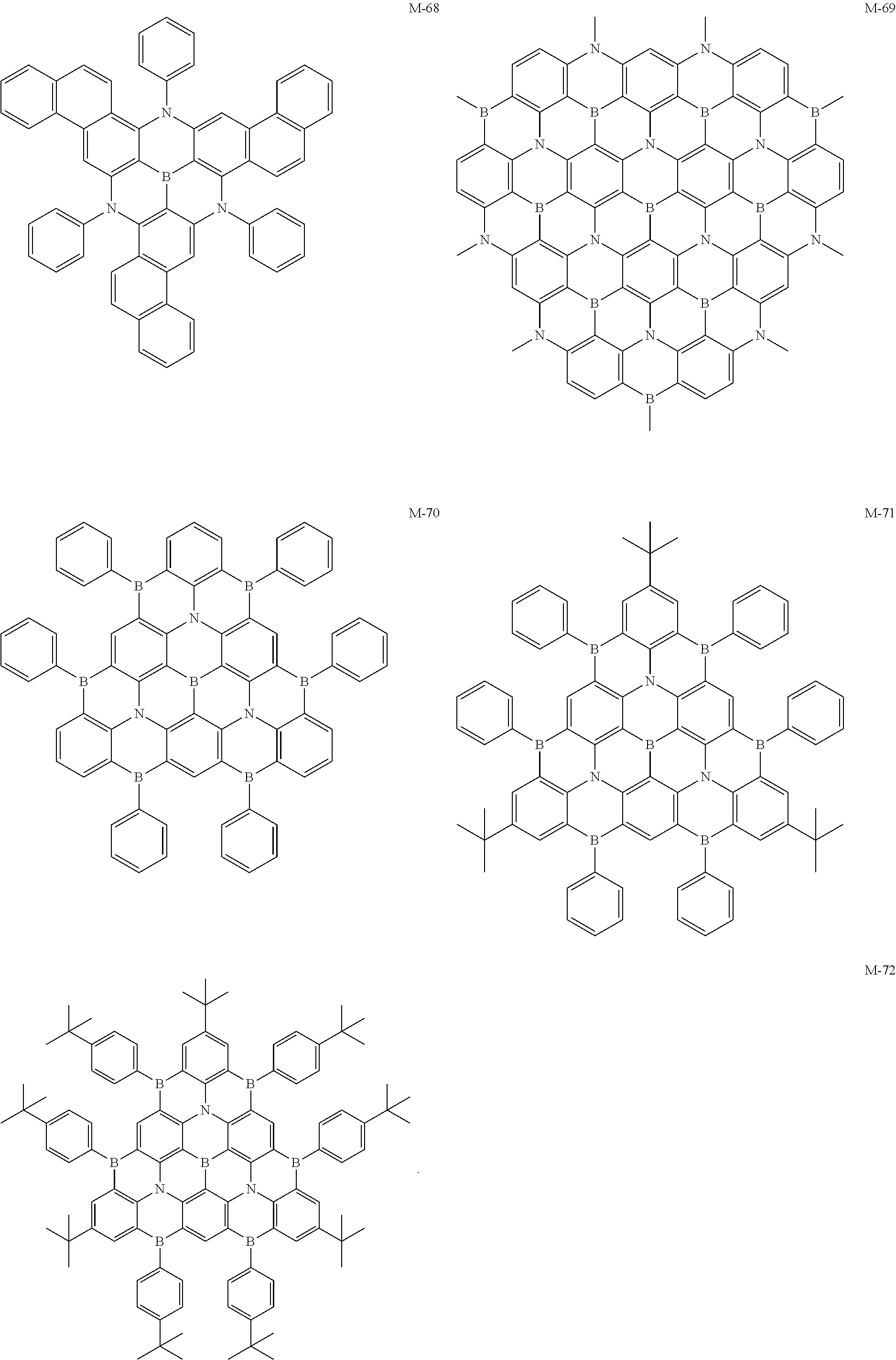

8. The organic electroluminescent device according to claim 1, wherein the exciplex comprises an electron donor type material and an electron acceptor type material.

9. The organic electroluminescent device according to claim 8, wherein an energy level difference between a singlet state and a triplet state of the exciplex is less than or equal to 0.15 ev.

10. The organic electroluminescent device according to claim 8, wherein the electron donor type material is a compound having a hole-transport property containing at least one group of carbazolyl, arylamino, silicon group, fluorenyl, dibenzothiophenyl, and dibenzofuranyl.

11. The organic electroluminescent device according to claim 10, wherein the electron donor type material is a compound having one of the following structures:

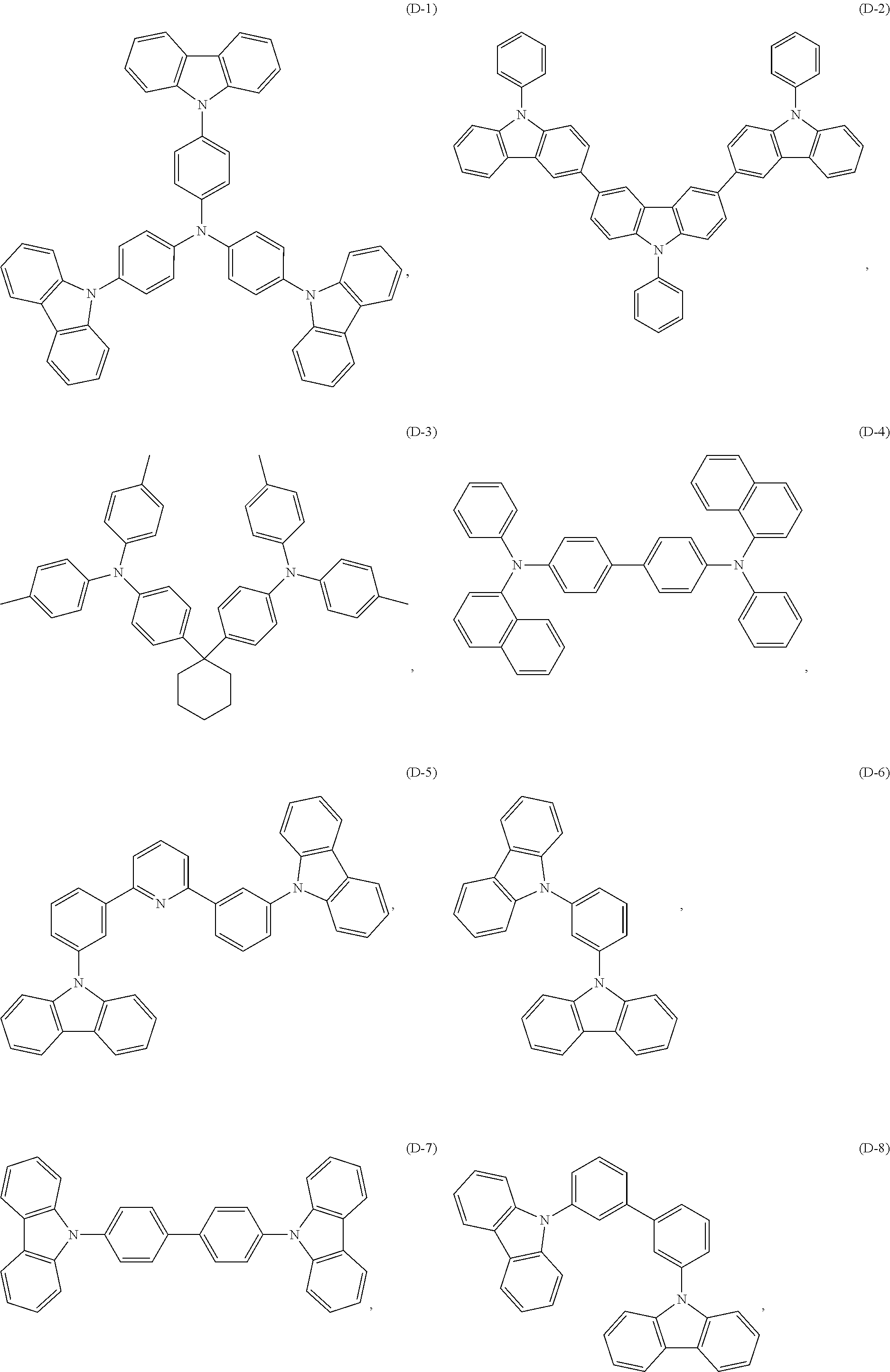

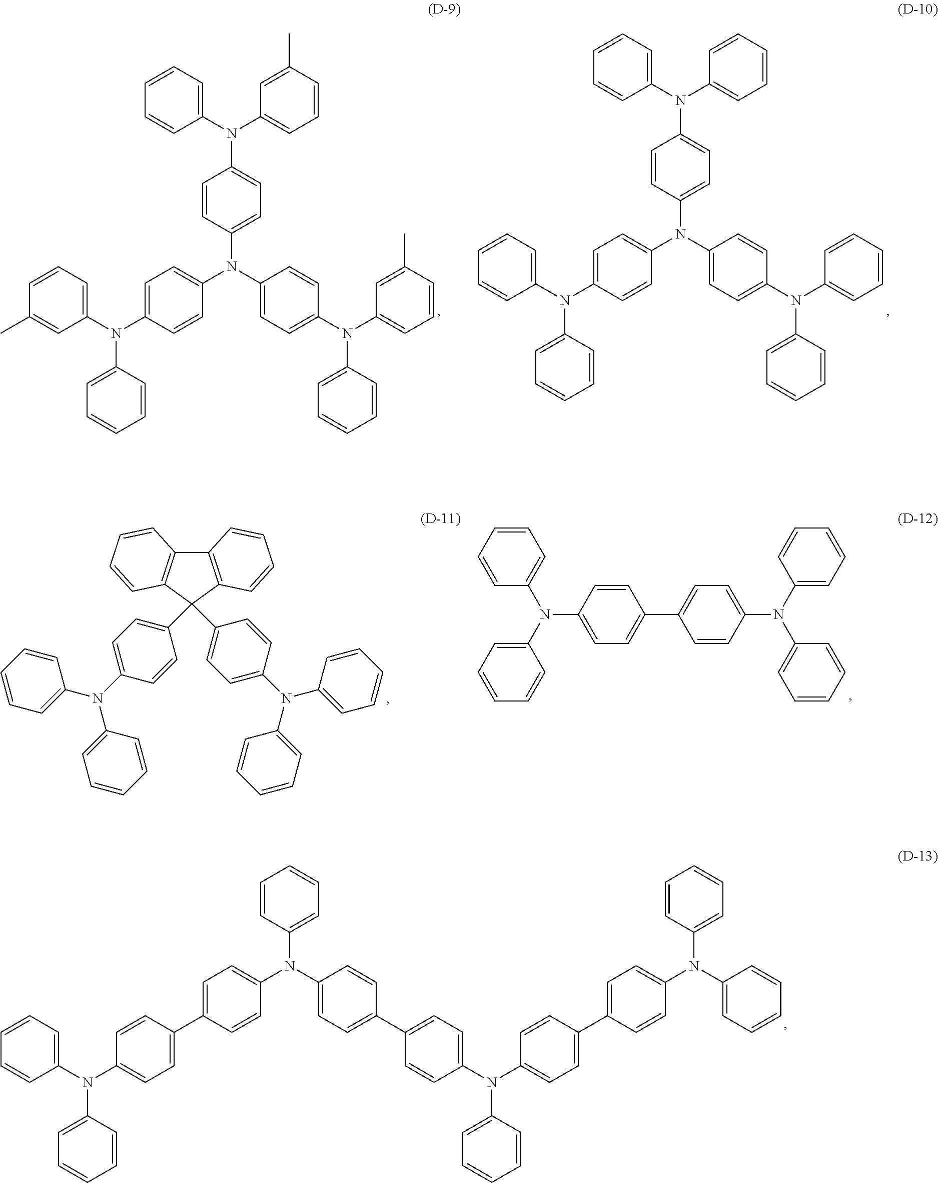

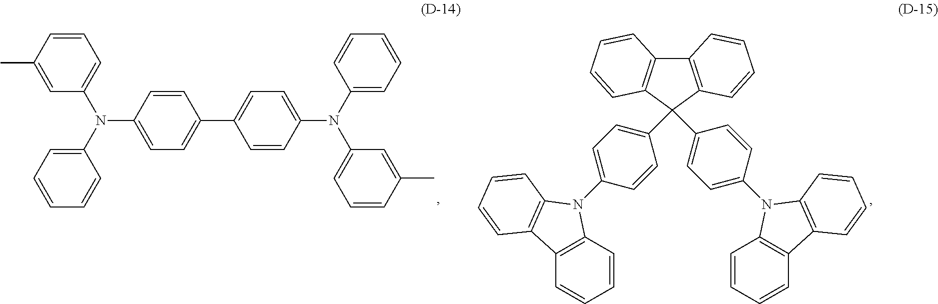

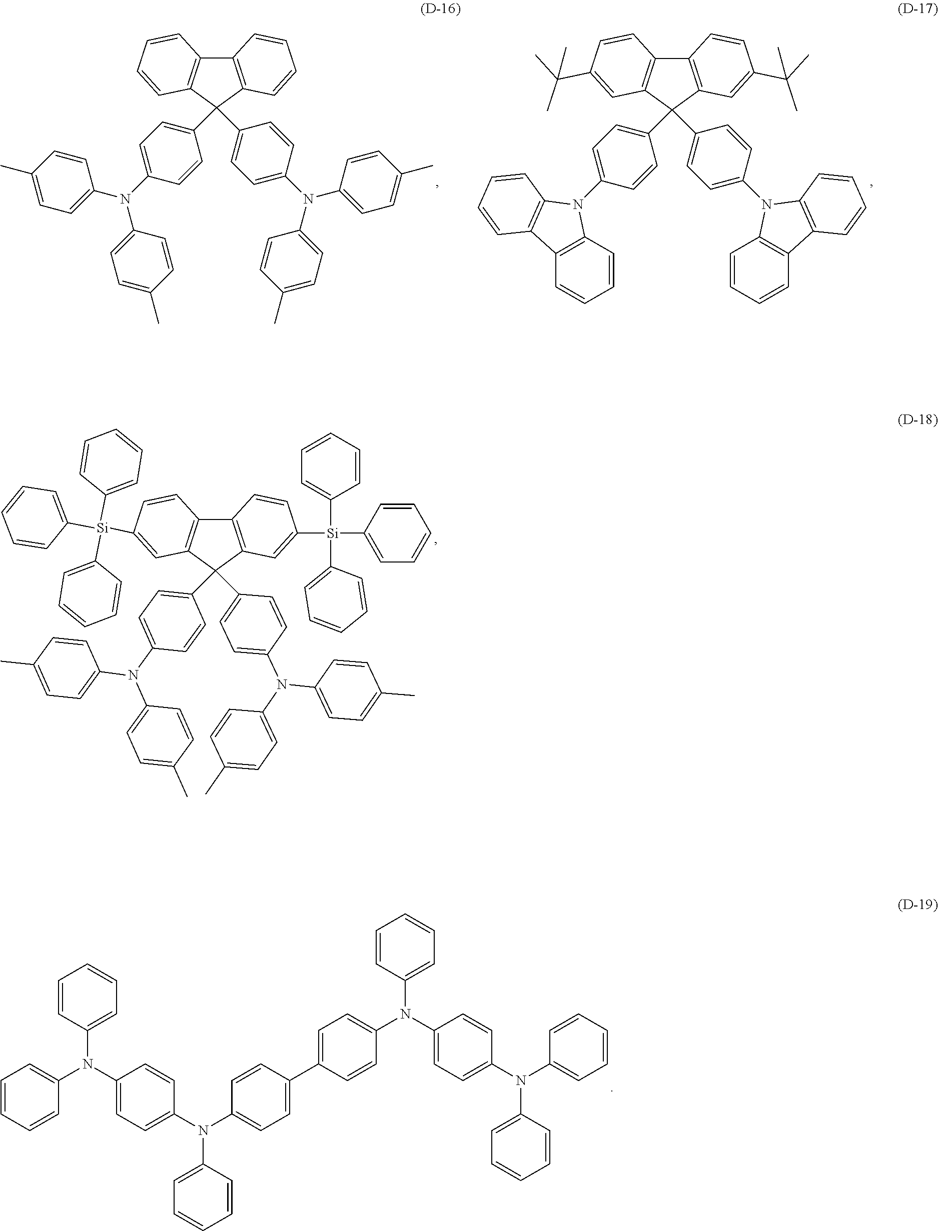

12. The organic electroluminescent device according to claim 8, wherein the electron acceptor type material is a compound having electron transport property containing at least one group of pyridyl, pyrimidyl, triazinyl, imidazolyl, o-phenanthrolinyl, sulfonyl, heptazinyl, oxadiazolyl, cyano, and diphenylphosphonyl.

13. The organic electroluminescent device according to claim 12, wherein the electron acceptor type material is a compound having one of the structures shown below:

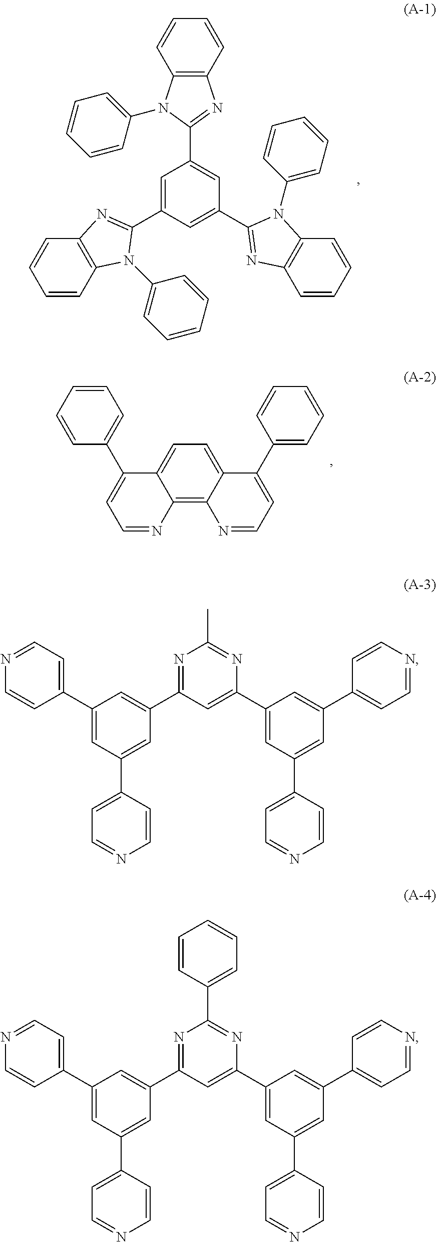 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2ccnc3c2ccc2c(-c4ccccc4)ccnc23)cc1 ; Cc1nc(-c2cc(-c3ccncc3)cc(-c3ccncc3)c2)cc(-c2cc(-c3ccncc3)cc(-c3ccncc3)c2)n1 ; c1ccc(-c2nc(-c3cc(-c4ccncc4)cc(-c4ccncc4)c3)cc(-c3cc(-c4ccncc4)cc(-c4ccncc4)c3)n2)cc1]

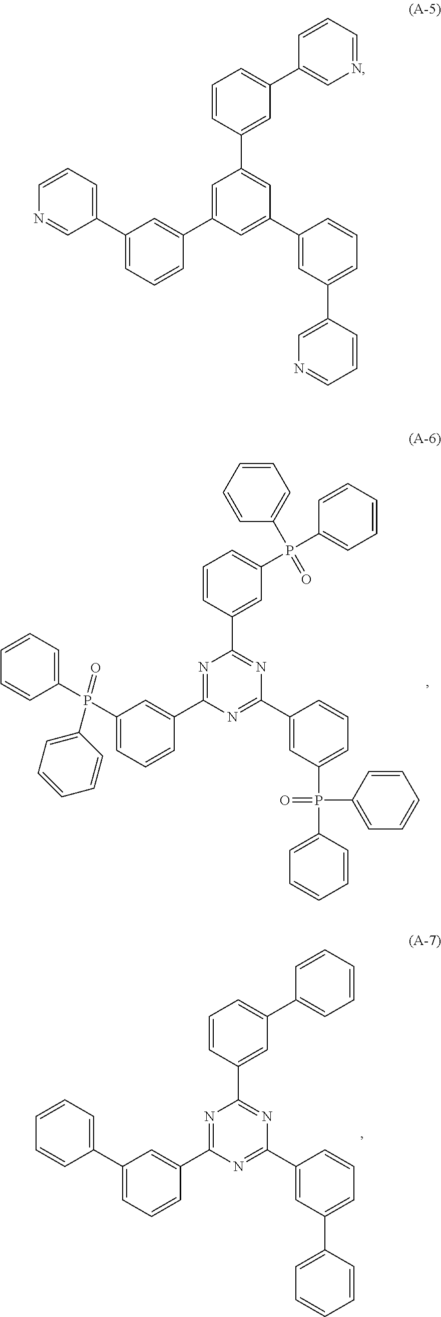 [SMILES: c1cncc(-c2cccc(-c3cc(-c4cccc(-c5cccnc5)c4)cc(-c4cccc(-c5cccnc5)c4)c3)c2)c1 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1 ; c1ccc(-c2cccc(-c3nc(-c4cccc(-c5ccccc5)c4)nc(-c4cccc(-c5ccccc5)c4)n3)c2)cc1]

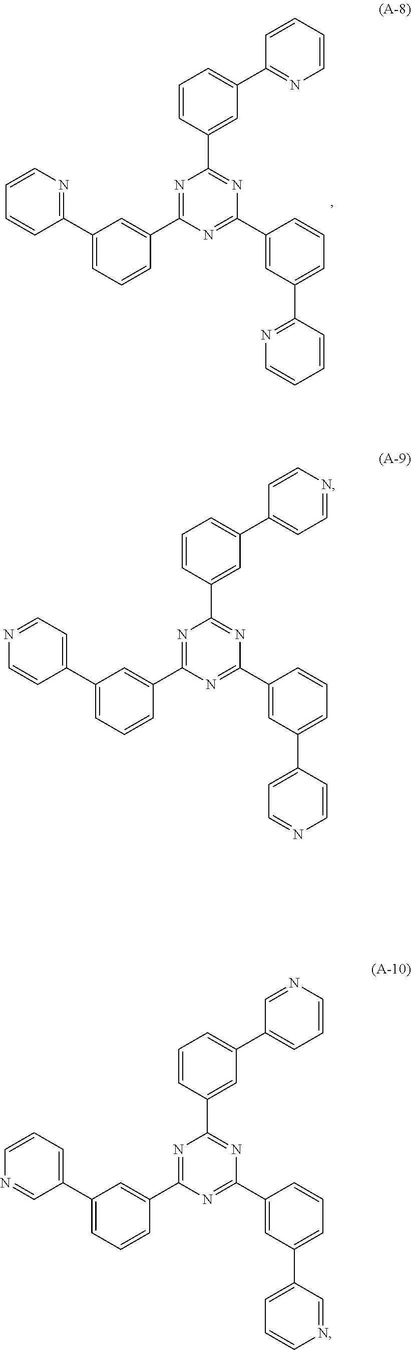 [SMILES: c1ccc(-c2cccc(-c3nc(-c4cccc(-c5ccccn5)c4)nc(-c4cccc(-c5ccccn5)c4)n3)c2)nc1 ; c1cc(-c2ccncc2)cc(-c2nc(-c3cccc(-c4ccncc4)c3)nc(-c3cccc(-c4ccncc4)c3)n2)c1 ; c1cncc(-c2cccc(-c3nc(-c4cccc(-c5cccnc5)c4)nc(-c4cccc(-c5cccnc5)c4)n3)c2)c1]

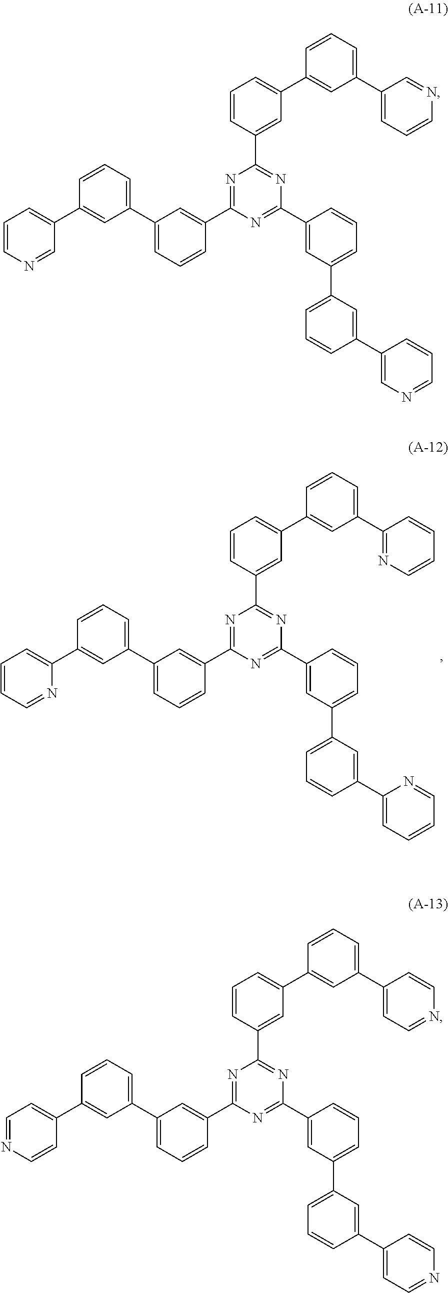 [SMILES: c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1 ; c1ccc(-c2cccc(-c3cccc(-c4nc(-c5cccc(-c6cccc(-c7ccccn7)c6)c5)nc(-c5cccc(-c6cccc(-c7ccccn7)c6)c5)n4)c3)c2)nc1 ; c1cc(-c2ccncc2)cc(-c2cccc(-c3nc(-c4cccc(-c5cccc(-c6ccncc6)c5)c4)nc(-c4cccc(-c5cccc(-c6ccncc6)c5)c4)n3)c2)c1]

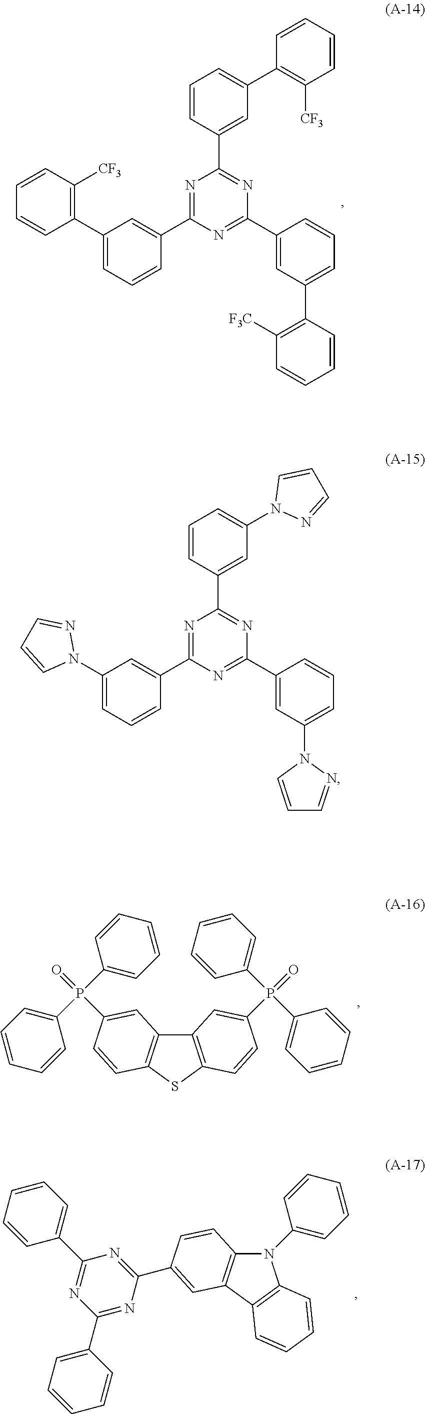 [SMILES: FC(F)(F)c1ccccc1-c1cccc(-c2nc(-c3cccc(-c4ccccc4C(F)(F)F)c3)nc(-c3cccc(-c4ccccc4C(F)(F)F)c3)n2)c1 ; c1cc(-c2nc(-c3cccc(-n4cccn4)c3)nc(-c3cccc(-n4cccn4)c3)n2)cc(-n2cccn2)c1 ; O=P(c1ccccc1)(c1ccccc1)c1ccc2sc3ccc(P(=O)(c4ccccc4)c4ccccc4)cc3c2c1 ; c1ccc(-c2nc(-c3ccccc3)nc(-c3ccc4c(c3)c3ccccc3n4-c3ccccc3)n2)cc1]

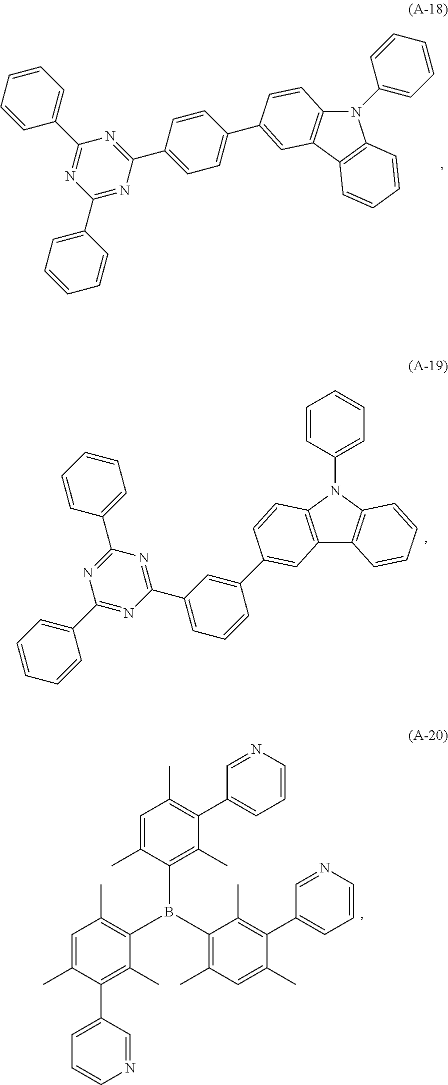 [SMILES: c1ccc(-c2nc(-c3ccccc3)nc(-c3ccc(-c4ccc5c(c4)c4ccccc4n5-c4ccccc4)cc3)n2)cc1 ; c1ccc(-c2nc(-c3ccccc3)nc(-c3cccc(-c4ccc5c(c4)c4ccccc4n5-c4ccccc4)c3)n2)cc1 ; Cc1cc(C)c(-c2cccnc2)c(C)c1B(c1c(C)cc(C)c(-c2cccnc2)c1C)c1c(C)cc(C)c(-c2cccnc2)c1C]

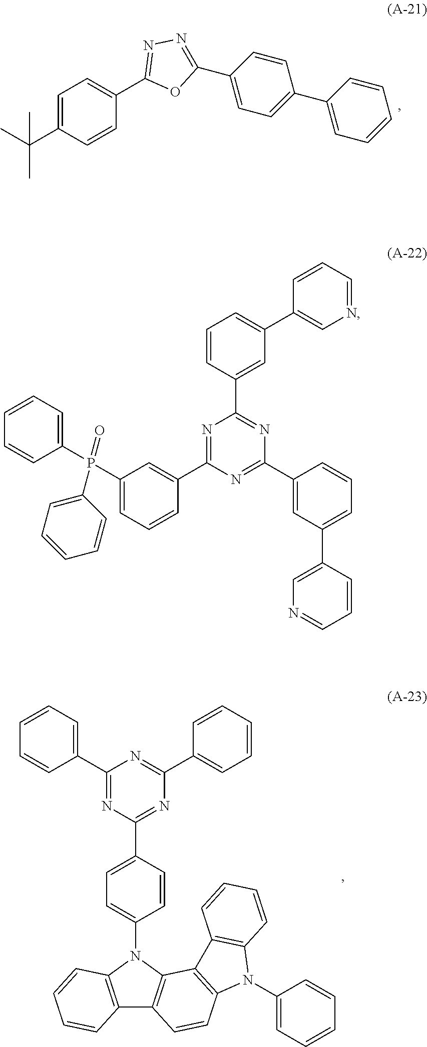 [SMILES: CC(C)(C)c1ccc(-c2nnc(-c3ccc(-c4ccccc4)cc3)o2)cc1 ; O=P(c1ccccc1)(c1ccccc1)c1cccc(-c2nc(-c3cccc(-c4cccnc4)c3)nc(-c3cccc(-c4cccnc4)c3)n2)c1 ; c1ccc(-c2nc(-c3ccccc3)nc(-c3ccc(-n4c5ccccc5c5ccc6c(c7ccccc7n6-c6ccccc6)c54)cc3)n2)cc1]

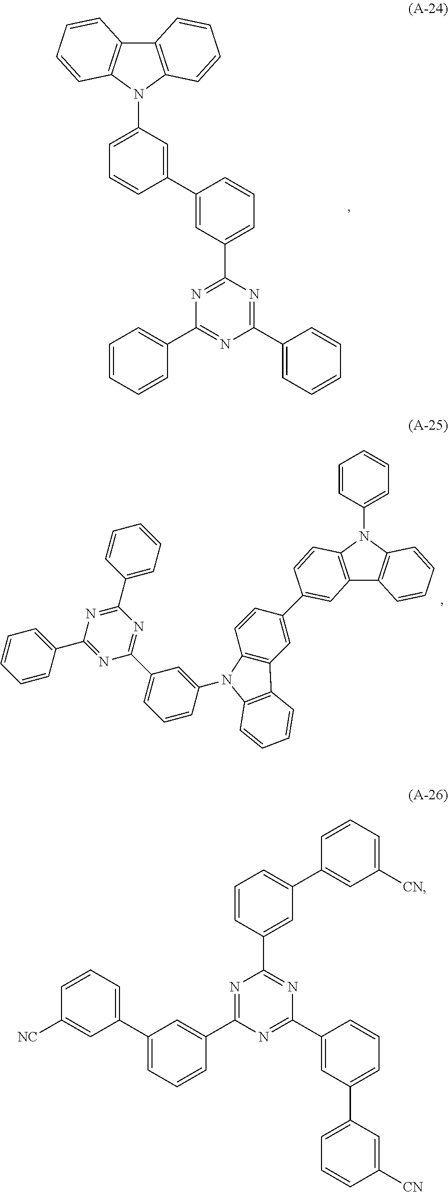 [SMILES: c1ccc(-c2nc(-c3ccccc3)nc(-c3cccc(-c4cccc(-n5c6ccccc6c6ccccc65)c4)c3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; N#Cc1cccc(-c2cccc(-c3nc(-c4cccc(-c5cccc(C#N)c5)c4)nc(-c4cccc(-c5cccc(C#N)c5)c4)n3)c2)c1]

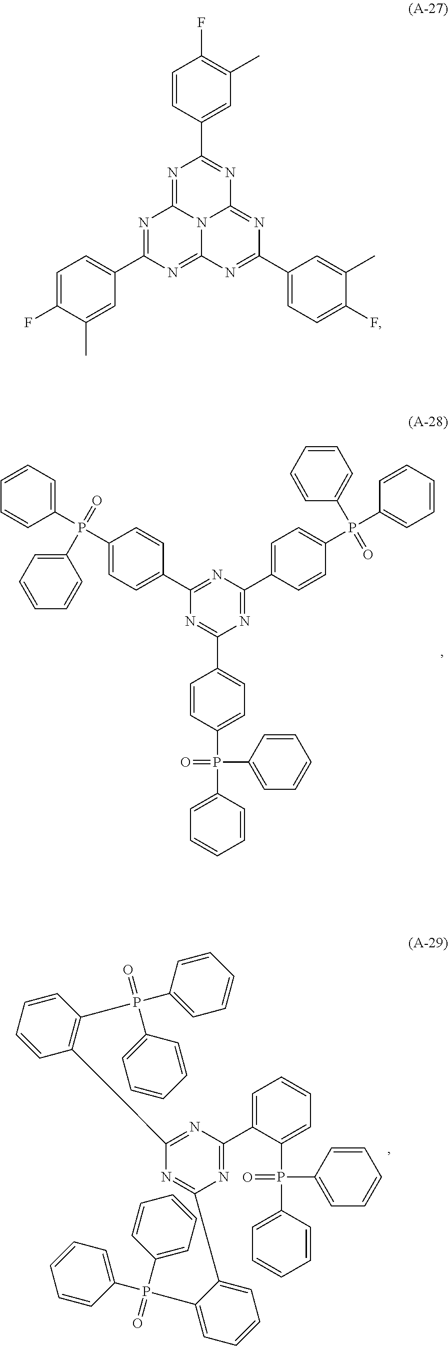 [SMILES: Cc1cc(C2=NC3=NC(c4ccc(F)c(C)c4)=NC4=NC(c5ccc(F)c(C)c5)=NC(=N2)N34)ccc1F ; O=P(c1ccccc1)(c1ccccc1)c1ccc(-c2nc(-c3ccc(P(=O)(c4ccccc4)c4ccccc4)cc3)nc(-c3ccc(P(=O)(c4ccccc4)c4ccccc4)cc3)n2)cc1 ; O=P(c1ccccc1)(c1ccccc1)c1ccccc1-c1nc(-c2ccccc2P(=O)(c2ccccc2)c2ccccc2)nc(-c2ccccc2P(=O)(c2ccccc2)c2ccccc2)n1]

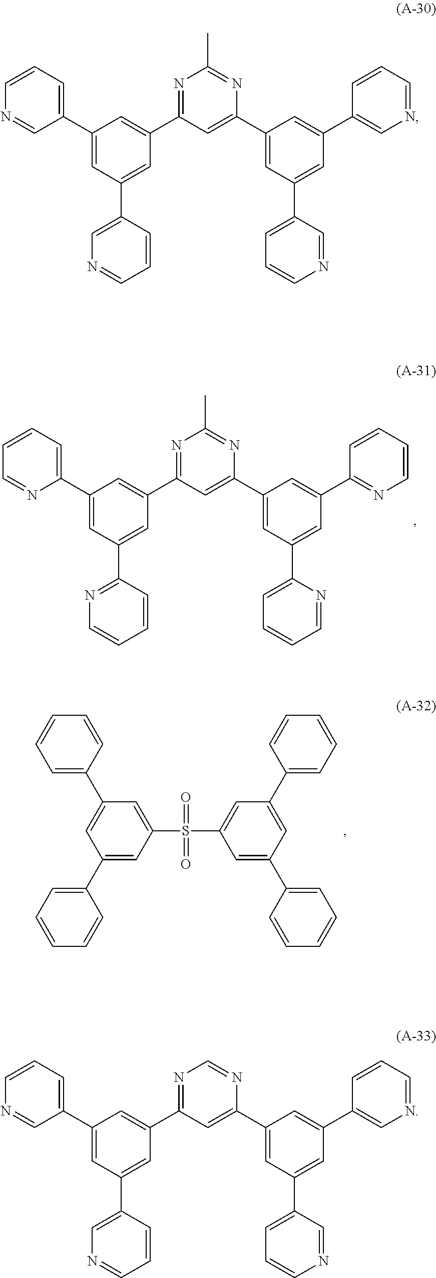 [SMILES: Cc1nc(-c2cc(-c3cccnc3)cc(-c3cccnc3)c2)cc(-c2cc(-c3cccnc3)cc(-c3cccnc3)c2)n1 ; Cc1nc(-c2cc(-c3ccccn3)cc(-c3ccccn3)c2)cc(-c2cc(-c3ccccn3)cc(-c3ccccn3)c2)n1 ; O=S(=O)(c1cc(-c2ccccc2)cc(-c2ccccc2)c1)c1cc(-c2ccccc2)cc(-c2ccccc2)c1 ; c1cncc(-c2cc(-c3cccnc3)cc(-c3cc(-c4cc(-c5cccnc5)cc(-c5cccnc5)c4)ncn3)c2)c1]

14. The organic electroluminescent device according to claim 8, wherein in the exciplex, a mass ratio of the electron donor type material to the electron acceptor type material is 1:9 to 9:1.

15. The organic electroluminescent device according to claim 14, wherein in the exciplex, the mass ratio of the electron donor type material to the electron acceptor type material is 1:1.

16. The organic electroluminescent device according to claim 1, wherein a mass ratio of the exciplex in the organic light emitting layer is 1 wt % to 99 wt %.

17. The organic electroluminescent device according to claim 1, wherein a mass ratio of the resonance-type thermally activated delayed fluorescence material in the organic light emitting layer is 0.1 wt % to 50 wt %.

18. A preparation method of an organic electroluminescent device, comprising: forming an organic light emitting layer by co-evaporation of a host material source and a resonance-type thermally activated delayed fluorescence material source, the host material being an exciplex.

19. A display apparatus comprising the organic electroluminescent device according to claim 1.
